(19) United States
(12) Patent Application Publication
(10) Pub. No.: US 2026/0182241 A1
(43) Pub. Date: Jun. 25, 2026

(54) Light Emitting Element, Display Device, And Electronic Apparatus

(71) Applicant: Samsung Display Co., Ltd., Yongin-si (KR)

(72) Inventors: Jaeweon Hur, Yongin-si (KR); Jungkyun Kim, Yongin-si (KR); Seulong Kim, Yongin-si (KR)

(73) Assignee: Samsung Display Co., Ltd., Yongin-si (KR)

(21) Appl. No.: 19/428,563

(22) Filed: Dec. 22, 2025

(30) Foreign Application Priority Data
Dec. 24, 2024 (KR) 10-2024-0196160

(51) Int. Cl. H10K 85/60; C09K 11/02; H10K 50/12; H10K 59/35; H10K 101/00

(52) U.S. Cl. CPC H10K 85/615; C09K 11/02; H10K 59/35; H10K 85/626; H10K 85/6574; H10K 50/12; H10K 2101/90

(57) ABSTRACT

A light-emitting element may include a first electrode, a second electrode facing the first electrode, a first light-emitting structure between the first electrode and the second electrode, and containing a first lower functional layer, a first light-emitting layer, and a first upper functional layer stacked in sequence, a second light-emitting structure on the first light-emitting structure and containing a second lower functional layer, a second light-emitting layer, and a second upper functional layer stacked in sequence, and a charge generation layer between the first light-emitting structure and the second light-emitting structure. The second light-emitting layer may include a first host, a second host different form the first host, and a blue light-emitting dopant, and a ratio of the first host to the second host may be about 9:1 to about 8:2. The light-emitting element may have improved light-emitting efficiency and lifespan characteristics. The light-emitting element may be included in a display device.

### CROSS-REFERENCE TO RELATED APPLICATIONS

This U.S. non-provisional patent application claims priority under 35 U.S.C. § 119 of Korean Patent Application No. 10-2024-0196160, filed on Dec. 24, 2024, the entire contents of which are hereby incorporated by reference.

### TECHNICAL FIELD

The present disclosure herein relates to a light-emitting element, a display device, and an electronic apparatus, and more particularly, to a light-emitting element including a plurality of light-emitting structures being stacked, a display device and an electronic apparatus including the light-emitting element.

### BACKGROUND

Various display devices used for multi-media apparatuses, such as a television, a mobile phone, a tablet computer, a navigation system, and a game console, are being developed. In this display device, a so-called self-luminous display element, in which a light-emitting material including an organic compound, quantum dots, or the like emits light to realize display on a light-emitting layer disposed between electrodes facing each other, is used.

In applying the light-emitting element to the display device, high light-emitting efficiency and long lifespan of the light-emitting element is required, and development of the material and stacked structure of the light-emitting element, capable of implementing such requirements stably, is continuously required.

### SUMMARY

The present disclosure provides a light-emitting element exhibiting improved light-emitting efficiency and long lifespan characteristics.

The present disclosure also provides a display device including the light-emitting element with high light-emitting efficiency and long lifespan.

The present disclosure also provides an electronic apparatus including the light-emitting element with high light-emitting efficiency and long lifespan.

An aspect of the present disclosure provides a light-emitting element including a first electrode, a second electrode facing the first electrode, a first light-emitting structure disposed between the first electrode and the second electrode, and containing a first lower functional layer, a first light-emitting layer, and a first upper functional layer stacked in sequence, a second light-emitting structure disposed on the first light-emitting structure, and containing a second lower functional layer, a second light-emitting layer, and a second upper functional layer stacked in sequence, and a charge generation layer disposed between the first light-emitting structure and the second light-emitting structure, wherein the second light-emitting layer includes a first host, a second host different from the first host, and a blue light-emitting dopant, and a ratio of the first host and the second host is about 9:1 to about 8:2.

In an aspect, the first light-emitting layer may include the first host, the second host, and the blue light-emitting dopant.

In an aspect, the first host included in the first light-emitting layer may be the same as the first host included in the second light-emitting layer, and the second host included in the first light-emitting layer may be the same as the second host included in the second light-emitting layer.

In an aspect, each of the first light-emitting structure and the second light-emitting structure may emit light in a blue-light wavelength region.

In an aspect, the first host may have a HOMO energy level of about −5.1 eV or greater, and a LUMO energy level of about −1.6 eV or less, and the second host may have a HOMO energy level of about −5.2 eV or greater, and a LUMO energy level of about −1.7 eV or less.

In an aspect, each of the first lower functional layer and the second lower functional layer may include an auxiliary light-emitting layer.

In an aspect, the first host may be represented by Formula 1 below.

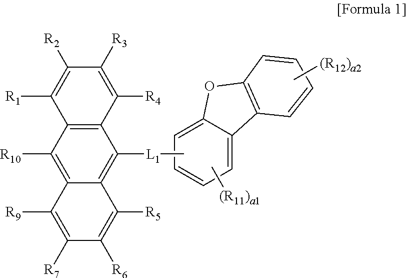

In an aspect, the second host may be represented by Formula 2 below.

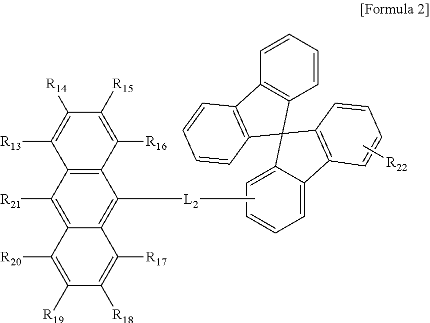

In an aspect, the first host may be represented by any one of compounds in Compound Group 1 to be described later.

In an aspect, the second host may be represented by any one of compounds in Compound Group 2 below.

In an aspect, the light-emitting element may further include a capping layer disposed on the second electrode.

In an aspect, at least one of the first lower functional layer or the second lower functional layer may further include an auxiliary light-emitting layer.

In an aspect, at least one of the first upper functional layer or the second upper functional layer may further include an electron transport layer.

In an aspect of the present disclosure, a display device has a red light-emitting region, a green light-emitting region, and a blue light-emitting region separated from each other on a plane, and the display device includes a base layer, a circuit layer disposed on the base layer, and a display layer disposed on the circuit layer, and containing a red light-emitting element disposed corresponding to the red light-emitting region, a green light-emitting element disposed corresponding to the green light-emitting region, and a blue light-emitting element disposed corresponding to the blue light-emitting region, each of the red light-emitting element, the green light-emitting element, and the blue light-emitting element includes a first electrode, a second electrode facing the first electrode, a first light-emitting structure disposed between the first electrode and the second electrode, and containing a first lower functional layer, a first light-emitting layer, and a first upper functional layer stacked in sequence, a second light-emitting structure disposed on the first light-emitting structure, and containing a second lower functional layer, a second light-emitting layer, and a second upper functional layer stacked in sequence, and a charge generation layer disposed between the first light-emitting structure and the second light-emitting structure, the second light-emitting layer of the blue light-emitting element includes a first host, a second host different from the first host, and a blue light-emitting dopant, and a ratio of the first host and the second host is about 9:1 to about 8:2.

In an aspect, the charge generation layer may include an n-type charge generation layer overlapping the red light-emitting region, the green light-emitting region, and the blue light-emitting region, and provided as a common layer on the first light-emitting structure, and a p-type charge generation layer directly disposed on the n-type charge generation layer, and the p-type charge generation layer may be provided as a pattern layer overlapping each of the red light-emitting region, the green light-emitting region, and the blue light-emitting region.

In an aspect, the green light-emitting element may include a hole transport host and an electron transport host on at least one of the first light-emitting layer or the second light-emitting layer.

In an aspect, the hole transport host may be represented by Formula HT-1 below.

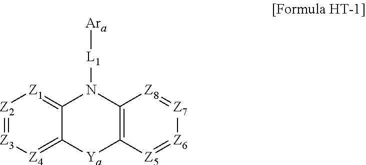

In an aspect, the electron transport host may be represented by Formula ET-1 below.

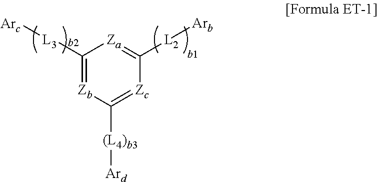

### BRIEF DESCRIPTION OF THE DRAWINGS

The accompanying drawings are included to provide a further understanding of aspects of the present disclosure, and are incorporated in and constitute a part of this specification. The drawings illustrate aspects of the present disclosure and, together with the description, serve to explain principles of the present disclosure. In the drawings:

FIG. 1 is a block diagram of an electronic apparatus according to an aspect;

FIG. 2 shows schematic views of an electronic apparatus according to an aspect.

FIG. 3 is a perspective view of a display device according to an aspect;

FIG. 4 is a cross-sectional view of a display device corresponding to line I-I′ of FIG. 1;

FIG. 5 is a cross-sectional view of a display device corresponding to line II-II′ of FIG. 1;

FIG. 6 is a cross-sectional view of a light-emitting element according to an aspect;

FIG. 7 is a cross-sectional view of a light-emitting element according to an aspect;

FIG. 8 is a cross-sectional view of a light-emitting element according to an aspect; and

FIG. 9 is a cross-sectional view of a display layer according to an aspect.

### DETAILED DESCRIPTION

Aspects of the present disclosure may be modified in various manners and have many forms, and thus specific aspects will be exemplified in the drawings and described in detail herein. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numbers are used for referring to like elements. In the accompanying drawings, the dimensions of each structure are exaggeratingly illustrated for clarity of the present disclosure. It will be understood that, although the terms “first,” “second,” etc., may be used herein to describe various components, these components should not be limited by these terms. These terms are only used to distinguish one component from another. For example, a first component could be termed a second component, and, similarly, a second component could be termed a first component, without departing from the scope of the aspects of the present disclosure. As used herein, the singular forms, “a,” “an,” and “the” are intended to include the plural forms as well, unless the context clearly indicates otherwise.

In the present disclosure, it will be understood that the terms “include,” “have” or the like specify the presence of features, numbers, steps, operations, component, parts, or combinations thereof disclosed in the specification, but do not exclude the possibility of presence or addition of one or more other features, numbers, steps, operations, component, parts, or combinations thereof.

In the present disclosure, when a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary to this, when a layer, a film, a region, or a plate is referred to as being “below”, “in a lower portion of” another layer, film, region, or plate, it can be not only directly under the layer, film, region, or plate, but intervening layers, films, regions, or plates may also be present. In addition, it will be understood that when a part is referred to as being “on” another part, it can be disposed above the other part, or disposed under the other part as well.

In the specification, the term “substituted or unsubstituted” may mean substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents exemplified above may be substituted or unsubstituted. For example, a biphenyl group may be interpreted as an aryl group or a phenyl group substituted with a phenyl group.

In the specification, the phrase “bonded to an adjacent group to form a ring” may mean that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In addition, the rings formed by being bonded to each other may be connected to another ring to form a spiro structure.

In the present disclosure, the term “adjacent group” may mean a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the present disclosure, examples of the halogen atom may include a fluorine atom, a chlorine atom, a bromine atom, or an iodine atom.

In the present disclosure, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the aspects of the present disclosure are not limited thereto.

In the present disclosure, a cycloalkyl group may mean a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but the aspects of the present disclosure are not limited thereto.

In the present disclosure, an alkenyl group means a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, etc., but the aspects of the present disclosure are not limited thereto.

In the present disclosure, an alkynyl group means a hydrocarbon group including at least one carbon triple bond in the middle or terminal of an alkyl group having 2 or more carbon atoms. The alkynyl group may be linear or branched. Although the number of carbon atoms is not specifically limited, it is 2 to 30, 2 to 20, or 2 to 10. Specific examples of the alkynyl group may include an ethynyl group, a propynyl group, etc., but are not limited thereto.

In the present disclosure, the hydrocarbon ring group means any functional group or substituent derived from an aliphatic hydrocarbon ring. The hydrocarbon ring group may be a saturated hydrocarbon ring group having 5 to 20 ring-forming carbon atoms.

In the present disclosure, an aryl group means any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the aspects of the present disclosure are not limited thereto.

In the present disclosure, the fluorenyl group may be substituted, and two substituents may be bonded to each other to form a spiro structure. Examples of the substituted fluorenyl group are as follows. However, the aspects of the present disclosure are not limited thereto.

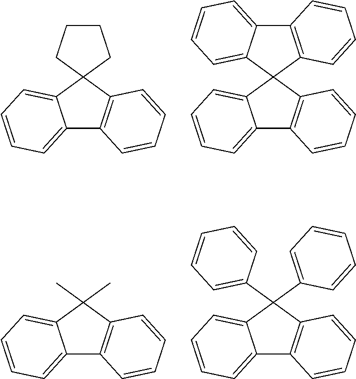

The heterocyclic group herein means any functional group or substituent derived from a ring containing at least one of B, O, N, P, Si, Se or S as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the present disclosure, the heterocyclic group may contain at least one of B, O, N, P, Si, Se or S as a heteroatom. If the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 30, 2 to 20, or 2 to 10.

In the present disclosure, the aliphatic heterocyclic group may include at least one of B, O, N, P, Si, Se or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but the aspects of the present disclosure are not limited thereto.

In the present disclosure, the heteroaryl group may contain at least one of B, O, N, P, Si, Se or S as a heteroatom. If the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the aspects of the present disclosure are not limited thereto.

In the present disclosure, the above description of the aryl group may be applied to an arylene group except that the arylene group is a divalent group. The above description of the heteroaryl group may be applied to a heteroarylene group except that the heteroarylene group is a divalent group.

In the present disclosure, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but the aspects of the present disclosure are not limited thereto.

In the present disclosure, the number of ring-forming carbon atoms in the carbonyl group is not specifically limited, but may be 1 to 40, 1 to 30, or 1 to 20. For example, the carbonyl group may have the following structures, but the aspects of the present disclosure are not limited thereto.

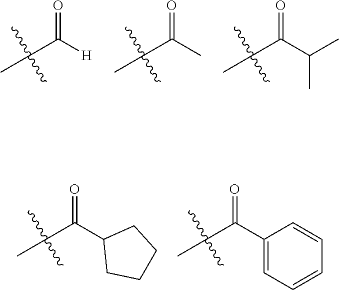

In the present disclosure, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the present disclosure, the thio group may include an alkylthio group and an arylthio group. The thio group may mean that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the aspects of the present disclosure are not limited thereto.

In the present disclosure, an oxy group may mean that an oxygen atom is bonded to the alkyl group or the aryl group as defined above. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy group, ethoxy group, n-propoxy group, isopropoxy group, butoxy group, pentyloxy group, hexyloxy group, octyloxy group, nonyloxy group, decyloxy group, benzyloxy group, etc., but the aspects of the present disclosure are not limited thereto.

The boron group herein may mean that a boron atom is bonded to the alkyl group or the aryl group as defined above. The boron group includes an alkyl boron group and an aryl boron group. Examples of the boron group may include a dimethylboron group, a trimethylboron group, a t-butyldimethylboron group, a diphenylboron group, a phenylboron group, etc., but the aspects of the present disclosure are not limited thereto.

In the present disclosure, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, etc., but the aspects of the present disclosure are not limited thereto.

In the present disclosure, the alkyl group among an alkylthio group, an alkylsulfoxy group, an alkylaryl group, an alkylamino group, an alkyl boron group, an alkyl silyl group, and an alkyl amine group is the same as the examples of the alkyl group described above.

In the present disclosure, the aryl group among an aryloxy group, an arylthio group, an arylsulfoxy group, an arylamino group, an arylboron group, an arylsilyl group, an arylamine group is the same as the examples of the aryl group described above.

In the present disclosure, a direct linkage may mean a single bond.

Meanwhile, in the present disclosure,

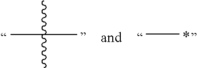

mean a position to be connected.

Hereinafter, aspects of the present disclosure are described with reference to the accompanying drawings.

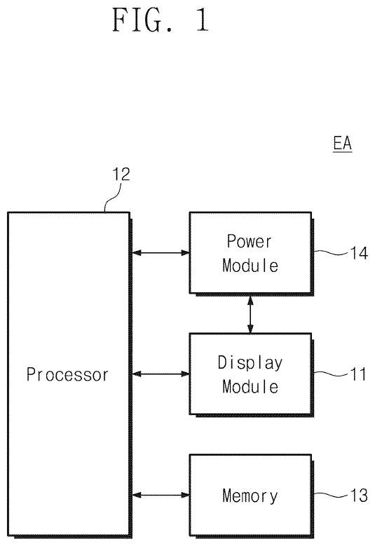

FIG. 1 is a block diagram of an electronic apparatus according to an aspect. Referring to FIG. 1, an electronic apparatus EA according to an aspect may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

In the memory 13, data information necessary for operation of the processor 12 or the display module 11 may be stored. When the processor 12 runs an application stored in the memory 13, image data signals and/or input control signals may be transmitted to the display module 11, and the display module 11 may process the received signals to output image information through a display screen. The display module 11 may include a display panel which displays the image.

The power module 14 may include a power supply module such as a power adapter or a battery device, and a power-converting module that converts power supplied by the power supply module, and generates power necessary for operation of the electronic apparatus EA.

At least one among the components of the electronic apparatus EA, previously described, may be included in a display panel according to aspects, to be described later, and in a display device according to an aspect including the same. In addition, some of individual modules, included in one functional module, may be included in the display device and others may also be provided separately from the display device. For example, the display device may include the display module 11, and the processor 12, the memory 13, and the power module 14 may be provided in the form of a device, other than the display device, in the electronic apparatus EA.

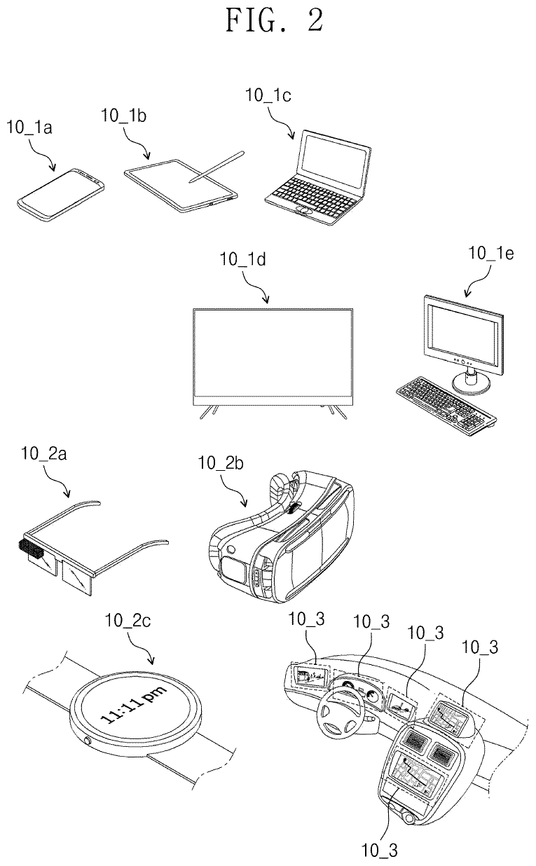

FIG. 2 shows schematic views of an electronic apparatus according to various aspects.

Referring to FIG. 2, various electronic apparatuses including a display device according to an aspect may not only include electronic apparatuses for displaying images such as a smartphone 10_1a, a tablet PC 10_1b, a laptop computer 10_1c, a TV 10_1d, or a desktop monitor 10_1e, but also include wearable electronic apparatuses such as smart glasses 10_2a, a head mounted display 10_2b, or a smart watch 10_2c, electronic apparatuses for vehicles 10_3 such as a car dashboard, a center fascia, a center information display (CID) disposed on the dashboard, or a room mirror display, etc.

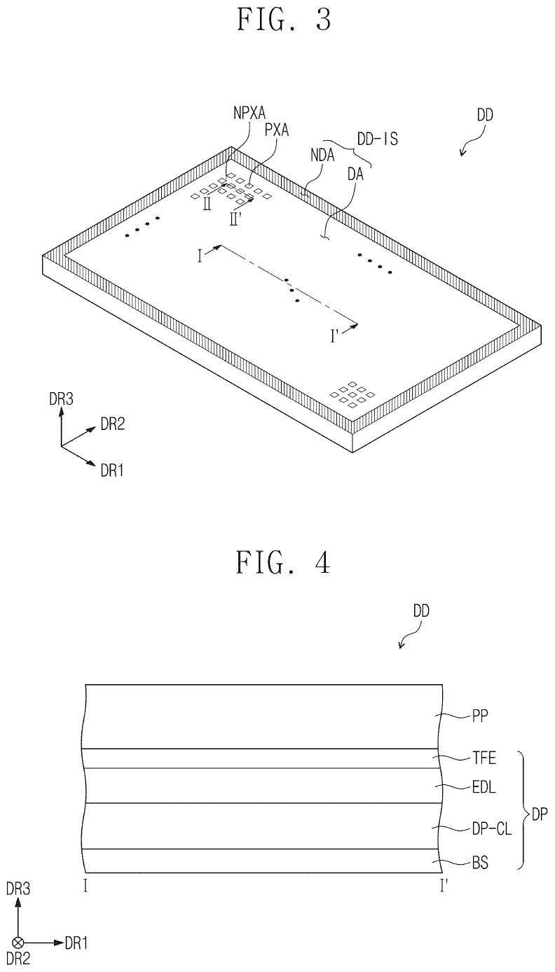

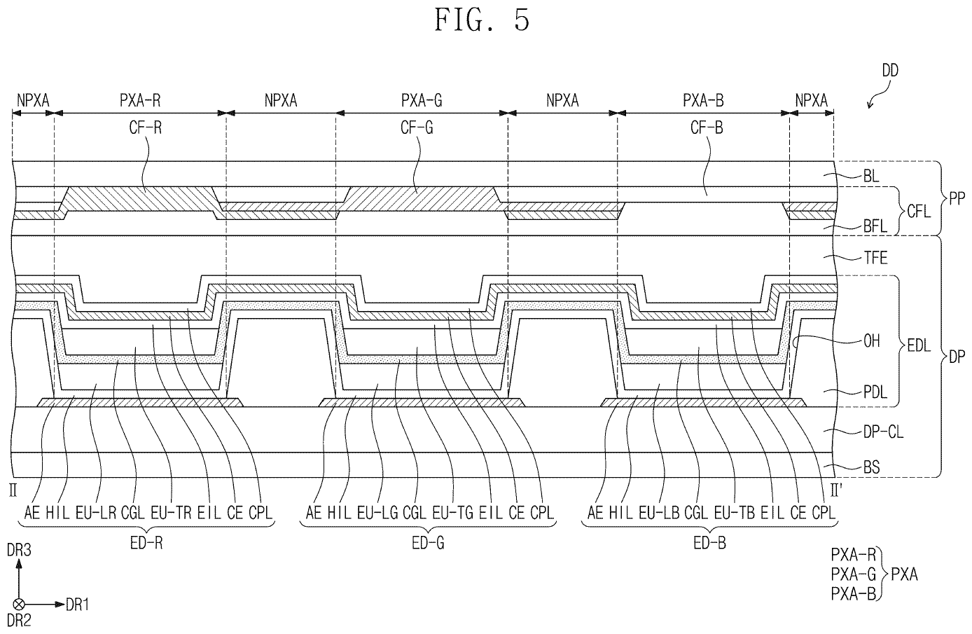

FIG. 3 is a perspective view of a display device according to an aspect. FIG. 4 is a cross-sectional view of a display device according to an aspect. FIG. 5 is a cross-sectional view illustrating a portion of a display device according to an aspect. FIG. 4 is a cross-sectional view corresponding to line I-I′ of FIG. 3, and FIG. 5 is a cross-sectional view corresponding to line II-II′ of FIG. 1.

A display device DD according to an aspect may be a device which is activated in response to electrical signals. The display device DD according to an aspect may include the electronic apparatus EA (see FIG. 1 and FIG. 2) previously described. The display device DD may be a part which provides a movie in the electronic apparatus EA (see FIG. 1 and FIG. 2). For example, the display device DD may be included in a large-size electronic apparatus such as a television, a monitor, or a billboard. In addition, the display device DD may be included in a small-and medium-sized electronic apparatus such as a personal computer, a laptop computer, a personal digital assistant, a car navigation unit, a game console, a smartphone, a tablet computer, a smart watch, or a camera. In addition, these are presented only as examples, and the display device may also be employed in another electronic apparatus as long as it does not deviate from the scope of the present disclosure.

The display device DD may display an image (or movie) through a display surface DD-IS. The display device DD may include a plurality of light-emitting regions PXA and a non-light-emitting region NPXA. The display surface DD-IS may be parallel to a plane defined by a first direction DR1 and a second direction DR2. The display surface DD-IS may include a display region DA and a non-display region NDA. The plurality of light-emitting regions PXA may be disposed in the display region DA. The light-emitting regions PXA may be referred to as pixel regions.

The non-display region NDA may be defined along a border of the display surface DD-IS. The non-display region NDA may surround the display region DA. However, aspects of the present disclosure are not limited thereto, and the non-display region NDA may be omitted, or the non-display region NDA may also be disposed only on one side of the display region DA.

FIG. 3 illustrates the display device DD including a flat display surface DD-IS, but aspects of the present disclosure are not limited thereto. The display device DD may also include a curved display surface or a three-dimensional display surface. The three-dimensional display surface may also include a plurality of display regions indicating different directions.

In FIG. 3 and the following drawings, a first directional axis to a third directional axis DR1, DR2 and DR3 are illustrated, and directions indicated by the first to third directional axes DR1, DR2, and DR3, may be relative concepts, and may thus be changed to other directions. In addition, the directions indicated by the first to third directional axes DR1, DR2, and DR3 may be described as first to third directions, and may be denoted as the same reference numerals or symbols. In this disclosure, the first directional axis DR1 and the second directional axis DR1 cross each other, and the third directional axis DR3 may be the normal direction of a plane defined by the first directional axis DR1 and the second directional axis DR2. In this disclosure, the ‘plane’ refers to a plane defined by the first directional axis DR1 and the second directional axis DR2, the ‘cross section’ refers to a surface perpendicular to the plane defined by the first directional axis DR1 and the second directional axis DR2 and parallel to the third directional axis DR3. The thickness direction of the display device DD may be a direction parallel to the third direction DR3 that is the normal direction of the plane defined by the first direction DR1 and the second direction DR2.

In this disclosure, an upper surface (or front surface) and a lower surface (or rear surface) of members constituting the display device DD may be defined on the basis of the third direction DR3. More particularly, among two surfaces of one member facing each other on the basis of the third direction DR3, the surface relatively adjacent to the display surface DD-IS may be defined as the front surface (or upper surface), and the surface relatively apart from the display surface DD-IS may be defined as the rear surface (or lower surface). In addition, in this disclosure, an upper part (or upper side) and a lower part (or lower side) may be defined on the basis of the third direction DR3, and the upper part (or upper side) may be defined as a direction closer to the display surface DD-IS, and the lower part (or lower side) may be defined as a direction away from the display surface DD-IS.

In this disclosure, one component “directly disposed/directly formed” on another component means that there is no intervening component between the one and the other components. That is, one component “directly disposed/directly formed” on another component means that the one and the other components are “in contact with” each other.

Referring to FIGS. 4 and 5, the display device DD may include a display panel DP, and an optical member PP disposed on the display panel DP. The display panel DP may include a display layer EDL. The display panel DP may include a base layer BS, a circuit layer DP-CL disposed on the base layer BS, and the display layer EDL disposed on the circuit layer DP-CL. The display layer EDL may include light-emitting elements ED-R, ED-G, and ED-B. In addition, the display panel DP may include an encapsulation layer TFE disposed on the display layer EDL. The encapsulation layer TFE may be directly disposed on the display layer EDL, or may be bonded to the display layer EDL through a separate member.

The display panel DP may be a component that substantially generates an image. In the display device DD according to an aspect, the display panel DP may be an emission type display panel. In an aspect, the display panel DP may include an organic light-emitting element containing an organic light-emitting material.

The optical member PP may be disposed on the display panel DP, and may control reflected light of external light on the display panel DP.

Referring to FIGS. 3 and 5, a plurality of light-emitting regions PXA may be disposed in the display region DA of the display device DD according to an aspect. The plurality of light-emitting regions PXA may be regions in which light generated from the light-emitting elements ED-R, ED-G, and ED-B is emitted, respectively.

The light-emitting regions PXA of the display device DD according to an aspect may be arranged in a stripe form. Referring to FIG. 3, the plurality of light-emitting regions PXA may be arranged along the first directional axis DR1 or the second directional axis DR2. However, aspects of the present disclosure are not limited thereto, and the arrangement of the light-emitting regions PXA may include a PENTILE® arrangement, or a Diamond Pixel® arrangement.

In addition, FIG. 3, etc. illustrates that the areas of the light-emitting regions PXA are all similar, but aspects of the present disclosure are not limited thereto, and the areas of the light-emitting regions PXA may differ from each other according to the wavelength region of light emitted.

The light-emitting regions PXA may include first to third light-emitting regions PXA-R, PXA-G, and PXA-B. The display device DD may include the plurality of light-emitting regions PXA-R, PXA-G, and PXA-B repeatably disposed in the entire display region DA. The display device DD according to an aspect may include the first to third light-emitting regions PXA-R, PXA-G, and PXA-B separated from each other. In addition, the display device DD may include a non-light-emitting region NPXA disposed around the first to third light-emitting regions PXA-R, PXA-G, and PXA-B. The non-light-emitting region NPXA may set boundaries between the first to third light-emitting regions PXA-R, PXA-G, and PXA-B. The non-light-emitting region NPXA may surround the first to third light-emitting regions PXA-R, PXA-G, and PXA-B. In the non-light-emitting region NPXA, a structure that prevents color mixing between the first to third light-emitting regions PXA-R, PXA-G, and PXA-B, for example, a pixel-defining film PDL, etc., may be disposed. The first to third light-emitting regions PXA-R, PXA-G, and PXA-B may be separated from each other on a plane.

The first to third light-emitting regions PXA-R, PXA-G, and PXA-B may be regions each separated by the pixel-defining film PDL. The non-light-emitting regions NPXA may be regions between the adjacent first to third light-emitting regions PXA-R, PXA-G, and PXA-B, and regions corresponding to the pixel-defining film PDL.

The first to third light-emitting regions PXA-R, PXA-G, and PXA-B may be regions where light generated from the first to third light-emitting elements ED-R, ED-G, and ED-B is emitted, respectively. The first to third light-emitting regions PXA-R, PXA-G, and PXA-B may be spaced apart from each other on a plane.

Meanwhile, in this specification, the first to third light-emitting regions PXA-R, PXA-G, and PXA-B may each correspond to a pixel. The pixel-defining film PDL may separate the first to third light-emitting elements ED-R, ED-G, and ED-B. Light-emitting structures EU-LR, EU-TR, EU-LG, EU-TG, EU-LB, and EU-TB of the first to third light-emitting elements ED-R, ED-G, and ED-B may be separately disposed in openings OH, defined in the pixel-defining film PDL.

The pixel-defining film PDL may be formed of a polymer resin. For example, the pixel-defining film PDL may be formed by including a polyacrylate-based resin or a polyimide-based resin. In addition, the pixel-defining film PDL may be formed by further including an inorganic material in addition to the polymer resin. Meanwhile, the pixel-defining film PDL may be formed by including a light-absorbing material, or formed by including a black pigment or black dye. The pixel-defining film PDL formed by including the black pigment or black dye may provide a black pixel-defining film. When the pixel-defining film PDL is formed, carbon black, etc. may be used as the black pigment or black dye, but aspects of the present disclosure are not limited thereto.

In addition, the pixel-defining film PDL may be formed of an inorganic material. For example, the pixel-defining film PDL may be formed of an inorganic material including silicon nitride (SiNₓ), silicon oxide (SiOₓ), silicon oxynitride (SiOₓN_{y}), etc.

The first to third light-emitting regions PXA-R, PXA-G, and PXA-B may be distinguished by the color of light generated from the first to third light-emitting elements ED-R, ED-G, and ED-B. In the display device DD according to the aspect illustrated in FIG. 3 as an example, red color light, green color light, and blue color light are respectively emitted in three light-emitting regions PXA-R, PXA-G, and PXA-B. For example, in the display device DD according to an aspect, the first light-emitting region PXA-R may correspond to a red light-emitting region, the second light-emitting region PXA-G may correspond to a green light-emitting region, and the third light-emitting region PXA-B may correspond to a blue light-emitting region.

In the display device DD according to an aspect, the light-emitting elements ED-R, ED-G, and ED-B may emit light in different wavelength regions. For example, in the display device DD according to an aspect, the first light-emitting element ED-R may correspond to a red light-emitting element emitting red light, the second light-emitting element ED-G may correspond to a green light-emitting element emitting green light, and the third light-emitting element ED-B may correspond to a blue light-emitting element emitting blue light. That is, the red light-emitting region PXA-R, the green light-emitting region PXA-G, and the blue light-emitting region PXA-B of the display device DD may respectively correspond to the first light-emitting element ED-R, the second light-emitting element ED-G, and the third light-emitting element ED-B.

Meanwhile, FIG. 5, etc. illustrates three light-emitting regions PXA-R, PXA-G, and PXA-B separated from each other, but aspects of the present disclosure are not limited thereto, and the display device DD according to an aspect may also include four or more light-emitting regions having different light-emitting characteristics.

In the display panel DP, the base layer BS may be a member that provides a base surface on which the display layer EDL is disposed. The base layer BS may be a glass substrate, a metal substrate, a plastic substrate, etc. However, aspects of the present disclosure are not limited thereto, and the base layer BS may be an inorganic layer, an organic layer, or a composite material layer.

In an aspect, the circuit layer DP-CL may be disposed on the base layer BS, and the circuit layer DP-CL may include a plurality of transistors (not shown). The transistors (not shown) may each include a control electrode, an input electrode, and an output electrode. For example, the circuit layer DP-CL may include a switching transistor and a driving transistor for driving the light-emitting elements ED-R, ED-G, and ED-B of the display layer EDL.

The encapsulation layer TFE may cover the light-emitting elements ED-R, ED-G, and ED-B. The encapsulation layer TFE may seal the display layer EDL. The encapsulation layer TFE may be a thin-film encapsulation layer. The encapsulation layer TFE may be a single layer or a stack of multiple layers. The encapsulation layer TFE includes at least one insulation layer. The encapsulation layer TFE according to an aspect may include at least one inorganic film (hereinafter, inorganic encapsulation film). In addition, the encapsulation layer TFE according to an aspect may include at least one organic film (hereinafter, organic encapsulation film) and at least one inorganic encapsulation film.

The inorganic encapsulation film protects the display layer EDL from moisture/oxygen, and the organic encapsulation film protects the display layer EDL from foreign substances such as dust particles. The inorganic encapsulation film may include silicon nitride, silicon oxynitride, silicon oxide, titanium oxide, aluminum oxide, or the like, and is not limited particularly thereto. The organic encapsulation film may include an acrylate-based compound, an epoxy-based compound, etc. The organic encapsulation film may include an organic material capable of photopolymerization, and is not limited particularly thereto.

The optical member PP may be a reflection-reducing layer that reduces the reflectance of external light. For example, the optical member PP may include a polarizing film that contains a phase retarder and/or a polarizer, multi-layer reflection layers that destructively interfere reflected light, or color filters disposed corresponding to a pixel arrangement and light-emitting color of the display panel DP. In case that the optical member PP includes the color filters, the color filters may be arranged in consideration of the light-emitting colors of pixels included in the display panel DP. In addition, in an aspect, the optical member PP may also be omitted.

In an aspect, the optical member PP may include a base substrate BL and a color filter layer CFL.

The base substrate BL may be a member that provides a base surface on which the color filter layer CFL, etc. is disposed. The base substrate BL may be a glass substrate, a metal substrate, a plastic substrate, etc. However, aspects of the present disclosure are not limited thereto, and the base substrate BL may be an inorganic layer, an organic layer, or a composite material layer.

The color filter layer CFL may include filters CF-R, CF-G, and CF-B. The color filter layer CFL may include first to third filters CF-R, CF-G, and CF-B. The first to third filters CF-R, CF-G, and CF-B may be respectively disposed corresponding to the first to third light-emitting elements ED-R, ED-G, and ED-B. For example, the first filter CF-R may be a red color filter, the second filter CF-G may be a green color filter, and the third filter CF-B may be a blue color filter. The first to third filters CF-R, CF-G, and CF-B may be respectively disposed corresponding to the first to third light-emitting regions PXA-R, PXA-G, and PXA-B.

In addition, a plurality of filters CF-R, CF-G, and CF-B transmitting different light may be disposed overlapping each other in correspondence to the non-light-emitting regions NPXA disposed between the light-emitting regions PXA-R, PXA-G, and PXA-B. The plurality of filters CF-R, CF-G, and CF-B may be disposed overlapping each other in the third direction DR3 that is the thickness direction, so that the boundaries between the light-emitting regions PXA-R, PXA-G, and PXA-B adjacent to each other may be distinguished. Accordingly, with improved light-blocking effect against external light, the filters may function like a black matrix. The overlapped structure of the plurality of filters CF-R, CF-G, and CF-B may have a function of preventing color mixing.

The first to third filters CF-R, CF-G, and CF-B may each include a polymer photoresist, and a pigment or dye. The first filter CF-R may include a red pigment or blue dye, the second filter CF-G may include a green pigment or green dye, and the third filter CF-B may include a blue pigment or red dye. However, aspects of the present disclosure are not limited thereto, and the third filter CF-B may not include a pigment or dye. The third filter CF-B may include a polymer photoresist, and may not include a pigment or dye. The third filter CF-B may be transparent. The third filter CF-B may be formed of a transparent photoresist.

The color filter layer CFL may further include a buffer layer BFL. For example, the buffer layer BFL may be a protection layer that protects the first to third filters CF-R, CF-G, and CF-B. The buffer layer BFL may be an inorganic material layer including at least one inorganic material of silicon nitride, silicon oxide, or silicon oxynitride. The buffer layer BFL may be made of a single layer or a plurality of layers.

In addition, the first filter CF-R and the second filter CF-G may be yellow filters. The first filter CF-R and the second filter CF-G may not be separated from each other and may be provided as one body.

Although not illustrated in the drawing, the color filter layer CFL may further include a light-blocking part (not shown). The light-blocking part may be a black matrix. The light-blocking part may be formed by including an organic light-blocking material or an inorganic light-blocking material containing a black pigment or black dye. The light-blocking part may prevent a light-leak phenomenon, and may set boundaries between the filters CF-R, CF-G, and CF-B adjacent to each other. In addition, unlike what is illustrated in FIG. 3, etc., the optical member PP of the display device DD according to an aspect may not include the color filter layer CFL.

In the display device DD according to an aspect, the first to third light-emitting elements ED-R, ED-G, and ED-B may each include a first electrode AE, a lower light-emitting structure EU-LR, EU-LG, or EU-LB, a charge generation layer CGL, an upper light-emitting structure EU-TR, EU-TG, or EU-TB, and a second electrode CE. FIG. 5 illustrates that each of the light-emitting elements ED-R, ED-G, and ED-B includes two light-emitting structures stacked in the third direction DR3 that is the thickness direction, but aspects of the present disclosure are not limited thereto, and each of the light-emitting elements a lower light-emitting structure EU-LR, EU-LG, and EU-LB and the upper light-emitting structure EU-TR, EU-TG, and EU-TB may be disposed between the first electrode AE and the second electrode CE, and may include three or more light-emitting structures stacked in the thickness direction. In addition, the light-emitting elements ED-R, ED-G, and ED-B, each including three or more light-emitting structures, may further include charge generation layers each disposed between the light-emitting structures.

In an aspect, each of the light-emitting elements ED-R, ED-G, and ED-B includes at least one light-emitting layer for each of the lower light-emitting structure EU-LR, EU-LG, and EU-LB and the upper light-emitting structure EU-TR, EU-TG, and EU-TB. That is, the light-emitting elements ED-R, ED-G, and ED-B may each be a light-emitting element of a tandem structure including a plurality of light-emitting layers stacked in the thickness direction. In this specification, the lower light-emitting structure EU-LR, EU-LG, and EU-LB may be referred to as a first light-emitting structure, and the upper light-emitting structure EU-TR, EU-TG, and EU-TB may be referred to as a second light-emitting structure.

In an aspect, the lower light-emitting structure EU-LR, EU-LG, and EU-LB and the upper light-emitting structure EU-TR, EU-TG, and EU-TB, included in each of the first to third light-emitting elements ED-R, ED-G, and ED-B, may emit the same color light. In an aspect, the lower light-emitting structure EU-LR, EU-LG, and EU-LB and the upper light-emitting structure EU-TR, EU-TG, and EU-TB, included in each of the first to third light-emitting elements ED-R, ED-G, and ED-B, may emit light in the same wavelength region. For example, the first light-emitting element ED-R may include the lower light-emitting structure EU-LR and the upper light-emitting structure EU-TR each emitting light in a red-light wavelength region, the second light-emitting element ED-G may include the lower light-emitting structure EU-LG and the upper light-emitting structure EU-TG each emitting light in a green-light wavelength region, and the third light-emitting element ED-B may include the lower light-emitting structure EU-LB and the upper light-emitting structure EU-TB each emitting light in a blue-light wavelength region. Meanwhile, in each light-emitting element, the light-emitting structures, stacked in the thickness direction, emitting light in the same wavelength region refers to emitting light in a wavelength region that is recognized as light of the same color even if the light-emitting wavelengths do not completely match.

The light-emitting structures and the charge generation layer, included in the light-emitting element ED-R, ED-G, and ED-B, will be described in more detail later. The light-emitting element ED-R, ED-G, and ED-B may further include a capping layer CPL disposed above the second electrode CE. In addition, the light-emitting element ED-R, ED-G, and ED-B may further include at least one of a hole injection layer HIL disposed between the first electrode AE and the light-emitting structure, and an electron injection layer EIL disposed between the light-emitting structure and the second electrode CE in addition to the light-emitting structure. For example, the hole injection layer HIL may be disposed between the first electrode AE and the lower light-emitting structure EU-LR, EU-LG, and EU-LB, and the electron injection layer EIL may be disposed between the upper light-emitting structure EU-TR, EU-TG, and EU-TB and the second electrode CE.

In an aspect, the first electrode AE may be exposed by a pixel opening OH of the pixel-defining film PDL. The first electrode AE has conductivity. The first electrode AE may be formed of a metal material, a metal alloy, or a conductive compound. The first electrode AE may be an anode or a cathode. In addition, the first electrode AE may be a pixel electrode. However, aspects of the present disclosure are not limited thereto.

The second electrode CE may be disposed on the first electrode AE. The second electrode CE may be a cathode or an anode. In an aspect, in case that the first electrode AE is the anode, the second electrode CE may be the cathode, and in case that the first electrode AE is the cathode, the second electrode CE may be the anode. The second electrode CE may be a common electrode. However, aspects of the present disclosure are not limited thereto.

The lower light-emitting structures EU-LR, EU-LG, and EU-LB may be disposed between the first electrode AE and the charge generation layer CGL, and the upper light-emitting structures EU-TR, EU-TG, and EU-TB may be disposed between the charge generation layer CGL and the second electrode CE.

FIG. 5 illustrates that the lower light-emitting structure EU-LR, EU-LG, and EU-LB and the upper light-emitting structure EU-TR, EU-TG, and EU-TB of each of the first to third light-emitting elements ED-R, ED-G, and ED-B, are disposed in the pixel opening OH. However, this is an example, and some components among the components of the lower light-emitting structure EU-LR, EU-LG, and EU-LB and the upper light-emitting structure EU-TR, EU-TG, and EU-TB, to be described later, may be provided by being pattered to be disposed in the pixel opening OH, and the rest of the components may be provided as common layers for the entire first to third light-emitting regions PXA-R, PXA-G, and PXA-B. In addition, in another aspect, at least some among the components of the lower light-emitting structure EU-LR, EU-LG, and EU-LB and the upper light-emitting structure EU-TR, EU-TG, and EU-TB may be disposed by extending to an upper part of the pixel-defining film PDL, or at least some may be connected to each other.

In the display device DD according to an aspect, the lower light-emitting structure EU-LR, EU-LG, and EU-LB and the upper light-emitting structure EU-TR, EU-TG, and EU-TB of each of the first to third light-emitting elements ED-R, ED-G, and ED-B may be provided and formed through inkjet printing. However, aspects of the present disclosure are not limited thereto. The lower light-emitting structure EU-LR, EU-LG, and EU-LB and the upper light-emitting structure EU-TR, EU-TG, and EU-TB may be provided and formed in a method other than the inkjet printing.

In the display device DD according to an aspect, the second electrode CE and the capping layer CPL may each be provided as a common layer for the entire first to third light-emitting elements ED-R, ED-G, and ED-B. However, aspects of the present disclosure are not limited thereto, and at least one of the second electrode CE or the capping layer CPL may be provided separately from each other in the adjacent light-emitting regions PXA-R, PXA-G, and PXA-B.

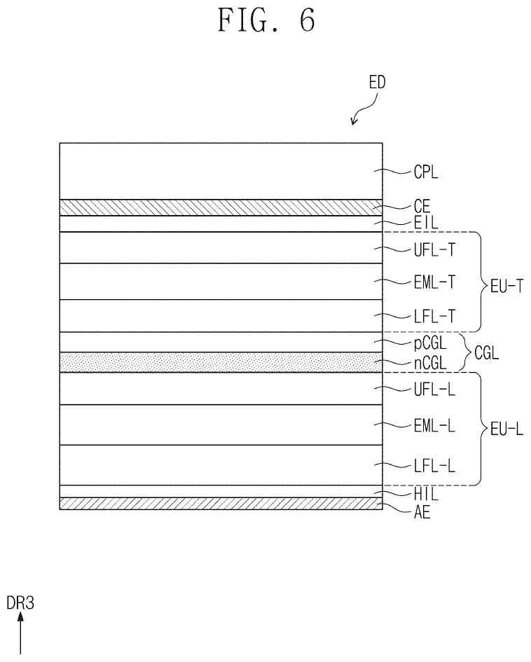

FIGS. 6 to 8 are cross-sectional views each illustrating a light-emitting element included in a display device according to an aspect. FIGS. 6 to 8 each illustrates a structure of one light-emitting element representative for the light-emitting elements included in the display device according to an aspect, and the structure of the light-emitting element, illustrated in FIGS. 6 to 8, may be equally applied to each of the first to third light-emitting elements ED-R, ED-G, and ED-B illustrated in FIG. 3.

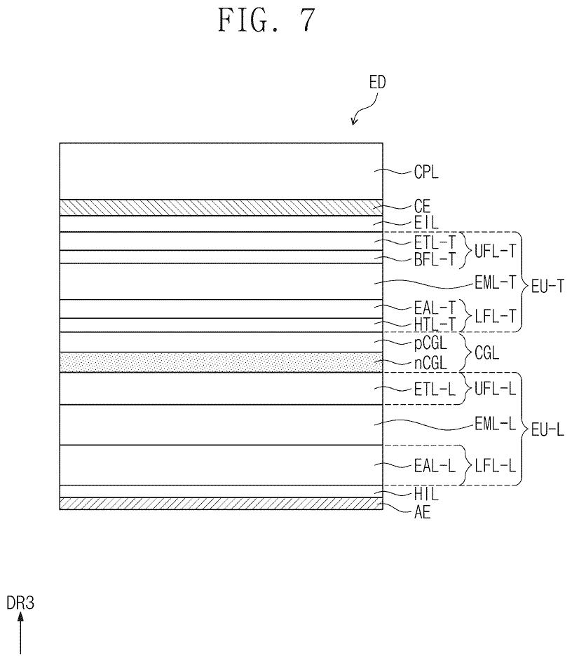

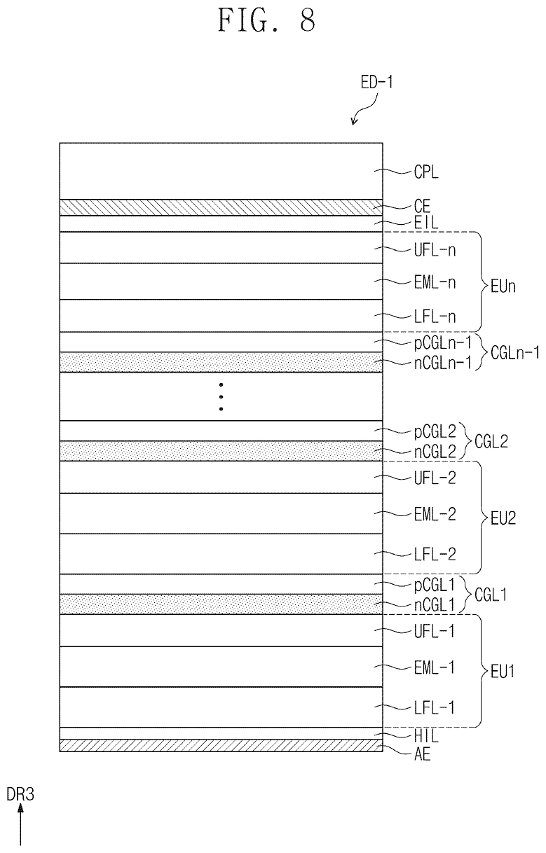

FIGS. 6 and 7 each illustrates an aspect of a light-emitting element including two light-emitting structures stacked between a first electrode AE and a second electrode CE. In addition, FIG. 8 illustrates an aspect of a light-emitting element including three or more light-emitting structures stacked between a first electrode AE and a second electrode CE.

Referring to FIGS. 6 and 7, a light-emitting element ED according to an aspect may include a first electrode AE, a hole injection layer HIL, a lower light-emitting structure EU-L, a charge generation layer CGL, an upper light-emitting structure EU-T, an electron injection layer EIL, a second electrode CE, and a capping layer CPL. Compared to FIG. 6, FIG. 7 exemplarily illustrates a constitution of sub-functional layers included in each of a lower functional layer LFL-L and LFL-T and an upper functional layer UFL-L and UFL-T.

A light-emitting element ED-1 according to an aspect, illustrated in FIG. 8, may include n light-emitting structures EU1, EU2, . . . , and EUn between a first electrode AE and a second electrode CE. The light-emitting element ED-1 according to an aspect may include the first electrode AE, a hole injection layer HIL, the n light-emitting structures EU1, EU2, . . . , and EUn, n-1 charge generation layers CGL1, CGL2, . . . , and CGLn-1, an electron injection layer EIL, the second electrode CE, and a capping layer CPL. In the aspect illustrated in FIG. 8, n may be an integer of 2 or greater. The charge generation layers CGL1, CGL2, . . . , and CGLn-1 may each be disposed between the light-emitting structures EU1, EU2, . . . , and EUn. For example, a first charge generation layer CGL1 may be disposed between a first light-emitting structure EU1 and a second light-emitting structure EU2, a second charge generation layer CGL2 may be disposed on the second light-emitting structure EU2, and an (n-1)-th charge generation layer CGLn-1 may be disposed below an n-th light-emitting structure EUn.

In the light-emitting elements ED and ED-1 according to the aspects illustrated in FIGS. 6 to 8, the first electrode AE may be a transmissive electrode, a semi-transmissive electrode, or a reflective electrode. The first electrode AE may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, or an oxide thereof.

If the first electrode AE is the transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode AE is the transflective electrode or the reflective electrode, the first electrode AE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (e.g., a mixture of Ag and Mg). Alternatively, the first electrode AE may have a multilayer structure including a reflective film or a transflective film formed of the above-described materials, and a transparent conductive film formed of ITO, IZO, ZnO, ITZO, etc. For example, the first electrode AE may have a three-layer structure of ITO/Ag/ITO, but aspects of the present disclosure are not limited thereto. In addition, the first electrode AE may include the above-described metal materials, combinations of at least two metal materials of the above-described metal materials, oxides of the above-described metal materials, or the like. The thickness of the first electrode AE may be from about 700 Å to about 10,000 Å. For example, the thickness of the first electrode AE may be from about 1,000 Å to about 3,000 Å.

The second electrode CE may include at least one selected from among Ag, Mg, Cu, Al, Pt, Pd, Au, Ni, Nd, Ir, Cr, Li, Ca, LiF, Mo, Ti, W, Na, In, Sn, Zn, a compound of two or more selected from among these, a mixture of two or more selected from among these, or an oxide thereof.

The second electrode CE may be a transmissive electrode, a transflective electrode, or a reflective electrode. If the second electrode CE is the transmissive electrode, the second electrode CE may include a transparent metal oxide such as indium tin oxide (ITO), indium zinc oxide (IZO), zinc oxide (ZnO), or indium tin zinc oxide (ITZO).

When the second electrode CE is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, Na, or a compound or mixture thereof (e.g., AgMg, AgYb, MgYb, AgLi, or AgNa). Alternatively, the second electrode CE may have a multilayer structure including a reflective film or a transflective film formed of the above-described materials, and a transparent conductive film formed of ITO, IZO, ZnO, ITZO, etc. For example, the second electrode CE may include the above-described metal materials, combinations of at least two metal materials of the above-described metal materials, oxides of the above-described metal materials, or the like.

Although not shown, the second electrode CE may be connected with an auxiliary electrode. The auxiliary electrode (not shown) can be formed as a conductive pattern in the circuit layer DP-CL (FIG. 5). If the second electrode CE is connected with the auxiliary electrode, the resistance of the second electrode CE may be decreased.

The light emitting element ED and ED-1 of an aspect may include a capping layer CPL disposed on the second electrode CE. The capping layer CPL may include a multilayer or a single layer.

In an aspect, the capping layer CPL may be an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or an epoxy resin, or acrylate such as methacrylate. However, aspects of the present disclosure are not limited thereto, and the capping layer CPL may include at least one among Compounds P1 to P5 below:

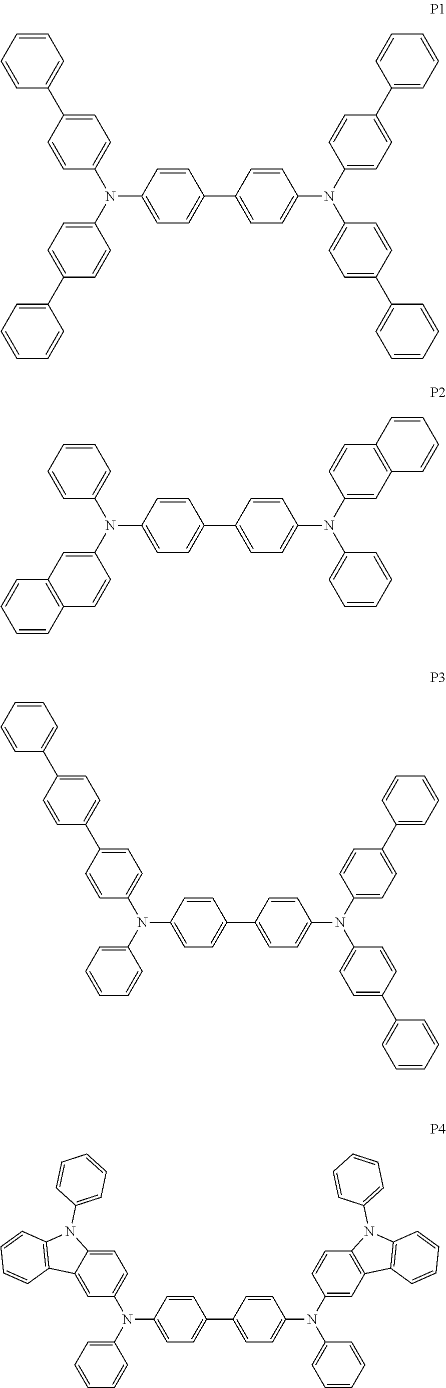 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

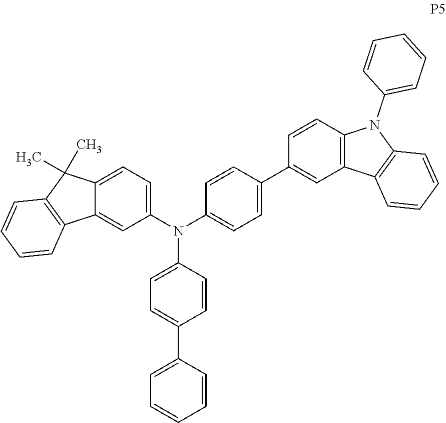 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

Meanwhile, the refractive index of the capping layer CPL may be about 1.6 or more. Specifically, the refractive index of the capping layer CPL may be about 1.6 or more with respect to light in a wavelength range of about 550 nm to about 660 nm.

Referring to FIGS. 6 and 7, in the light-emitting element ED according to an aspect, the lower light-emitting structure EU-L may include a first lower functional layer LFL-L, a first light-emitting layer EML-L, and a first upper functional layer UFL-L stacked in sequence, and the upper light-emitting structure EU-T may include a second lower functional layer LFL-T, a second light-emitting layer EML-T, and a second upper functional layer UFL-T stacked in sequence.

In the light-emitting element ED according to an aspect illustrated in FIG. 6, the upper functional layer UFL-L and UFL-T may be an electron-transport functional layer which has a function of electron injection or electron transport. The lower functional layer LFL-L and LFL-T may be a hole-transport functional layer which has a function of hole injection or hole transport. Aspects of the present disclosure are not limited thereto, and the lower functional layer LFL-L and LFL-T may be a functional layer that serves as an auxiliary light-emitting layer compensating the resonance distance according to the wavelength of light emitted from the light-emitting layer EML-L and EML-T and controlling hole charge balance to increase light-emitting efficiency. In addition, the auxiliary light-emitting layer may also serve as an electron-blocking layer that prevents injection of electrons into the hole transport layer, etc. The auxiliary light-emitting layer may include a hole-transporting material. In addition, the electron-blocking layer may be a layer that prevents injection of electrons from the electron-transport functional layers to the hole-transport functional layer.

In the aspect illustrated in FIG. 6, the upper functional layers UFL-L and UFL-T may each have a single layer or a multi-layer structure having a plurality of layers. The upper functional layers UFL-L and UFL-T may each have a single layer made of a single material, a single layer made of a plurality of different materials, or a multi-layer structure including a plurality of layers made of a plurality of different materials. For example, the upper functional layers UFL-L and UFL-T may each have a structure sequentially stacked from the light-emitting layer EML-L and EML-T including the structure of an electron transport layer/an electron injection layer, a buffer layer/an electron transport layer, or a hole-blocking layer/an electron transport layer/an electron injection layer, etc., but aspects of the present disclosure are not limited thereto. Meanwhile, the buffer layer may also be referred to as an electron transport layer or an auxiliary electron transport layer. The buffer layer may complement the electron-transporting function. In addition, the hole-blocking layer may be a layer that prevents injection of holes from the hole-transport functional layers to the electron-transport functional layer.

In the aspect illustrated in FIG. 6, the lower functional layers LFL-L and LFL-T may each be a single layer made of a single material, a single layer made of a plurality of different materials, or a multi-layer structure including a plurality of layers made of a plurality of different materials. For example, the lower functional layers LFL-L and LFL-T may each have a structure sequentially stacked from the first electrode AE, including the structure of a hole injection layer/a hole transport layer, a hole injection layer/a hole transport layer/an auxiliary light-emitting layer, a hole injection layer/an auxiliary light-emitting layer, a hole transport layer/an auxiliary light-emitting layer, a hole injection layer/a hole transport layer/an auxiliary light-emitting layer, a hole injection layer/a hole transport layer/an electron-blocking layer, or the like, but aspects of the present disclosure are not limited thereto.

In the aspect illustrated in FIG. 6, the first upper functional layer UFL-B may have a stacked structure of a first auxiliary electron transport layer (not shown) and a first electron transport layer (not shown), the second upper functional layer UFL-T may have a stacked structure of a second auxiliary electron transport layer (not shown) and a second electron transport layer (not shown). In an aspect, the first auxiliary electron transport layer (not shown) and the second auxiliary electron transport layer (not shown) may each independently function as an electron transport layer, a buffer layer, or a hole-blocking layer.

Referring to FIG. 7, the first upper functional layer ULF-L may include a first electron transport layer ETL-L stacked on a first light-emitting layer EML-L, and the second upper functional layer UFL-T may include a buffer layer BFL-T and a second electron transport layer ETL-T sequentially stacked on a second light-emitting layer EML-T. Unlike what is illustrated in FIG. 7, the first upper functional layer UFL-L may also further include a buffer layer.

In addition, referring to FIG. 7, the first lower functional layer LFL-L may include a first auxiliary light-emitting layer EAL-L stacked on the first electrode AEl. The second lower functional layer LFL-T may include a hole transport layer HTL-T and a second auxiliary light-emitting layer EAL-T sequentially stacked on the charge generation layer CGL. Unlike what is illustrated in FIG. 7, the first lower functional layer LFL-L may further include a hole transport layer, or the first auxiliary light-emitting layer EAL-L may also be substituted with the hole transport layer.

Referring to FIGS. 6 and 7, the light-emitting element ED according to an aspect may include the charge generation layer CGL disposed between the lower light-emitting structure EU-L and the upper light-emitting structure EU-T. When a voltage is applied to the light-emitting element ED, a complex may be formed through oxidation-reduction reaction to generate charges (electrons and holes) in the charge generation layer CGL. In addition, the charge generation layer CGL may provide the generated charges to each of the adjacent lower light-emitting structure EU-L and upper light-emitting structure EU-T. The charge generation layer CGL may increase the efficiency of current generated from each of the adjacent light-emitting structures EU-L and EU-T, and may serve to control balance of the charges between the adjacent light-emitting structures EU-L and EU-T. The charge generation layer CGL may include an n-type charge generation layer nCGL and a p-type charge generation layer pCGL. The n-type charge generation layer nCGL and the p-type charge generation layer pCGL may have a layered structure that is joined together.

The n-type charge generation layer nCGL may be a charge generation layer that provides electrons to the adjacent light-emitting structure EU-L. The n-type charge generation layer nCGL may be a layer in which a base material is doped with an n-type dopant. The p-type charge generation layer pCGL may be a charge generation layer that provides holes to the adjacent light-emitting structure EU-T. The p-type charge generation layer pCGL may be a layer in which a base material is doped with a p-type dopant. In addition, in an aspect, a buffer layer may also be further disposed between the n-type charge generation layer nCGL and the p-type charge generation layer pCGL. That is, in an aspect, the n-type charge generation layer nCGL may be an electron-transport functional layer that has an electron transport function, and the p-type charge generation layer pCGL may be a hole-transport functional layer that has a hole transport function.

The charge generation layer CGL may include an n-type aryl amine-based material, or a p-type metal oxide. For example, the charge generation layer CGL may include a charge-generating compound including an aryl amine-based organic compound, a carbazole-based compound, metal, a metal oxide, carbide, fluoride, or a mixture thereof.

For example, the aryl amine-based organic compound may be bphen(bathophenanthroline), α-NPD(N,N′-di(naphthalene-1-yl)-N,N′-diphenyl-benzidine), 2-TNATA(4,4′,4″-tris[N(2-naphthyl)-N-phenylamino]-triphenylamine), TDATA(4,4′4″-Tris(N,N-diphenylamino)triphenylamine), m-TDATA(4,4′,4″-[tris(3-methylphenyl)phenylamino]triphenylamine), sprio-TAD, or sprio-NPB, and the carbazole-based compound may be CBP(4,4′-bis(carbazol-9-yl)biphenyl). For example, the metal may be cesium (Cs), molybdenum (Mo), vanadium (V), titanium (Ti), tungsten (W), barium (Ba), or lithium (Li). In addition, for example, the oxide of metal, carbide, and fluoride may be Re₂O₇, MoO₃, V₂O₅, WO₃, TiO₂, Cs₂CO₃, BaF, LiF, or CsF.

In the light-emitting element ED according to an aspect, the upper functional layer UFL-L and UFL-T may be formed using various methods including vacuum deposition, spin coating, casting, Langmuir-Blodgett (LB), inkjet printing, laser printing, laser induced thermal imaging (LITI), etc.

The light-emitting element ED according to an aspect may include a known electron-transporting material in the upper functional layer UFL-L and UFL-T. Aspects of the present disclosure are not limited thereto, and the light-emitting element ED may also include a known electron-transporting material in the n-type charge generation layer nCGL. In an aspect, a plurality of sub-functional layers included in the first upper functional layer UFL-L and the second upper functional layer UFL-T may include a known electron-transporting material.

For example, the first upper functional layer UFL-L and the second upper functional layer UFL-T may each independently include an anthracene-based compound. However, aspects of the present disclosure are not limited thereto, and the upper functional layers UFL-L and UFL-T may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-diphenyl-1,10-phenanthroline 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butyiphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tflu-PBD), bis(2-methyl-8-quinolinolato-N1,08)-(1,1′-biphenyl-4-olato)aluminum (BAlq), beryllium bis(benzoquinolin-1O-olate) (Bebq₂), 9,10-di(naphthalene-2-yl)anthracene (ADN), 1,3-bis[3,5-di(pyridin-3-yl)phenyl]benzene (BmPyPhB), or a mixture thereof.+

The upper functional layers UFL-L and UFL-T may include at least one among Compound ET1 to Compound ET39 below:

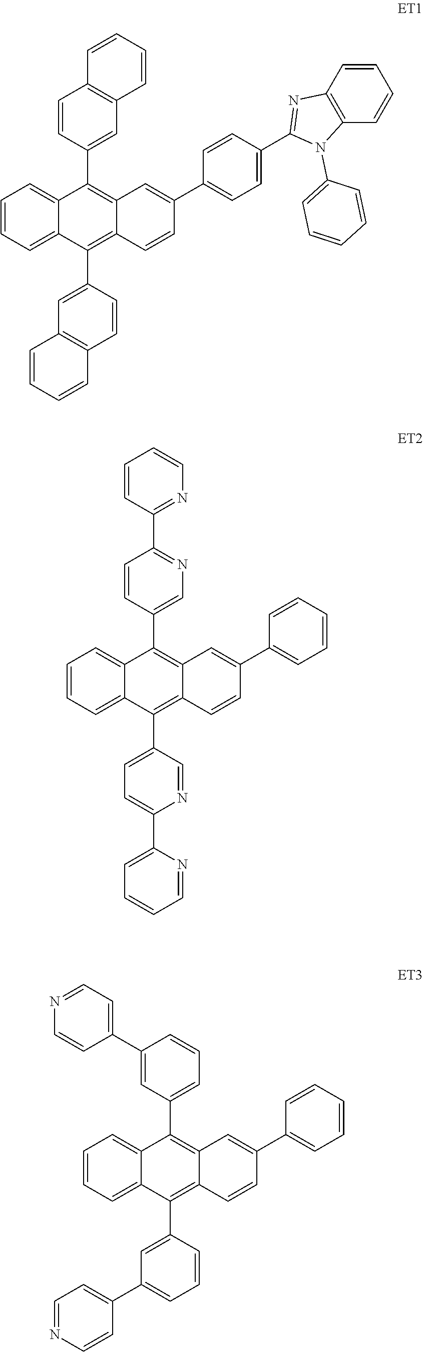 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

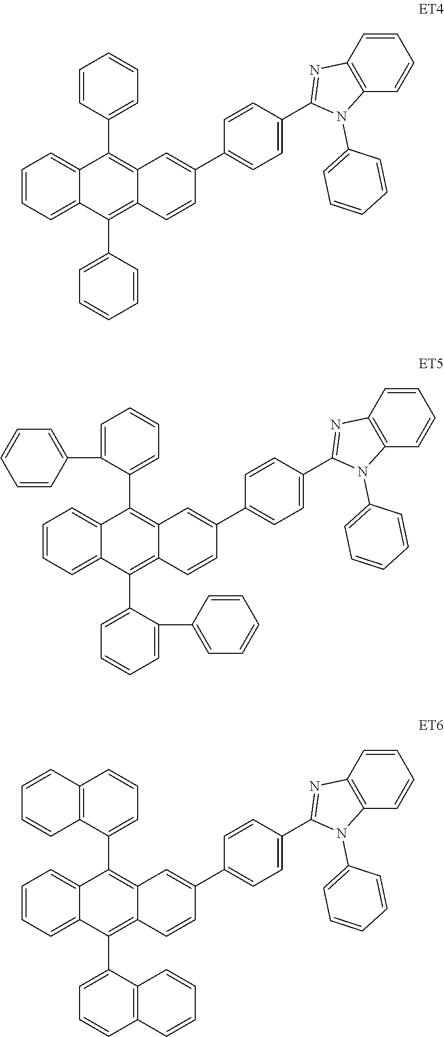 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

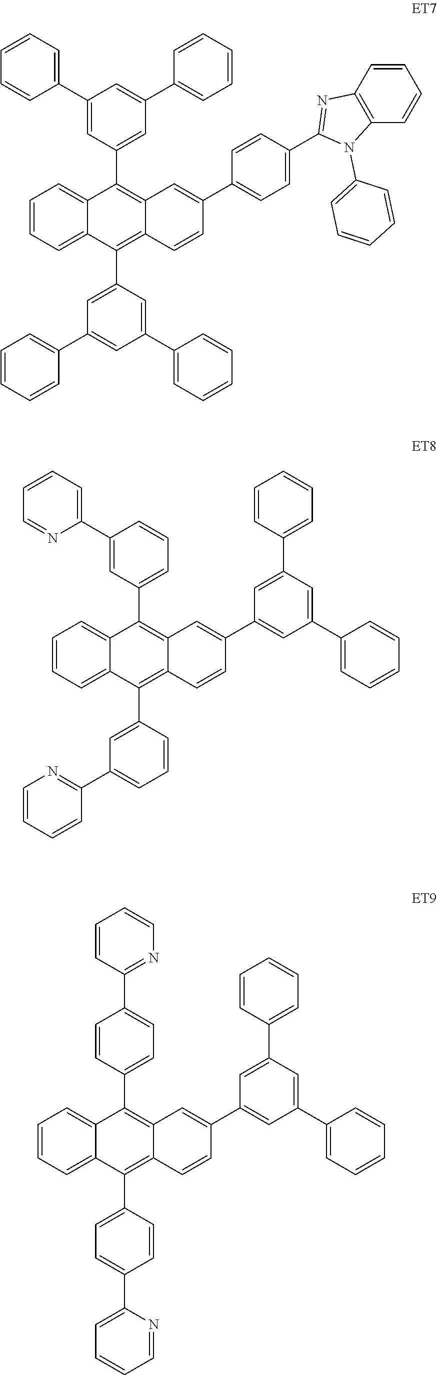 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

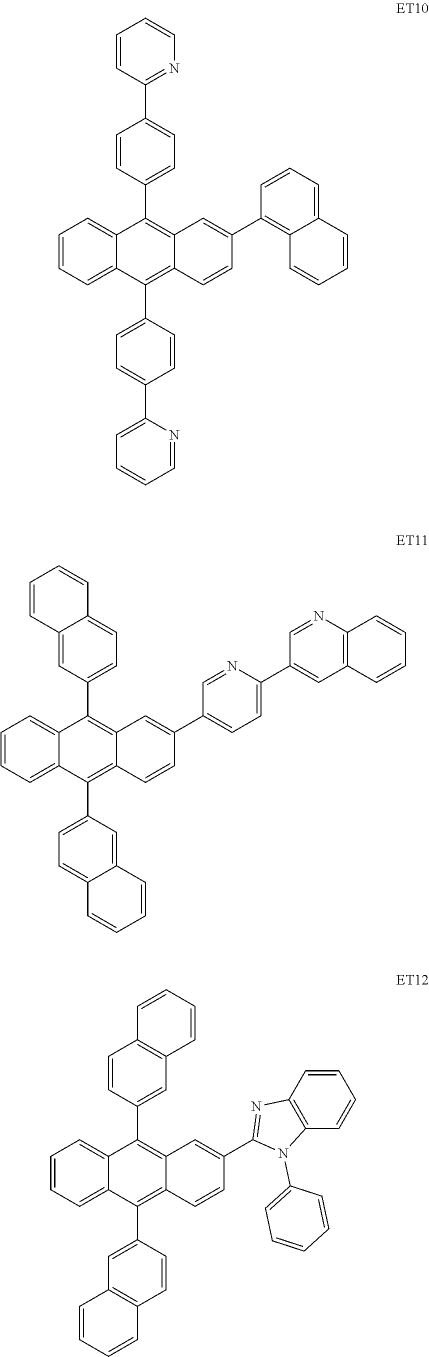 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

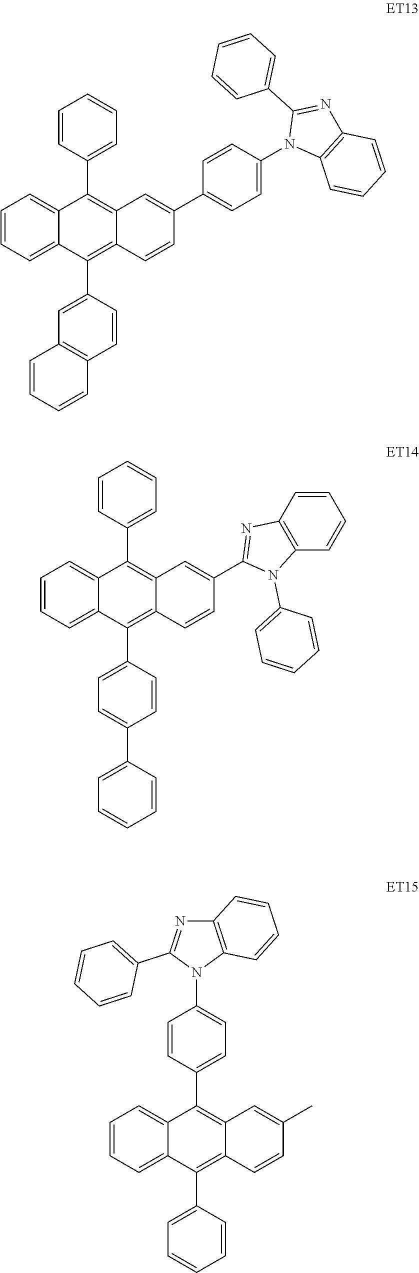 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

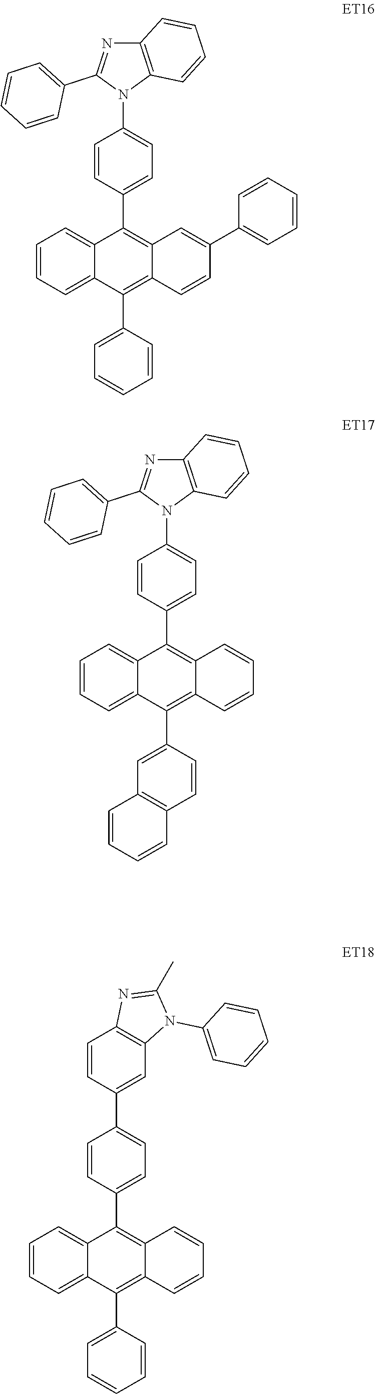 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

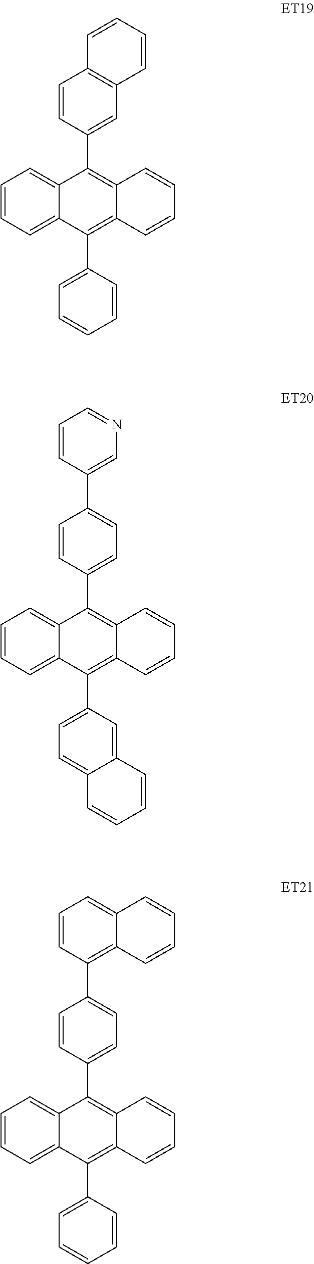

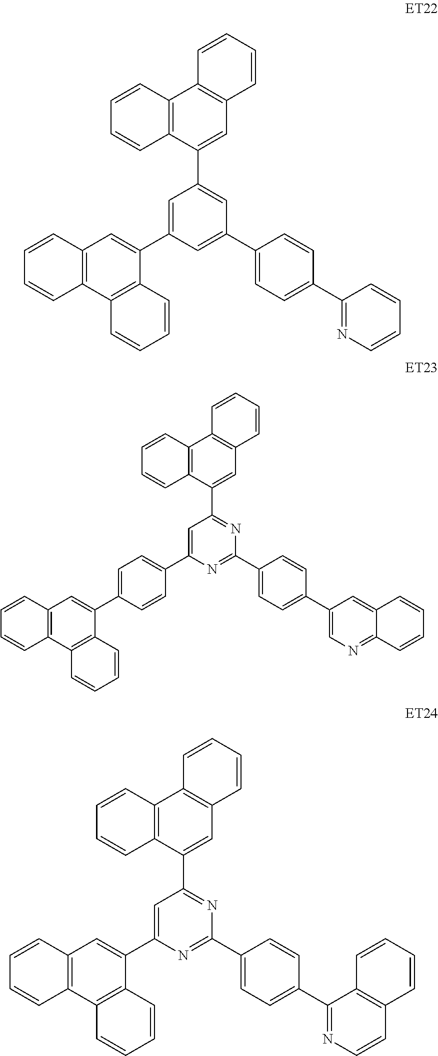 [SMILES: c1ccc(-c2ccc(-c3cc(-c4cc5ccccc5c5ccccc45)cc(-c4cc5ccccc5c5ccccc45)c3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

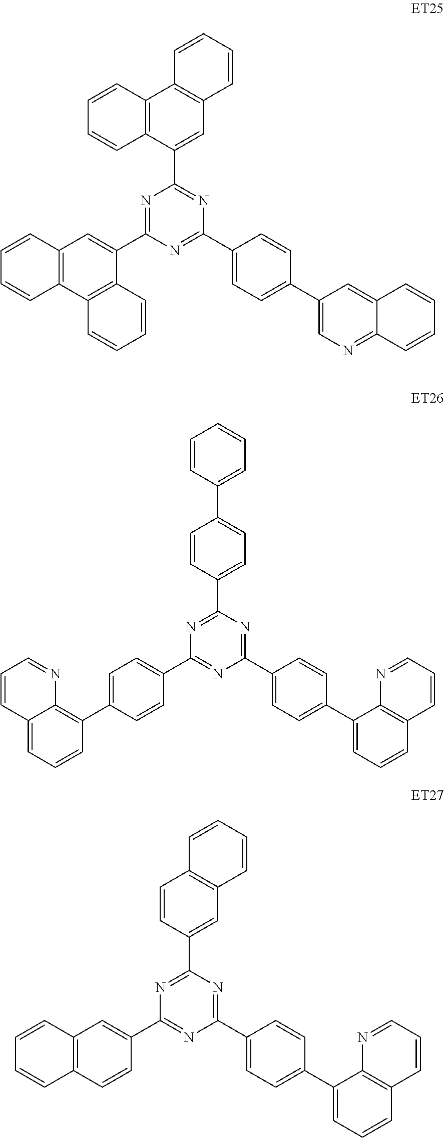 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

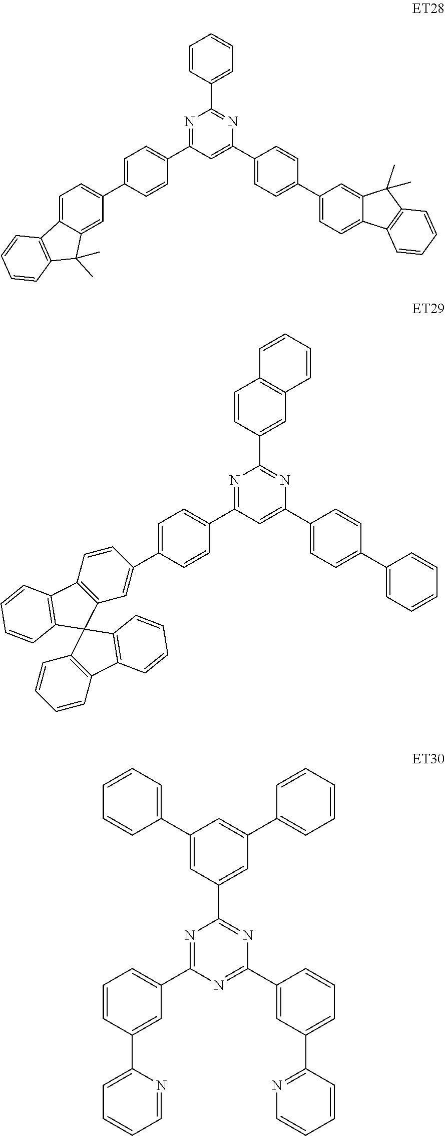 [SMILES: CC1(C)c2ccccc2-c2ccc(-c3ccc(-c4cc(-c5ccc(-c6ccc7c(c6)C(C)(C)c6ccccc6-7)cc5)nc(-c5ccccc5)n4)cc3)cc21 ; c1ccc(-c2ccc(-c3cc(-c4ccc(-c5ccc6c(c5)C5(c7ccccc7-c7ccccc75)c5ccccc5-6)cc4)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

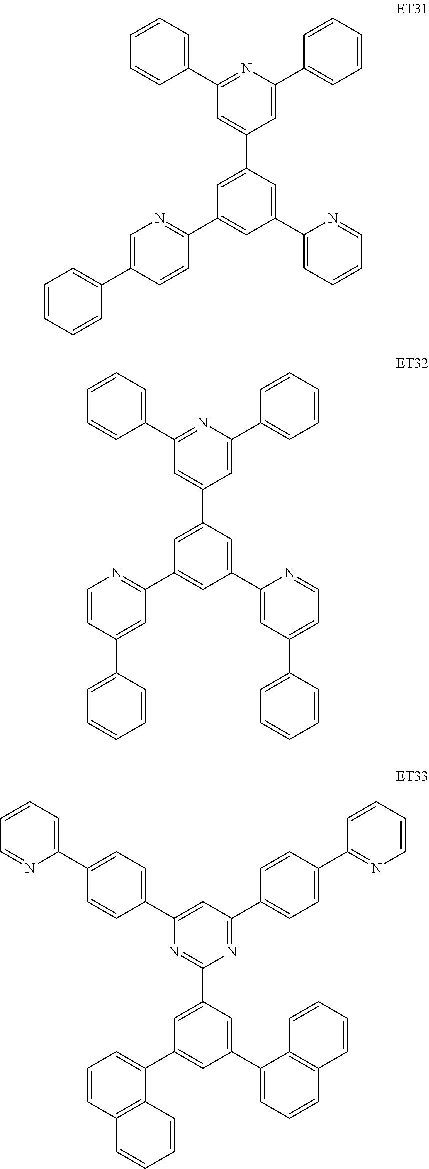 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

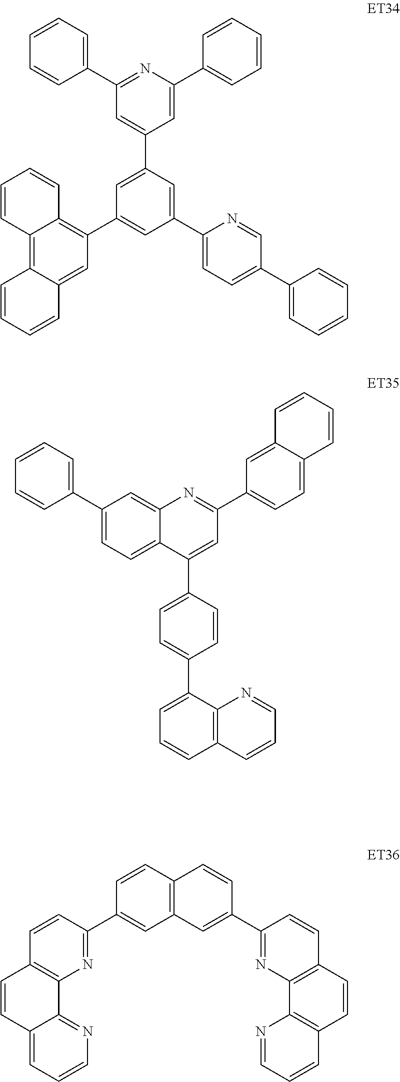 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

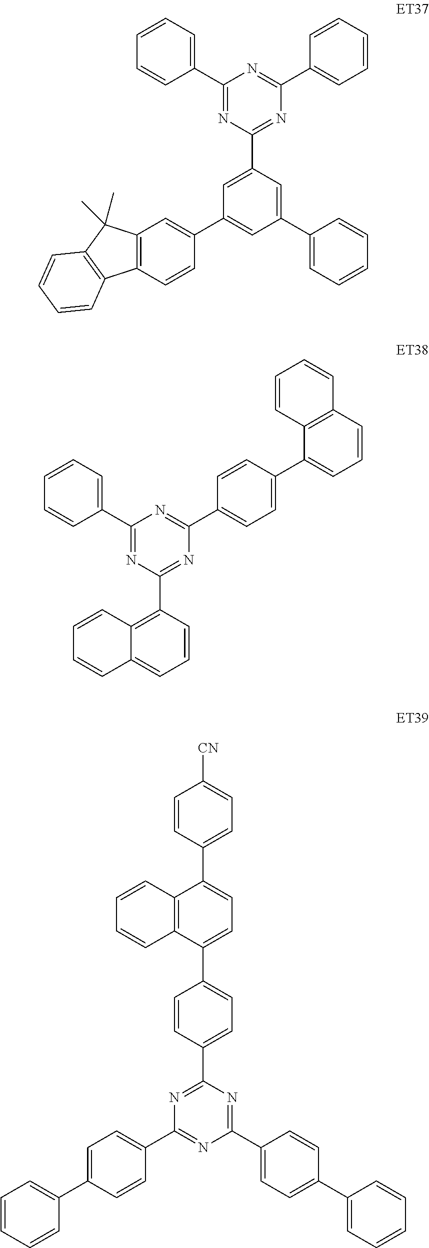 [SMILES: CC1(C)c2ccccc2-c2ccc(-c3cc(-c4ccccc4)cc(-c4nc(-c5ccccc5)nc(-c5ccccc5)n4)c3)cc21 ; c1ccc(-c2nc(-c3ccc(-c4cccc5ccccc45)cc3)nc(-c3cccc4ccccc34)n2)cc1 ; N#Cc1ccc(-c2ccc(-c3ccc(-c4nc(-c5ccc(-c6ccccc6)cc5)nc(-c5ccc(-c6ccccc6)cc5)n4)cc3)c3ccccc23)cc1]

In addition, the first upper functional layer UFL-L and the second upper functional layer UFL-T may include a metal halide such as LiF, NaCl, CsF, RbCl, RbI, CuI, and KI, a lanthanide metal such as Yb, and a co-deposited material of the metal halide and the lanthanide metal. For example, the first upper functional layer UFL-L and the second upper functional layer UFL-T may include KI:Yb, RbI:Yb, LiF:Yb, etc., as a co-deposited material. Meanwhile, the first upper functional layer UFL-L and the second upper functional layer UFL-T may be formed using a metal oxide such as Li₂O or BaO, or 8-hydroxyl-lithium quinolate (Liq), etc., but aspects of the present disclosure are not limited thereto. The first upper functional layer UFL-L and the second upper functional layer UFL-T may also be formed of a mixture material of an electron transport material and an insulating organometallic salt. The organometallic salt may be a material having an energy band gap of about 4 eV or more. Specifically, the organometallic salt may include, for example, a metal acetate, a metal benzoate, a metal acetoacetate, a metal acetylacetonate, or a metal stearate.

The first upper functional layer UFL-L and the second upper functional layer UFL-T may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but aspects of the present disclosure are not limited thereto.

The lower functional layers LFL-L and LFL-T included in the light-emitting structures EU-L and EU-T may have a hole-transporting function or a function of an auxiliary light-emitting layer. The lower functional layers LFL-L and LFL-T may have a single layer formed of a single material, a single layer formed of a plurality of different materials, or a multilayer structure including a plurality of layers formed of a plurality of different materials. The lower functional layers LFL-L and LFL-T may be formed using various methods such as a vacuum deposition method, a spin coating method, a cast method, a Langmuir-Blodgett (LB) method, an inkjet printing method, a laser printing method, and a laser induced thermal imaging (LITI) method.

The lower functional layers LFL-L and LFL-T may include a compound represented by Formula H-1 below as a hole transport material:

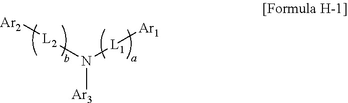

In Formula H-1 above, L₁ and L₂ may be each independently a direct linkage, a substituted or unsubstituted arylene group having 6 to 30 ring-forming carbon atoms, or a substituted or unsubstituted heteroarylene group having 2 to 30 ring-forming carbon atoms. a and b may be each independently an integer of 0 to 10. Meanwhile, when a or b is an integer of 2 or greater, a plurality of L₁'s and L₂'s may be each independently a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. In addition, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 above may be a monoamine compound. Alternatively, the compound represented by Formula H-1 above may be a diamine compound in which at least one among Ar₁ to Ar₃ includes the amine group as a substituent. In addition, the compound represented by Formula H-1 above may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one among the compounds in Compound Group H below. However, the compounds listed in Compound Group H below are examples, and the compounds represented by Formula H-1 are not limited to those represented by Compound Group H below:

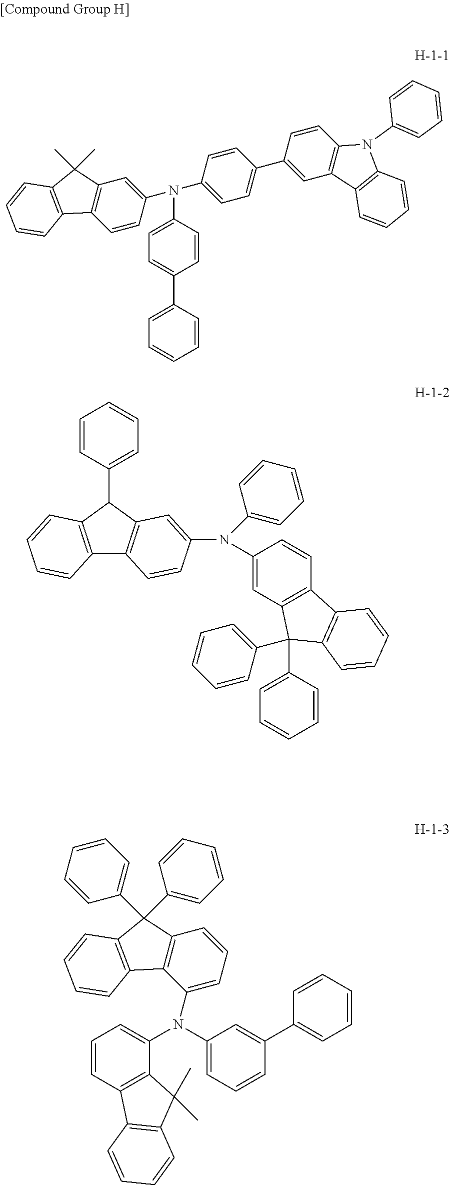 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(C2c3ccccc3-c3ccc(N(c4ccccc4)c4ccc5c(c4)C(c4ccccc4)(c4ccccc4)c4ccccc4-5)cc32)cc1 ; CC1(C)c2ccccc2-c2cccc(N(c3cccc(-c4ccccc4)c3)c3cccc4c3-c3ccccc3C4(c3ccccc3)c3ccccc3)c21]

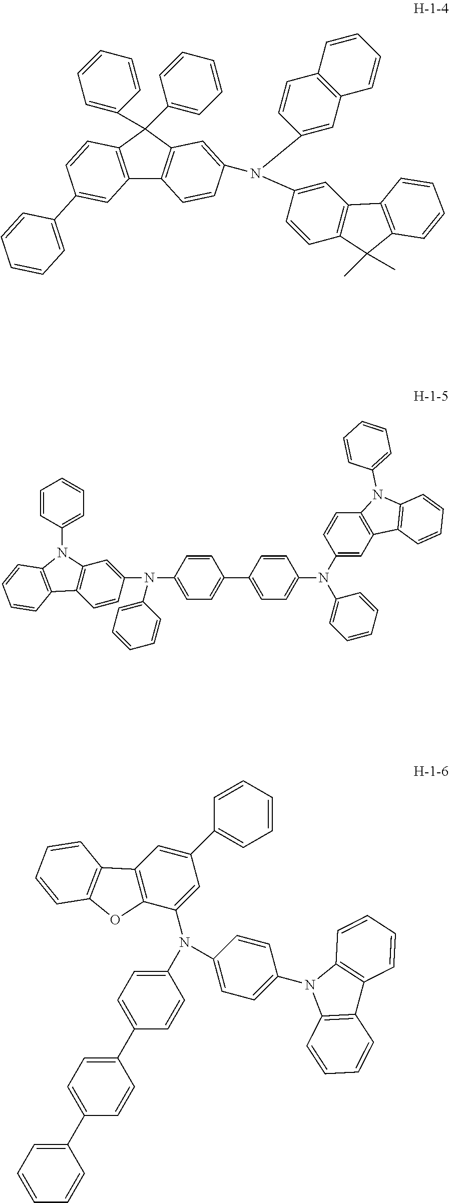 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

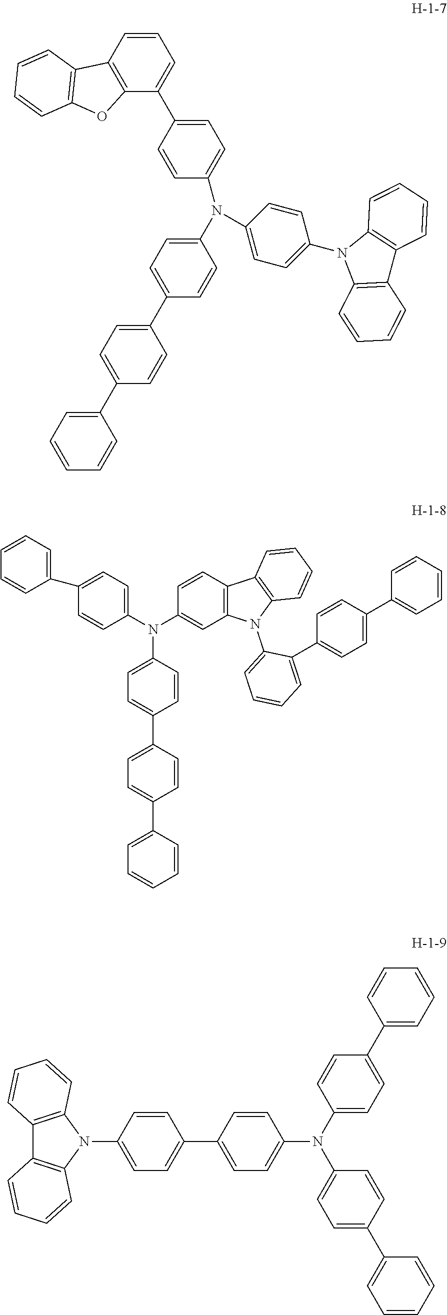 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

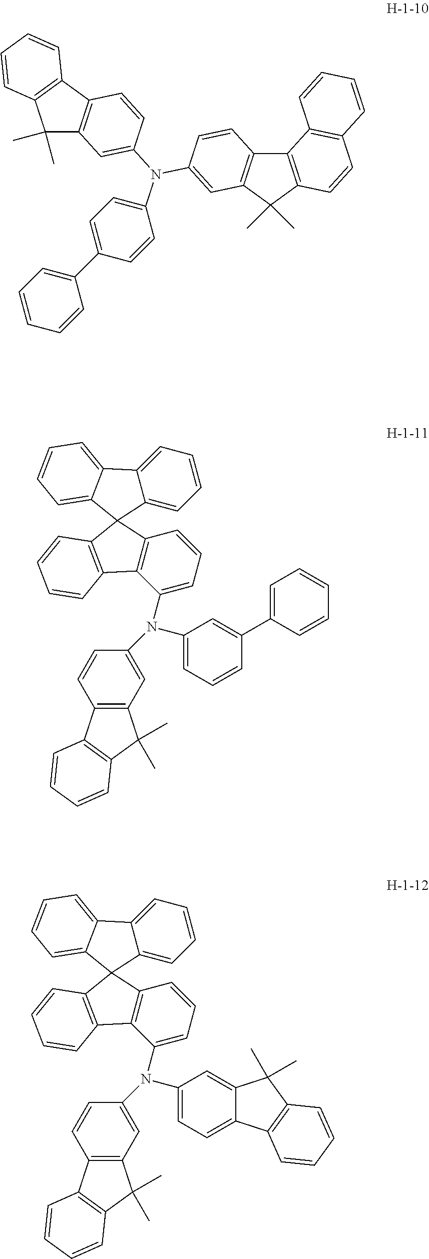 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2ccc(N(c3cccc(-c4ccccc4)c3)c3cccc4c3-c3ccccc3C43c4ccccc4-c4ccccc43)cc21 ; CC1(C)c2ccccc2-c2ccc(N(c3ccc4c(c3)C(C)(C)c3ccccc3-4)c3cccc4c3-c3ccccc3C43c4ccccc4-c4ccccc43)cc21]

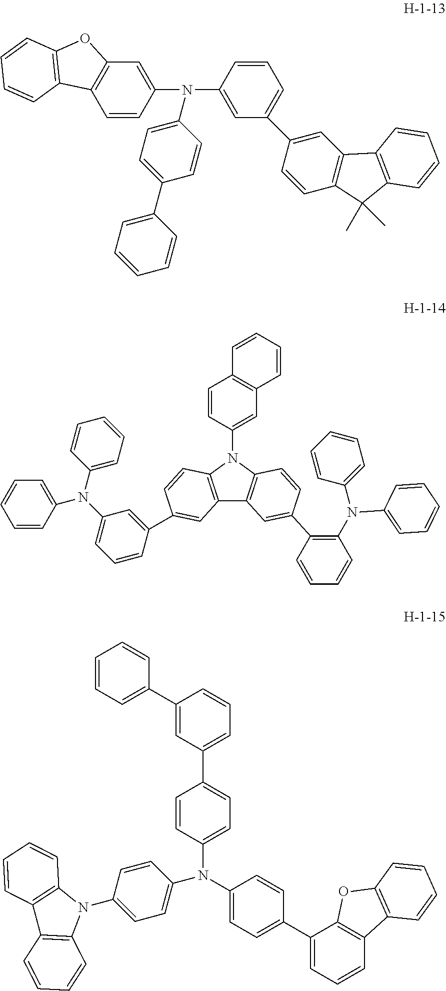 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2cccc(-c3ccc4c(c3)c3cc(-c5ccccc5N(c5ccccc5)c5ccccc5)ccc3n4-c3ccc4ccccc4c3)c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

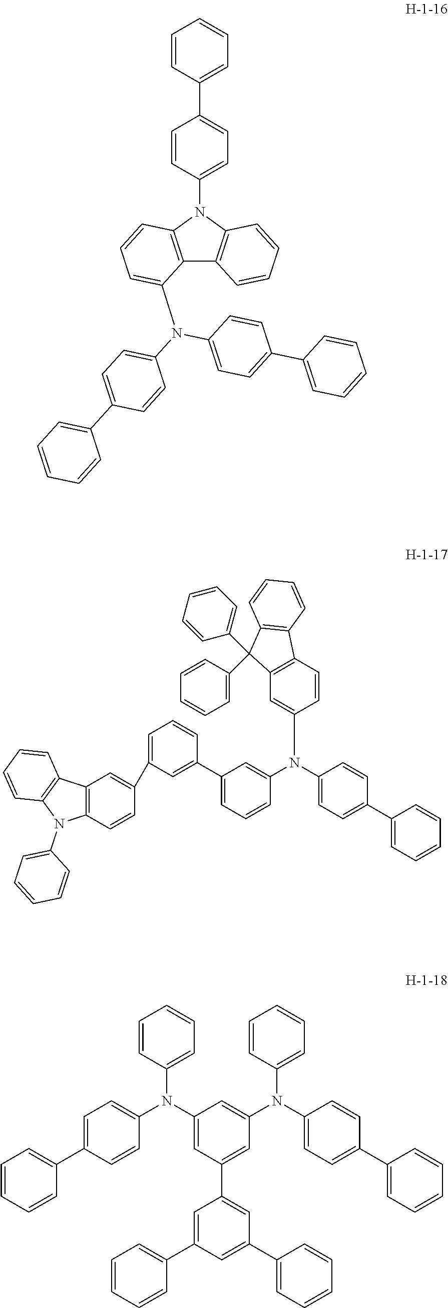 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

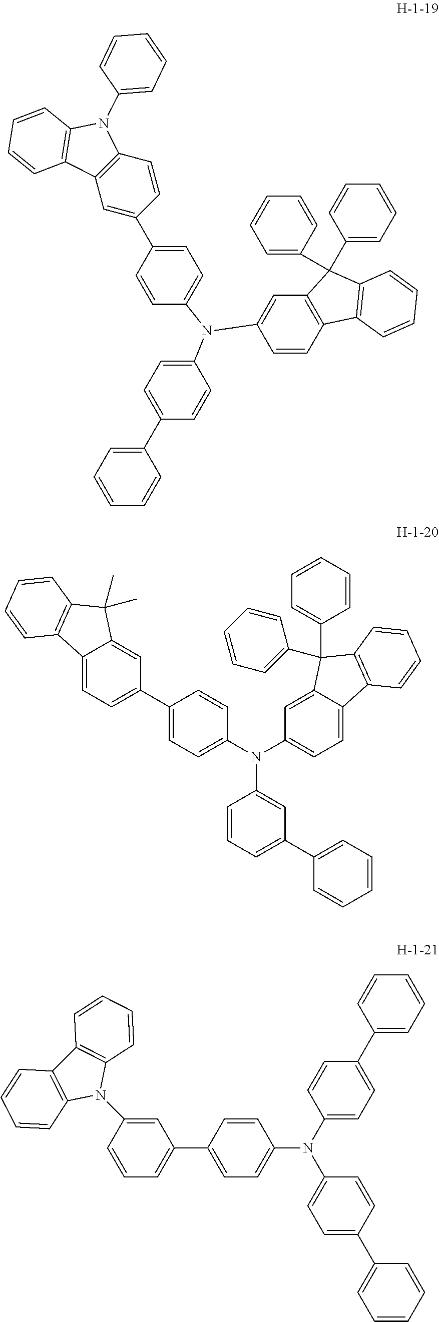 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; CC1(C)c2ccccc2-c2ccc(-c3ccc(N(c4cccc(-c5ccccc5)c4)c4ccc5c(c4)C(c4ccccc4)(c4ccccc4)c4ccccc4-5)cc3)cc21 ; c1ccc(-c2ccc(N(c3ccc(-c4ccccc4)cc3)c3ccc(-c4cccc(-n5c6ccccc6c6ccccc65)c4)cc3)cc2)cc1]

In an aspect, the first lower functional layer LFL-L and the second lower functional layer LFL-T may each independently include a known hole-transporting material. For example, the first lower functional layer LFL-L and the second lower functional layer LFL-T may include a phthalocyanine compound such as copper phthalocyanine; N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HAT-CN), etc.

The first lower functional layer LFL-L and the second lower functional layer LFL-T may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), etc.

In addition, the first lower functional layer LFL-L and the second lower functional layer LFL-T may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

In addition to the above-mentioned materials, the first lower functional layer LFL-L and the second lower functional layer LFL-T may further include a charge-generating material for improvement of conductivity. The charge-generating material may be dispersed uniformly or ununiformly in the first lower functional layer LFL-L and the second lower functional layer LFL-T. The charge generating material may be, for example, a p-dopant. The p-dopant may include at least one of a halogenated metal compound, a quinone derivative, a metal oxide, or a cyano group-containing compound, but aspects of the present disclosure are not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but aspects of the present disclosure are not limited thereto.

In the light-emitting element ED according to an aspect, the light-emitting layers EML-L and EML-T may be disposed on the respective lower functional layers LFL-L and LFL-T. For example, the first light-emitting layer EML-L may be disposed on the first lower functional layer LFL-L, and the second light-emitting layer EML-T may be disposed on the second lower functional layer LFL-T. The light-emitting layers EML-L and EML-T may each independently have a single layer made of a single material, a single layer made of a plurality of different materials, or a multi-layer structure including a plurality of layers made of a plurality of different materials. The light-emitting layer EML-L and EML-T may include at least one of a fluorescence light-emitting material or a phosphorescence light-emitting material. The light-emitting layer EML-L and EML-T may include the fluorescence light-emitting material and the phosphorescence light-emitting material as dopants. The light-emitting layer EML-L and EML-T may include a host material. In addition, at least one of the light-emitting layers EML-L or EML-T may include both of a hole transport host and an electron transport host.

In the light-emitting element ED according to an aspect, the light-emitting layer EML-L and EML-T may include two types of hosts and one dopant. Aspects of the present disclosure are not limited thereto, and the light-emitting layer EML-L and EML-T may include two types of hosts and two or more dopants.

The light-emitting element ED according to an aspect may include two types of hosts and one dopant at least in the second light-emitting layer EML-T among the light-emitting layers EML-L and EML-T. For example, the second light-emitting layer EML-T of the light-emitting element ED may include a first host, a second host, and a dopant. In addition, the first light-emitting layer EML-T and the second light-emitting layer EML-T of the light-emitting element ED may each include a first host, a second host, and a dopant. The first host may be different from the second host.

The first hosts included in the first light-emitting layer EML-L and the second light-emitting layer EML-T may be the same, or different from each other. The second hosts included in the first light-emitting layer EML-L and the second light-emitting layer EML-T may be the same, or different from each other. In addition, the dopants included in the first light-emitting layer EML-L and the second light-emitting layer EML-T may be the same, or different from each other. In an aspect, the first host, the second host, and the dopant included in the first light-emitting layer EML-L may be the same as the first host, the second host, and the dopant included in the second light-emitting layer EML-T, respectively.

The first host may include an anthracene moiety and a dibenzofuran moiety. In the first host, the dibenzofuran moiety may be directly connected to the anthracene moiety, or may be connected through a linker. For example, the first host may be represented by Formula 1 below.

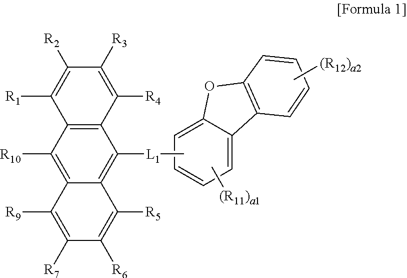

In Formula 1, L₁ may be a direct linkage, or a substituted or unsubstituted arylene group of 6 to 30 ring-forming carbon atoms. For example, L₁ may be a direct linkage, or an unsubstituted phenylene group, but aspects of the present disclosure are not limited thereto.

In Formula 1, R₁ to R₇ and R₉ to Ru may be each independently a hydrogen atom, a deuterium atom, or a substituted or unsubstituted aryl group of 6 to 30 ring-forming carbon atoms. For example, R₁ to R₇, R₉, and Ru may be all hydrogen atoms. R₁₀ may be a substituted or unsubstituted phenyl group, a substituted or unsubstituted naphthyl group, or a substituted or unsubstituted biphenyl group, but aspects of the present disclosure are not limited thereto.

In Formula 1, R₁₂ may be a hydrogen atom, a deuterium atom, a hydroxy group, a substituted or unsubstituted oxy group, a substituted or unsubstituted alkyl group of 1 to 30 carbon atoms, a substituted or unsubstituted alkenyl group of 2 to 30 carbon atoms, or a substituted or unsubstituted aryl group of 6 to 30 ring-forming carbon atoms, or may be bonded to an adjacent group to form a ring. For example, R₁₂ may be a hydrogen atom, a substituted or unsubstituted phenyl group, or a substituted or unsubstituted naphthyl group. In addition, a pair of R₁₂ adjacent to each other, selectively, may be bonded to form a hydrocarbon ring or a hetero ring.

In Formula 1, a1 may be an integer of 0 to 3. When a1 is 0, the first host according to an aspect may not be substituted with R₁₁. In Formula 1, when a1 is 3, and three R₁₁ are all hydrogen atoms, this may be the same as the case when a1 is 0. When a1 is an integer of 2 or greater, R₁₁ provided in plurality may be all the same, or at least one of the plurality of R₁₁ may be different.

In Formula 1, a2 may be an integer of 0 to 4. When a2 is 0, the first host according to an aspect may not be substituted with R₁₂. In Formula 1, when a2 is 4, and four R₁₂ are all hydrogen atoms, this may be the same as the case when a2 is 0 in Formula 1. When a2 is an integer of 2 or greater, R₁₂ provided in plurality may be all the same, or at least one of the plurality of R₁₂ may be different.

For example, Formula 1 may be expressed by Formula 1-A or Formula 1-B, but aspects of the present disclosure are not limited thereto.

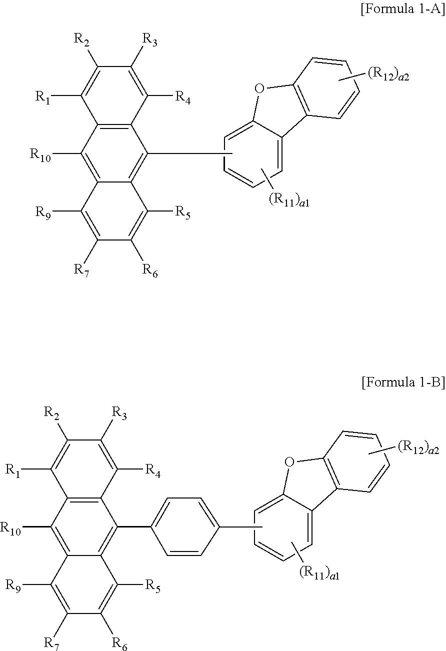

In Formula 1-A and Formula 1-B, R₁ R₇, R₉ to R₁₂, a1, and a2 may each be applied with the same content as the content described in Formula 1.

The first host may be represented by any one of compounds in Compound Group 1 below. The light-emitting layers EML-L and EML-T included in the light-emitting structures EU-L and EU-T may include a first host in Compound Group 1. At least the second light-emitting layer EML-T, among the light-emitting layers EML-L and EML-T, may include at least one of the compounds in Compound Group 1 as the first host.

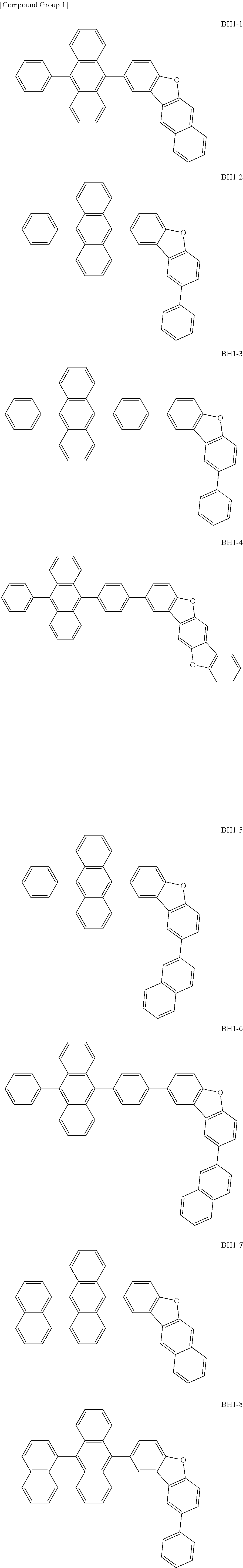

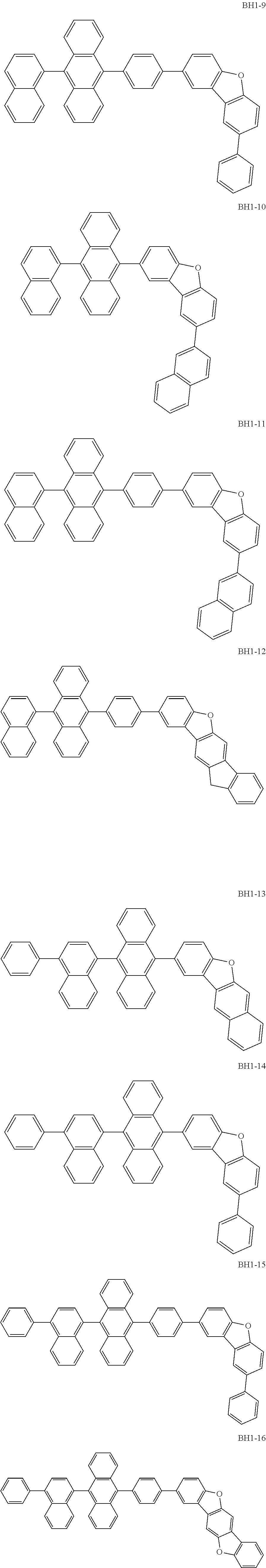

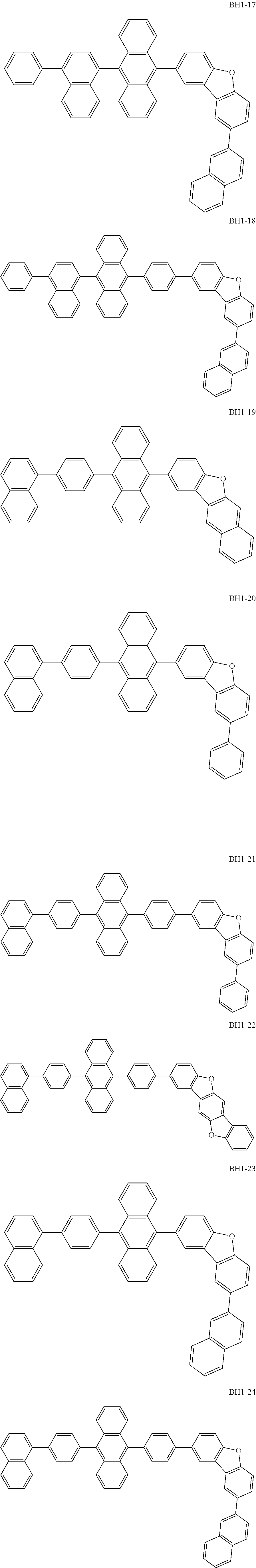

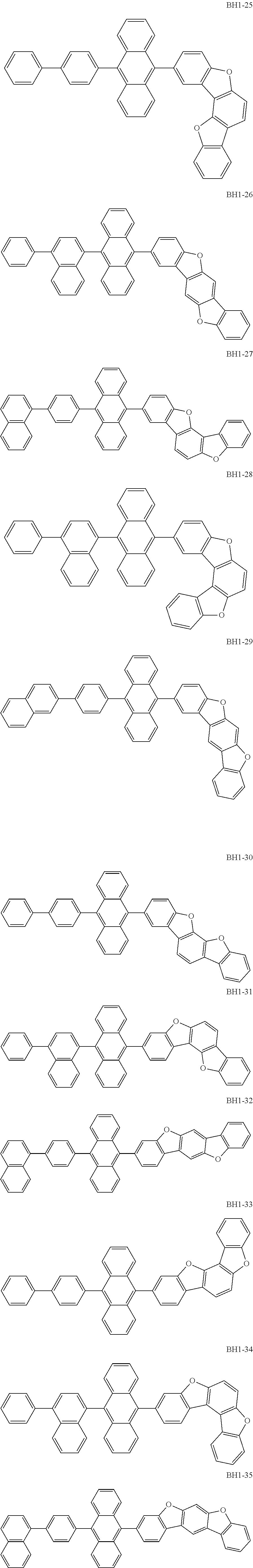

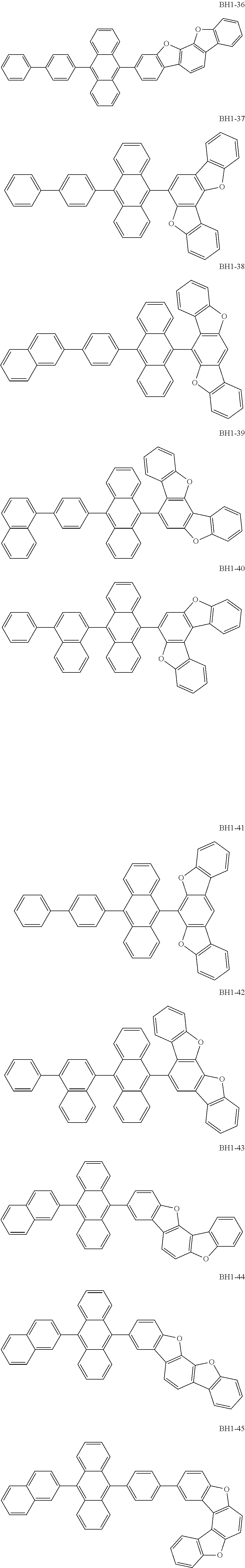

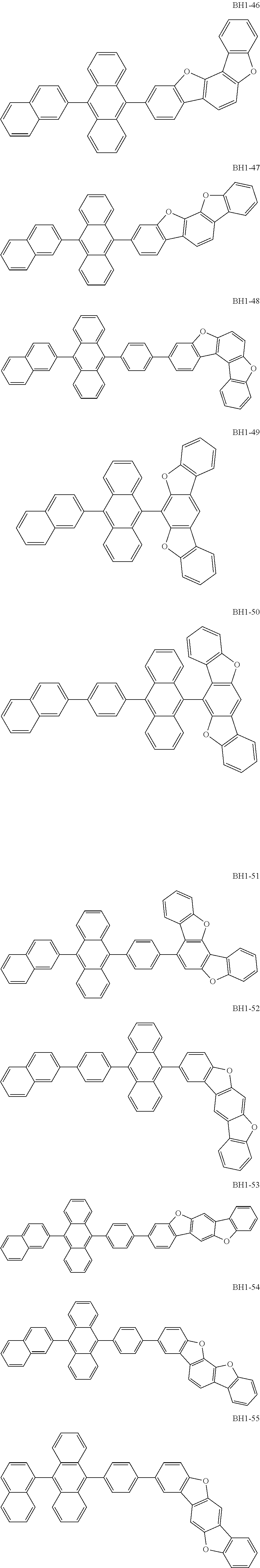

In an aspect, a highest occupied molecular orbital (HOMO) energy level of the first host, represented by Formula 1, may be about −5.1 eV or greater, and a lowest unoccupied molecular orbital (LUMO) energy level may be about −1.6 eV or less. In addition, a highest occupied molecular orbital (HOMO) energy level of each of the compounds in Compound Group 1 may be about −5.1 eV or greater, and a lowest unoccupied molecular orbital (LUMO) energy level may be about −1.6 eV or less.

The second host may include an anthracene moiety and a fluorene moiety in a spiro structure. In the second host, the fluorene moiety in a spiro structure may be directly connected to the anthracene moiety, or may be connected through a linker. For example, the second host may be represented by Formula 2 below.

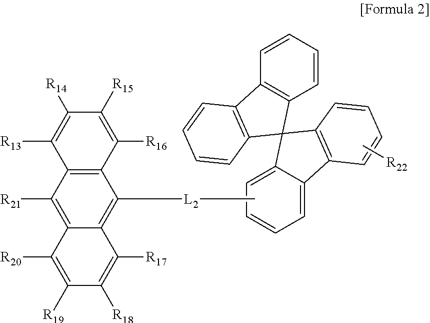

In Formula 2, L₂ may be a direct linkage, or a substituted or unsubstituted arylene group of 6 to 30 ring-forming carbon atoms. For example, L₂ may be a direct linkage, or an unsubstituted phenylene group.

In Formula 2, R₁₃ to R₂₁ may be each independently a hydrogen atom, a deuterium atom, or a substituted or unsubstituted aryl group of 6 to 30 ring-forming carbon atoms. For example, R₁₃ to R₂₀ may be all hydrogen atoms. R₂₁ may be a substituted or unsubstituted phenyl group, a substituted or unsubstituted naphthyl group, or a substituted or unsubstituted biphenyl group, but aspects of the present disclosure are not limited thereto.

In Formula 2, R₂₂ is a substituted or unsubstituted aryl group of 6 to 30 ring-forming carbon atoms. For example, R₂₂ may be a substituted or unsubstituted phenyl group, a substituted or unsubstituted biphenyl group, or a substituted or unsubstituted naphthyl group, but aspects of the present disclosure are not limited thereto.

For example, Formula 2 may be expressed by Formula 2-A or Formula 2-B, but aspects of the present disclosure are not limited thereto.

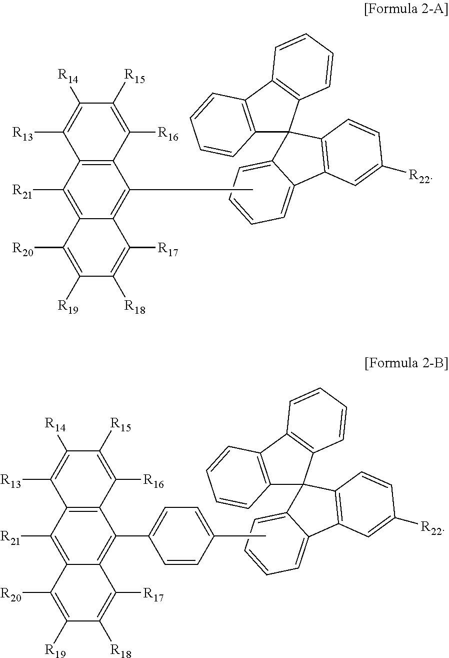

In Formula 2-A and Formula 2-B, R₁₃ to R₂₂ may each be applied with the same content as the content described in Formula 2.

The second host may be represented by any one of compounds in Compound Group 2 below. The light-emitting layers EML-L and EML-T included in the light-emitting structures EU-L and EU-T may include a second host in Compound Group 2. At least the second light-emitting layer EML-T among the light-emitting layers EML-L and EML-T may include at least one of the compounds in Compound Group 2 as the second host.

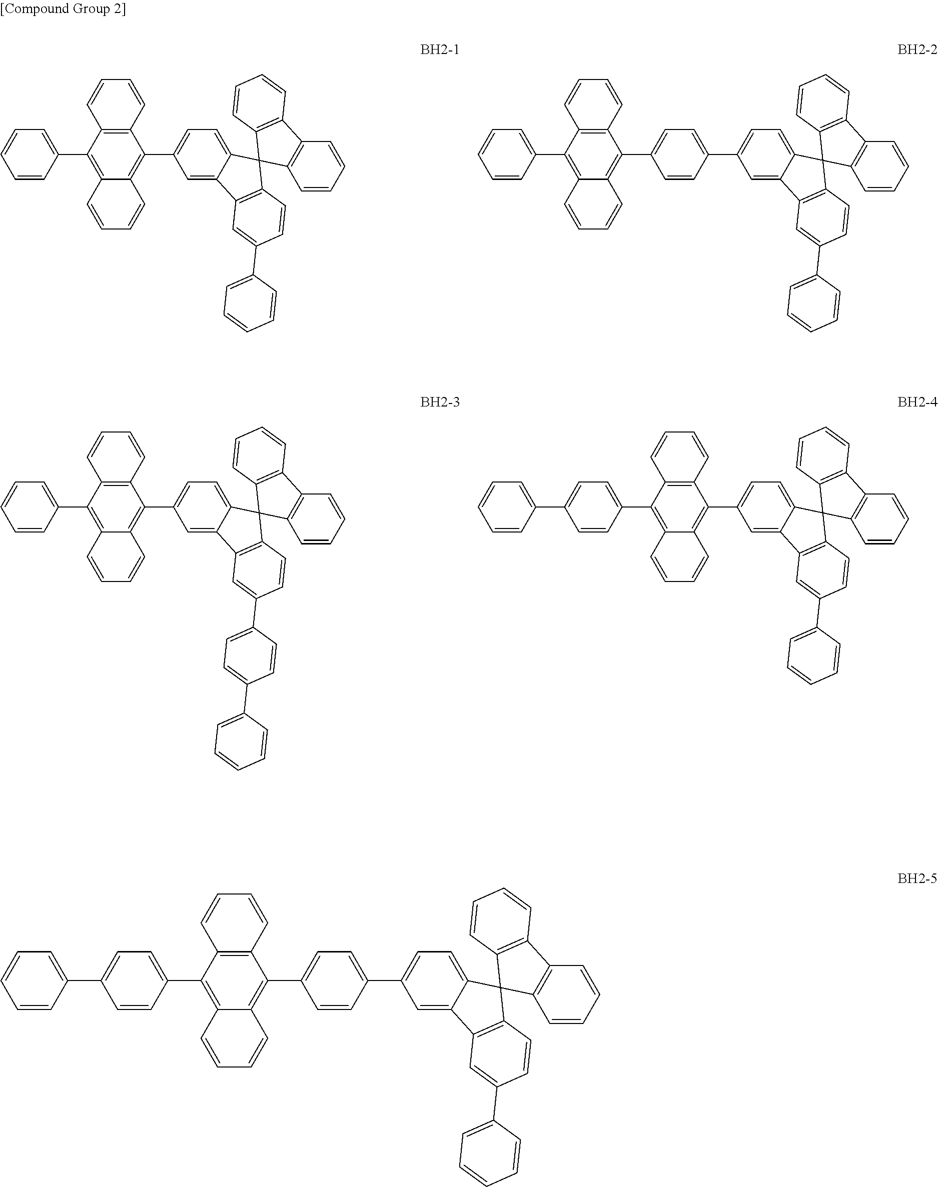

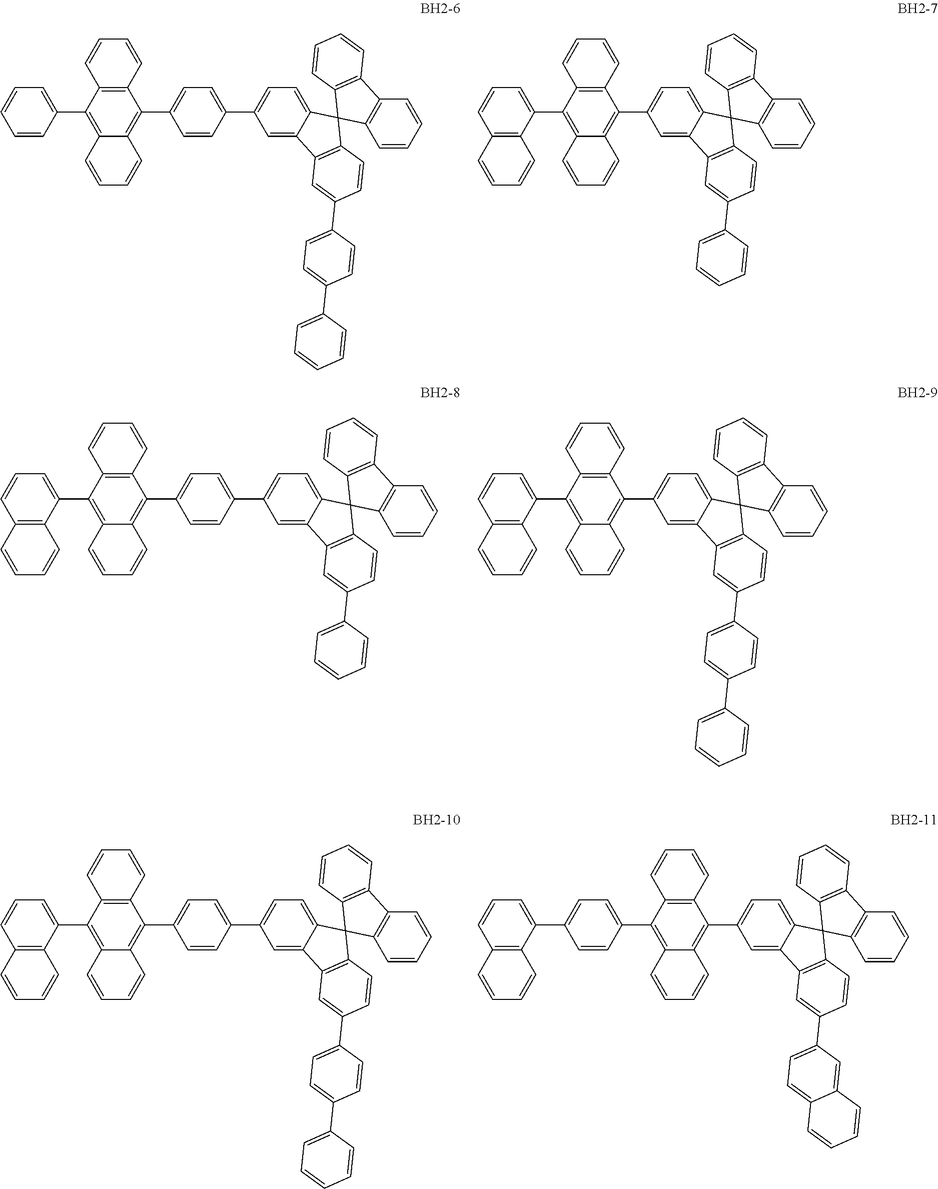

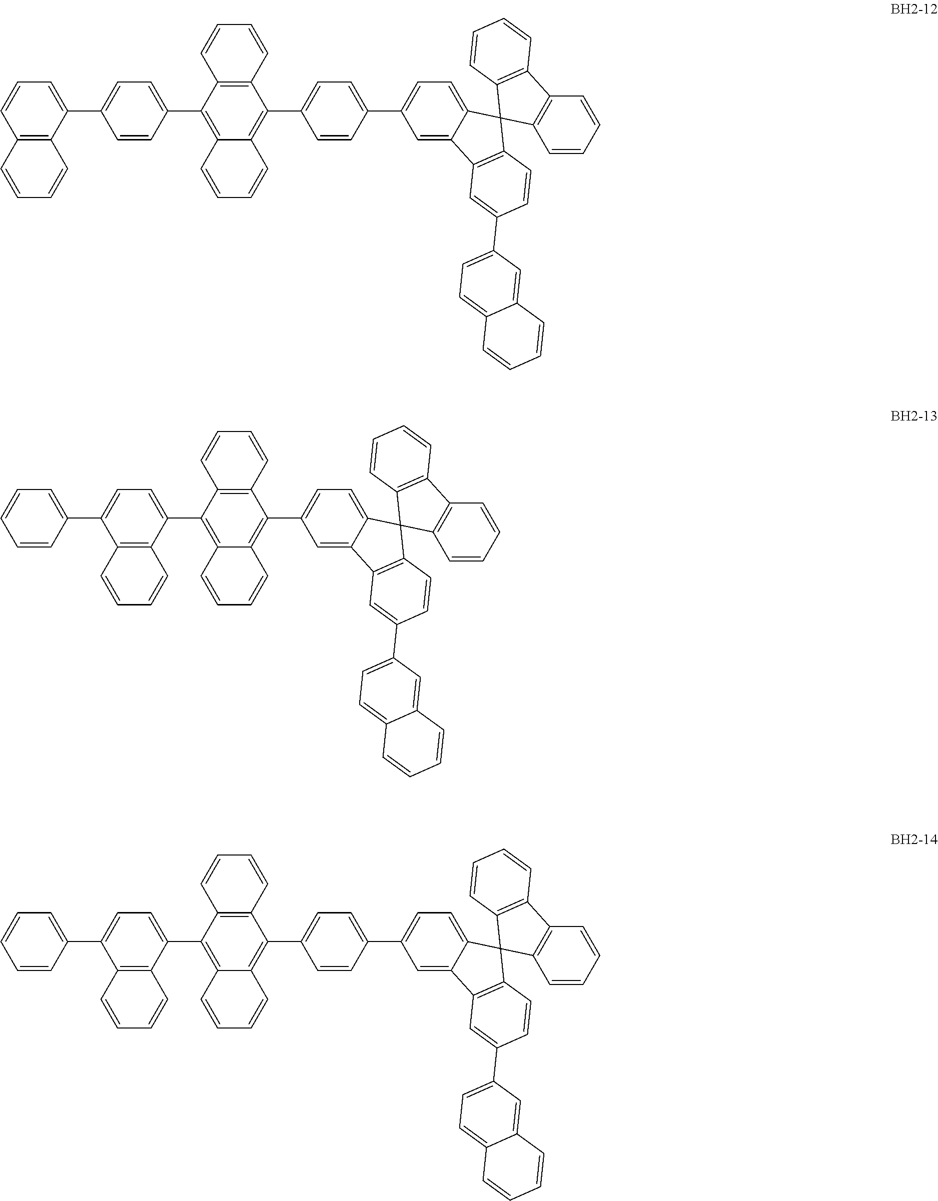

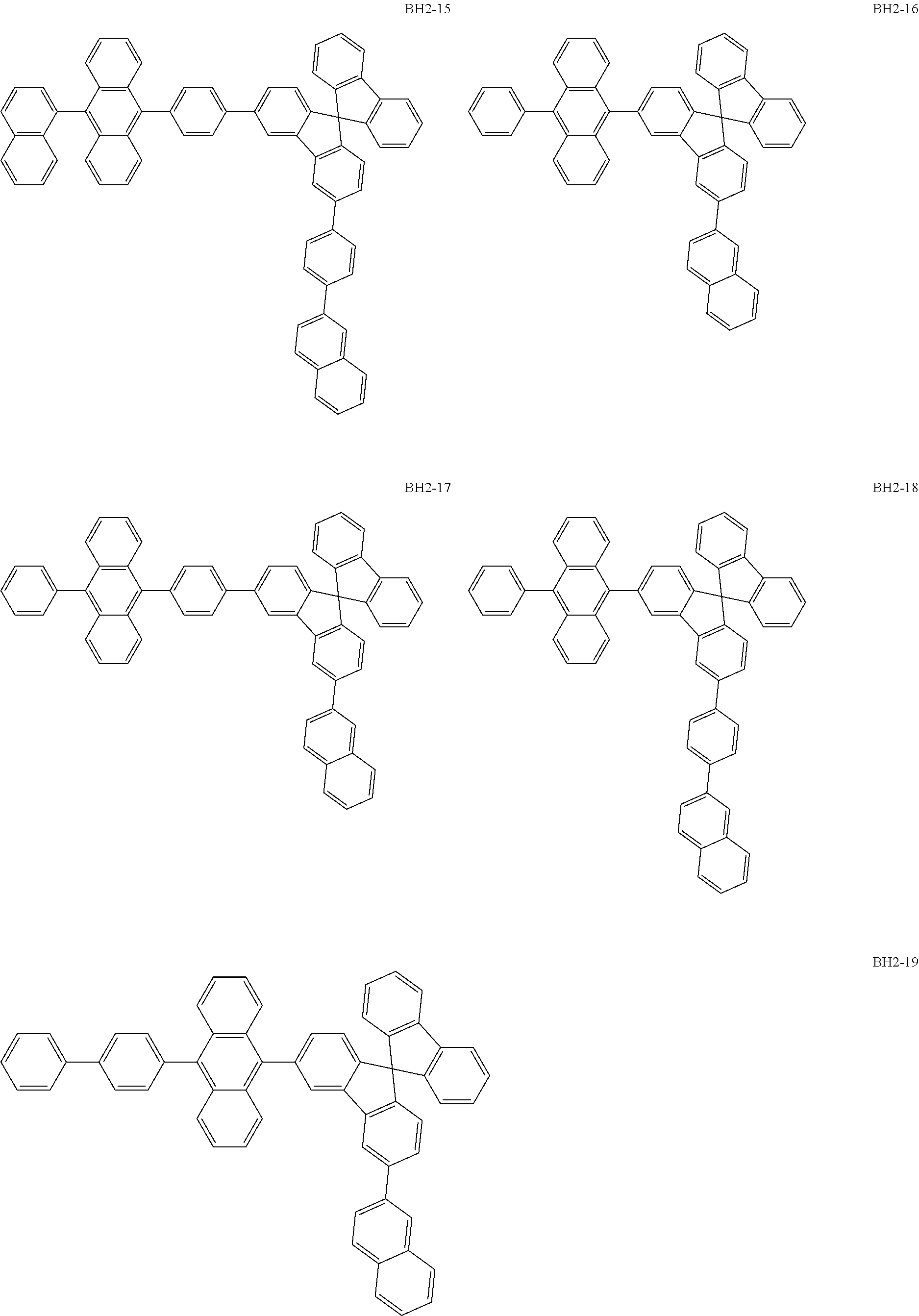

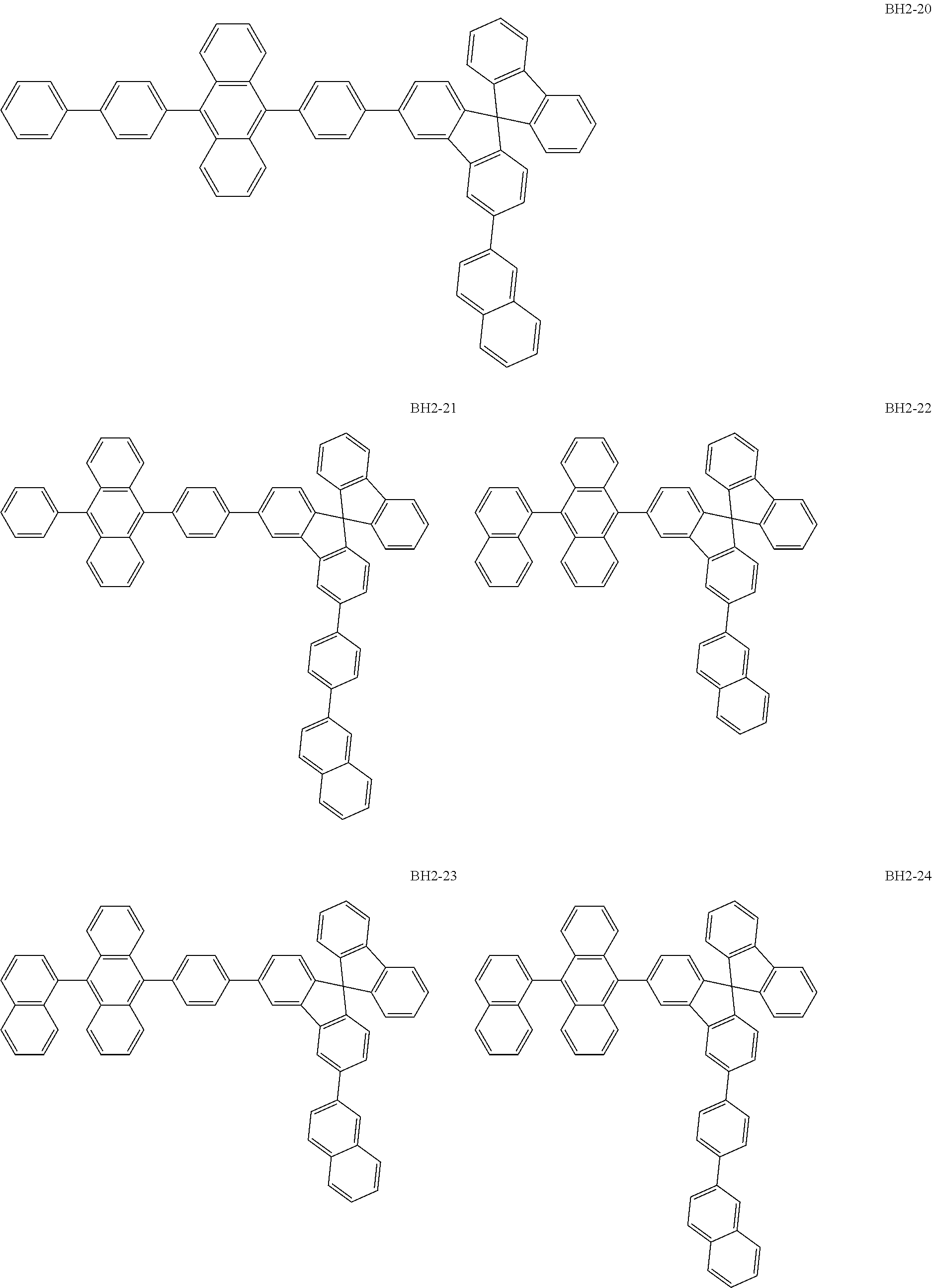

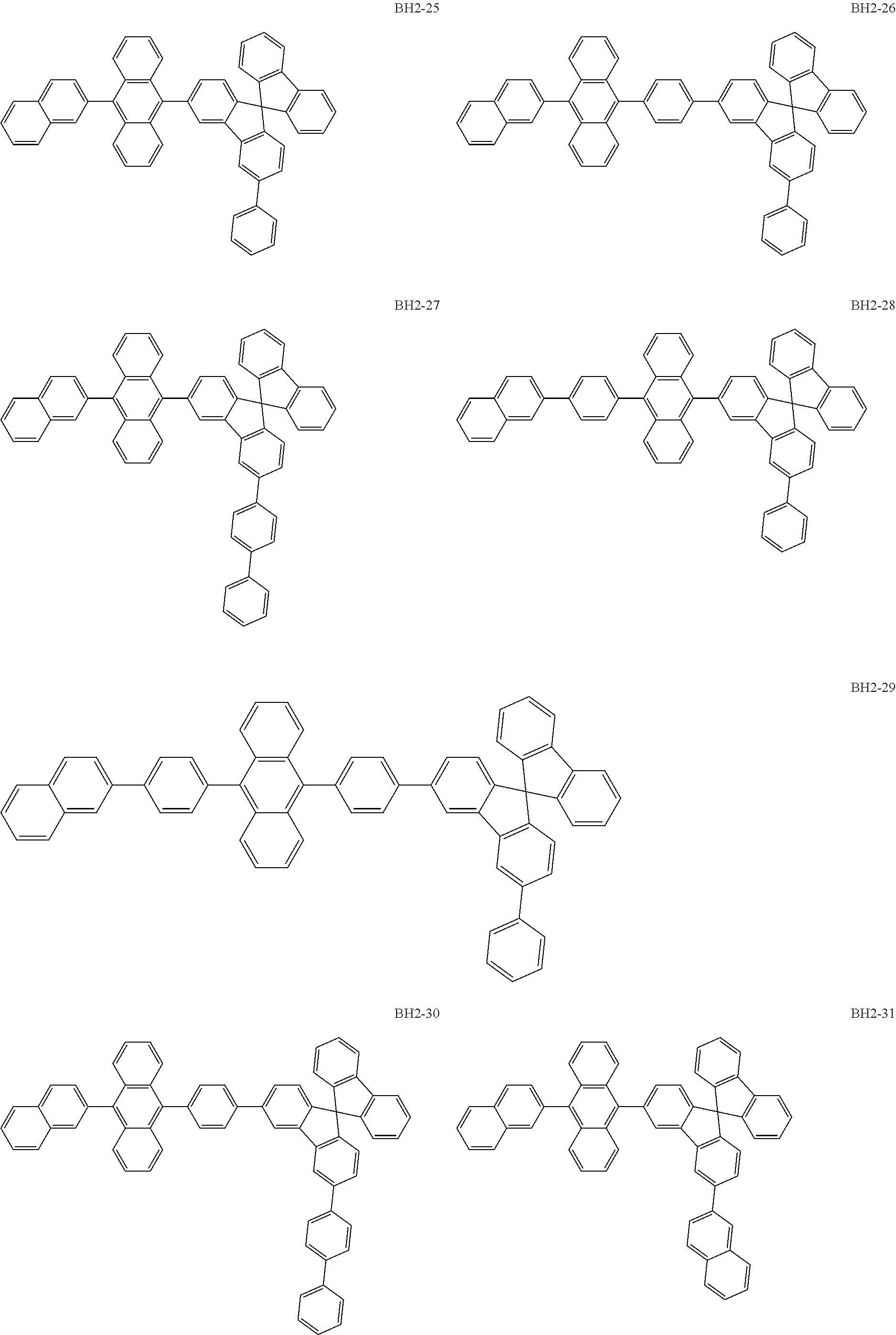

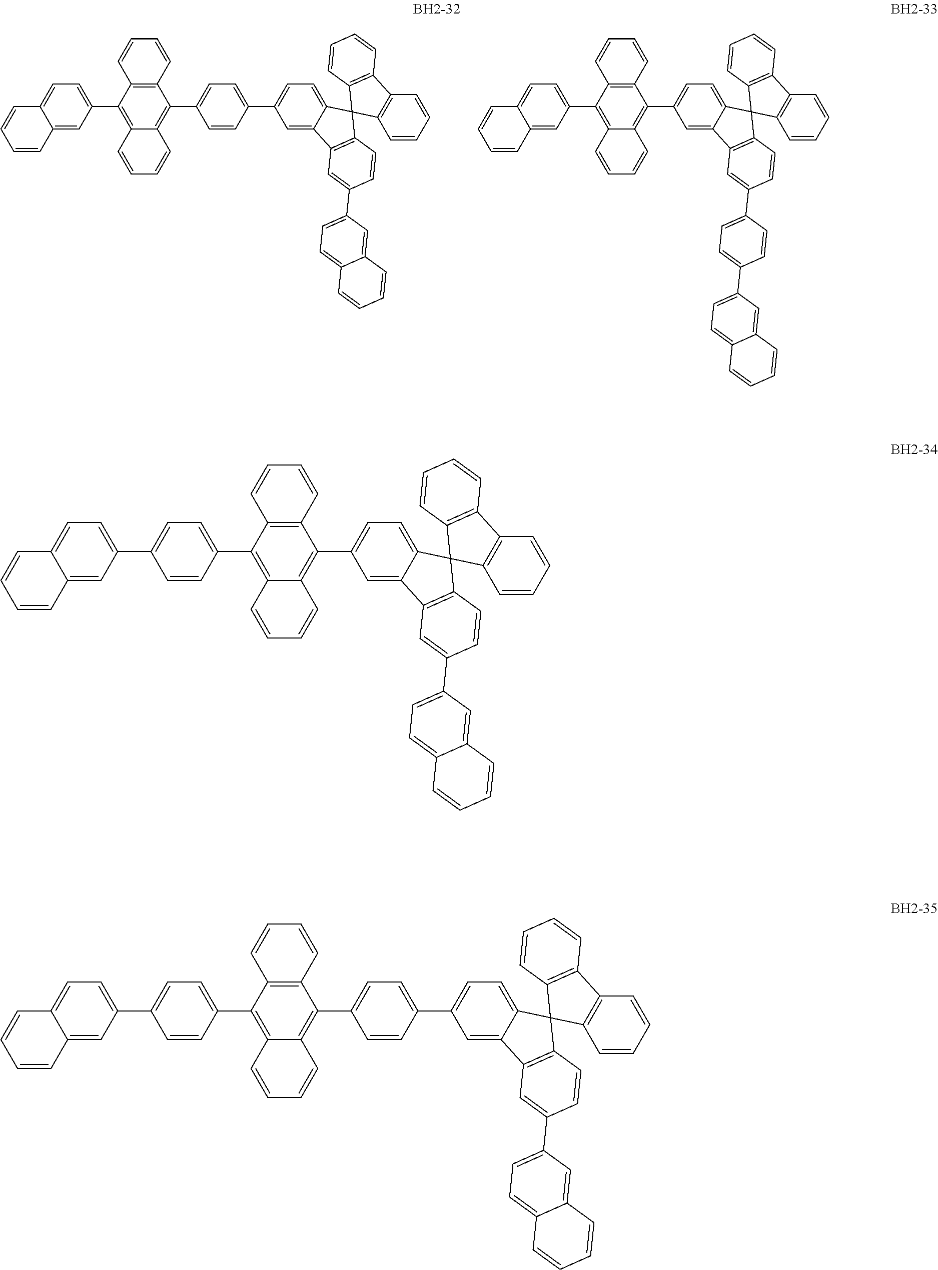

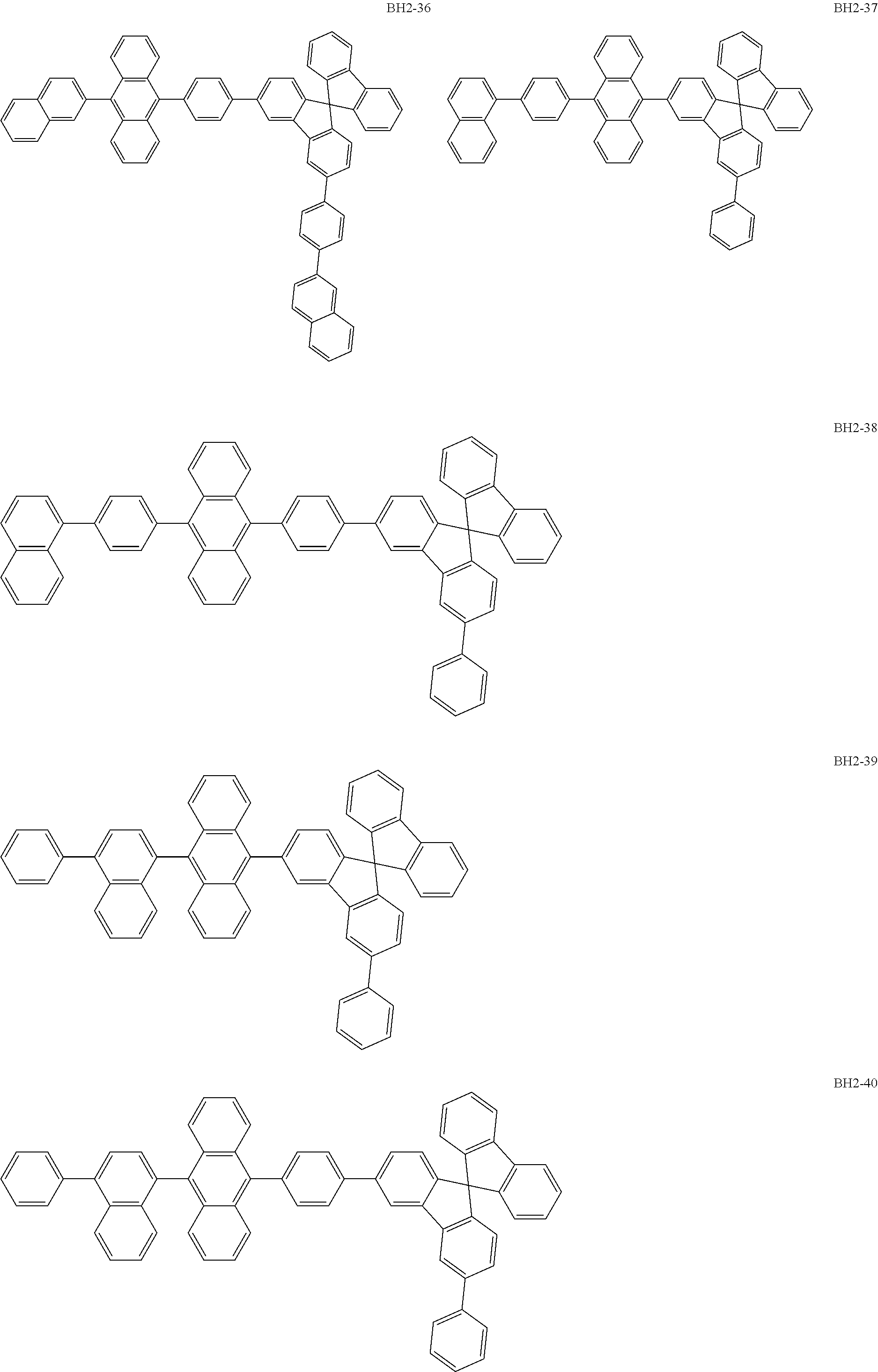

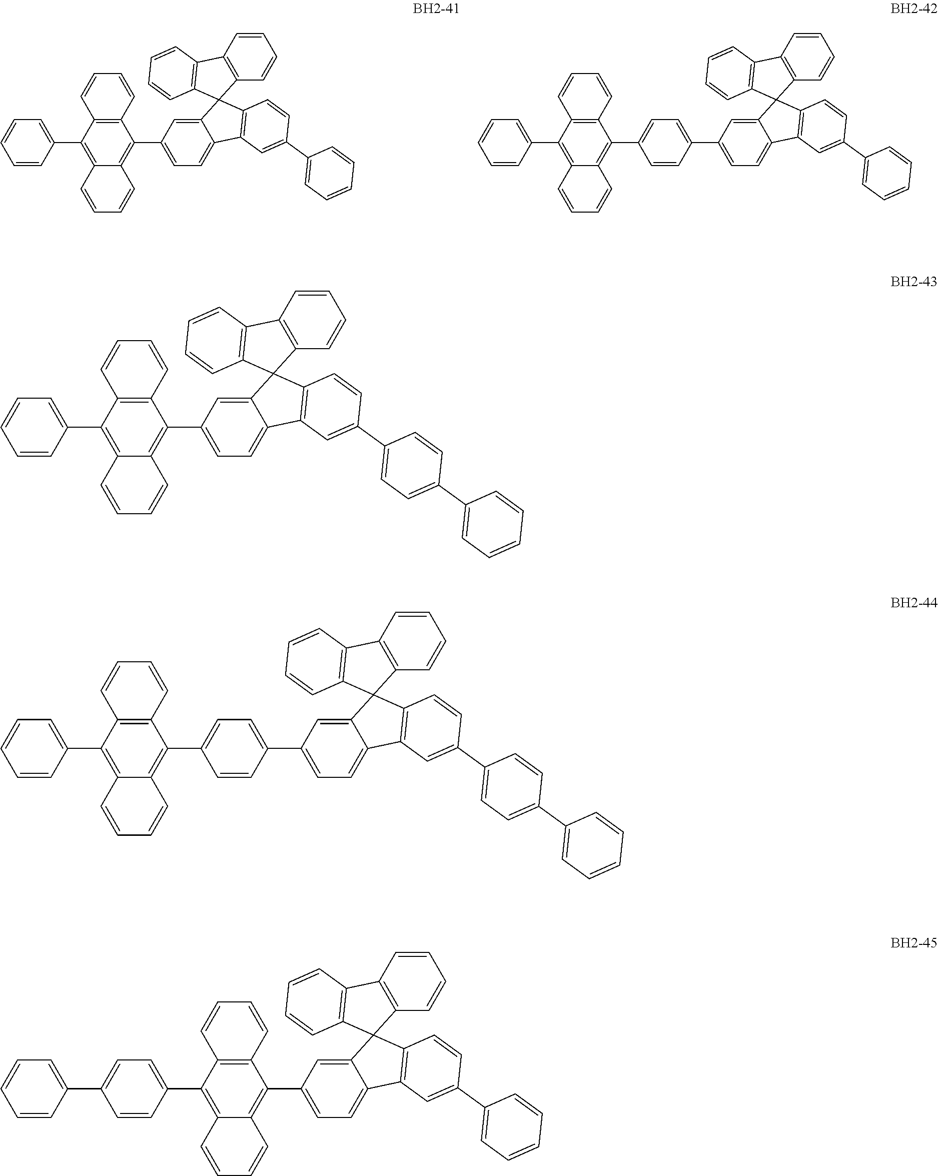

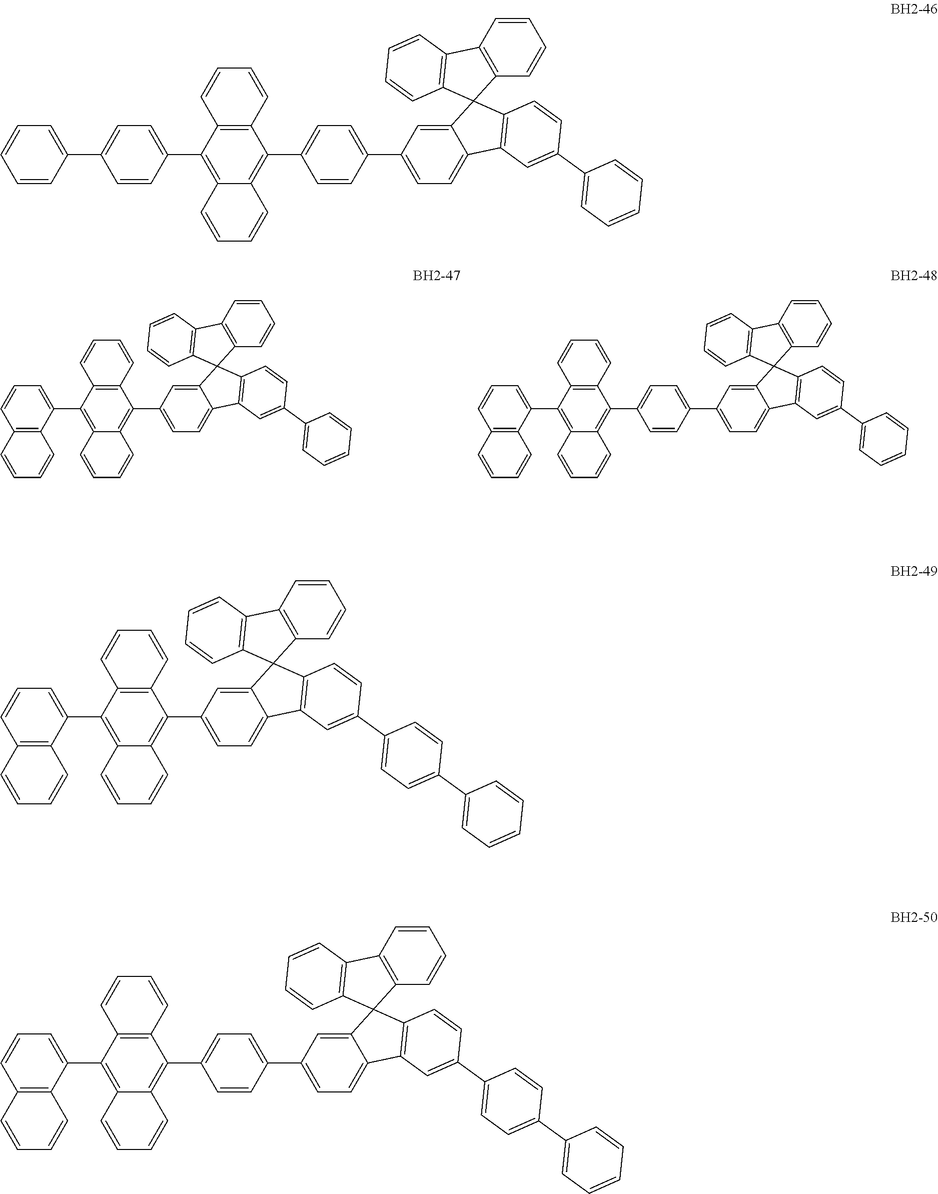

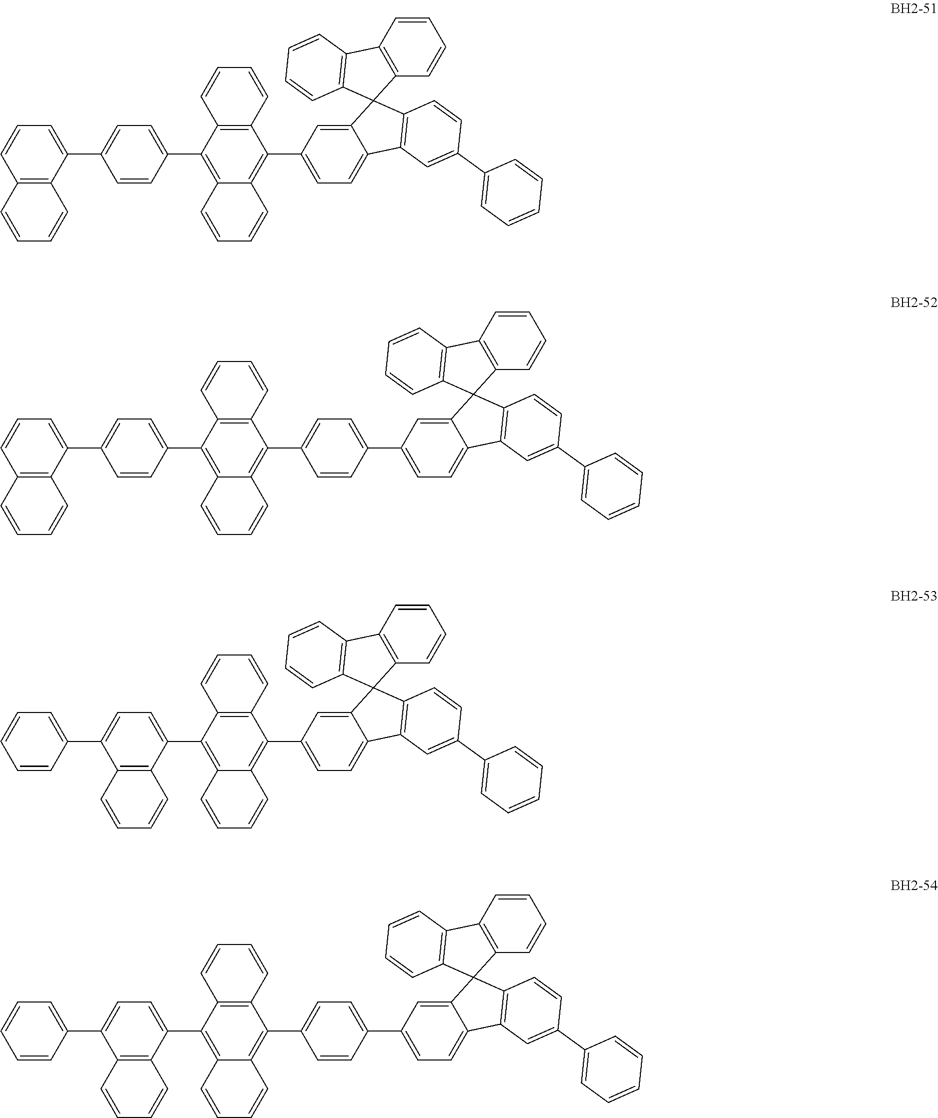

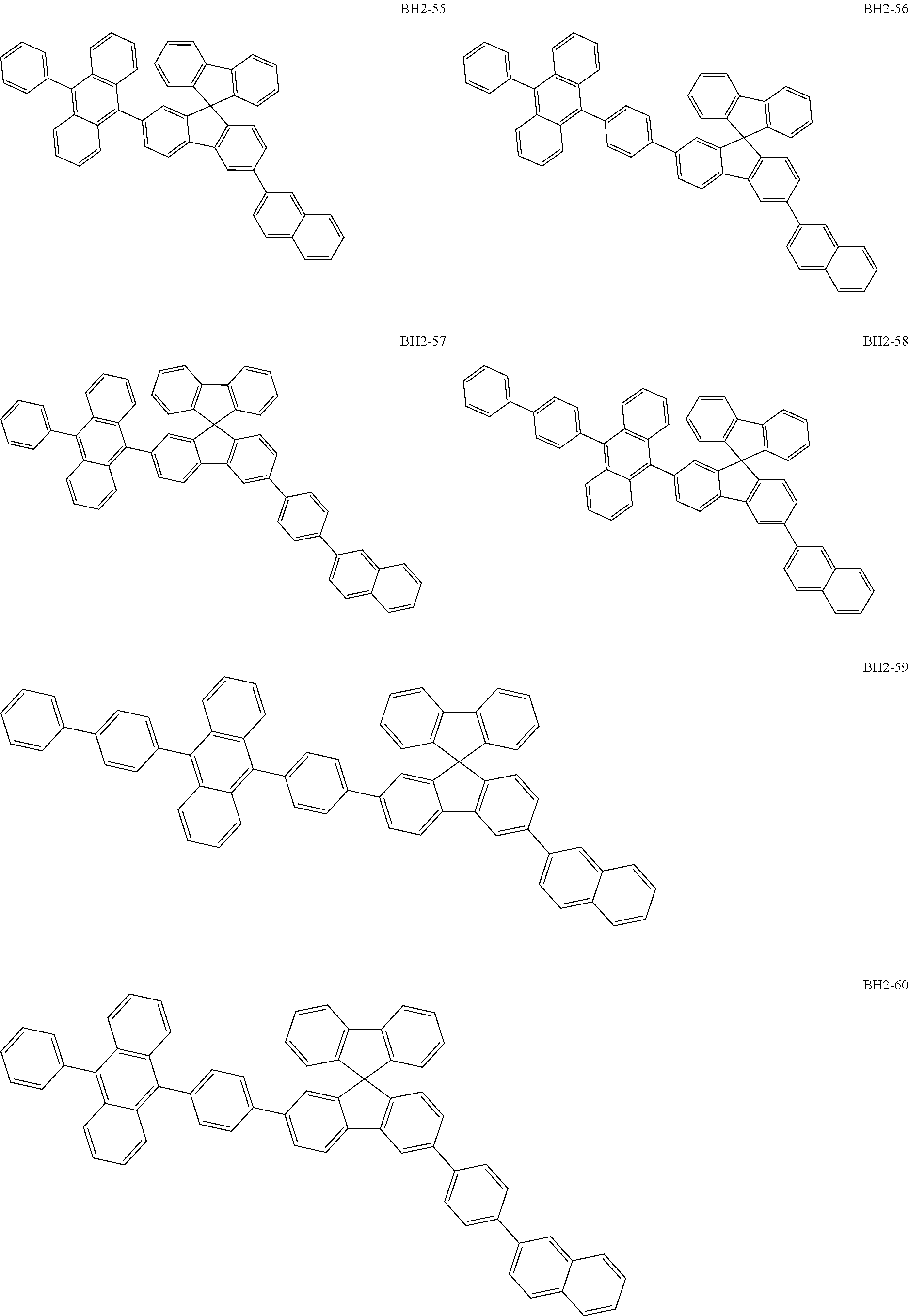

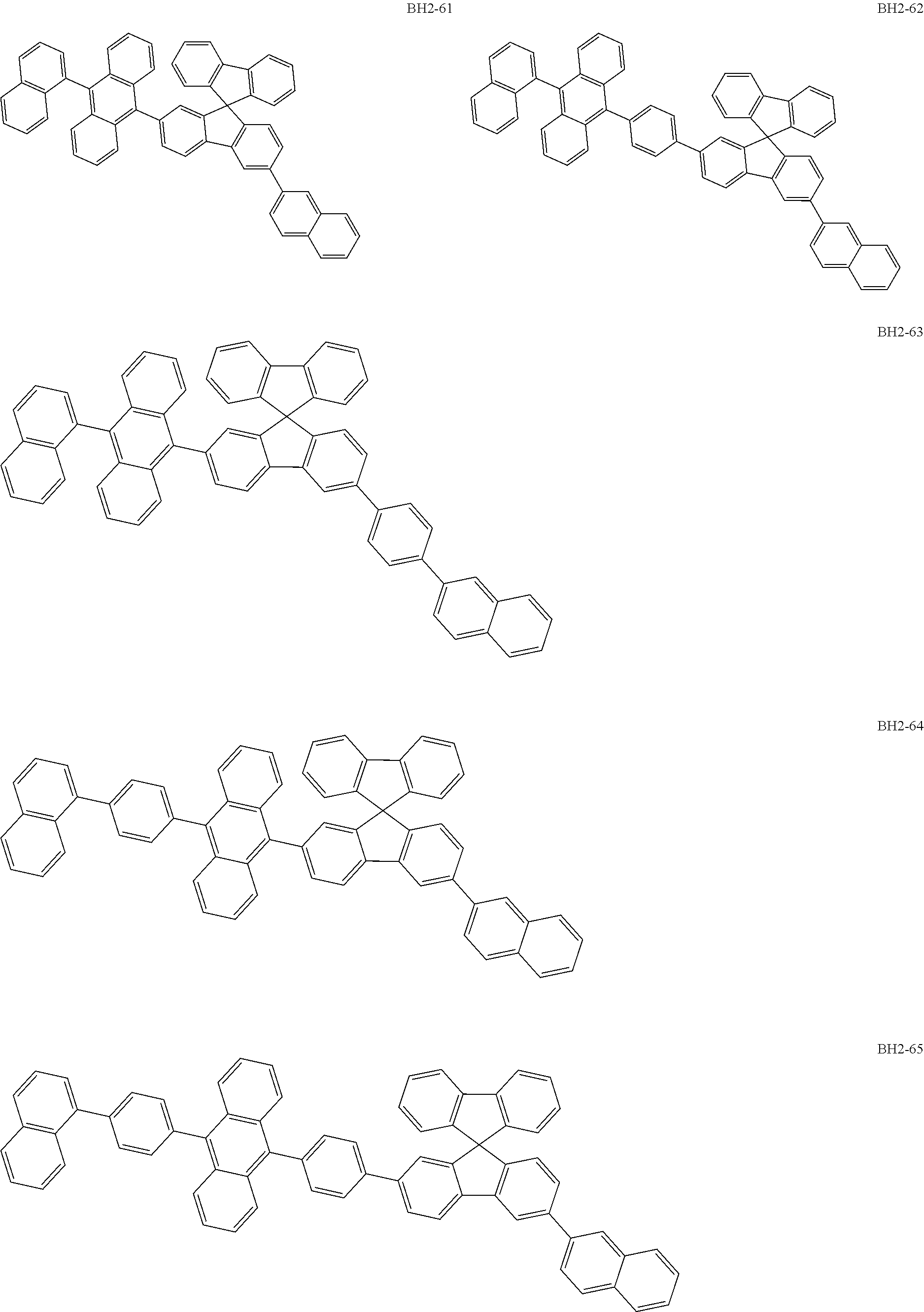

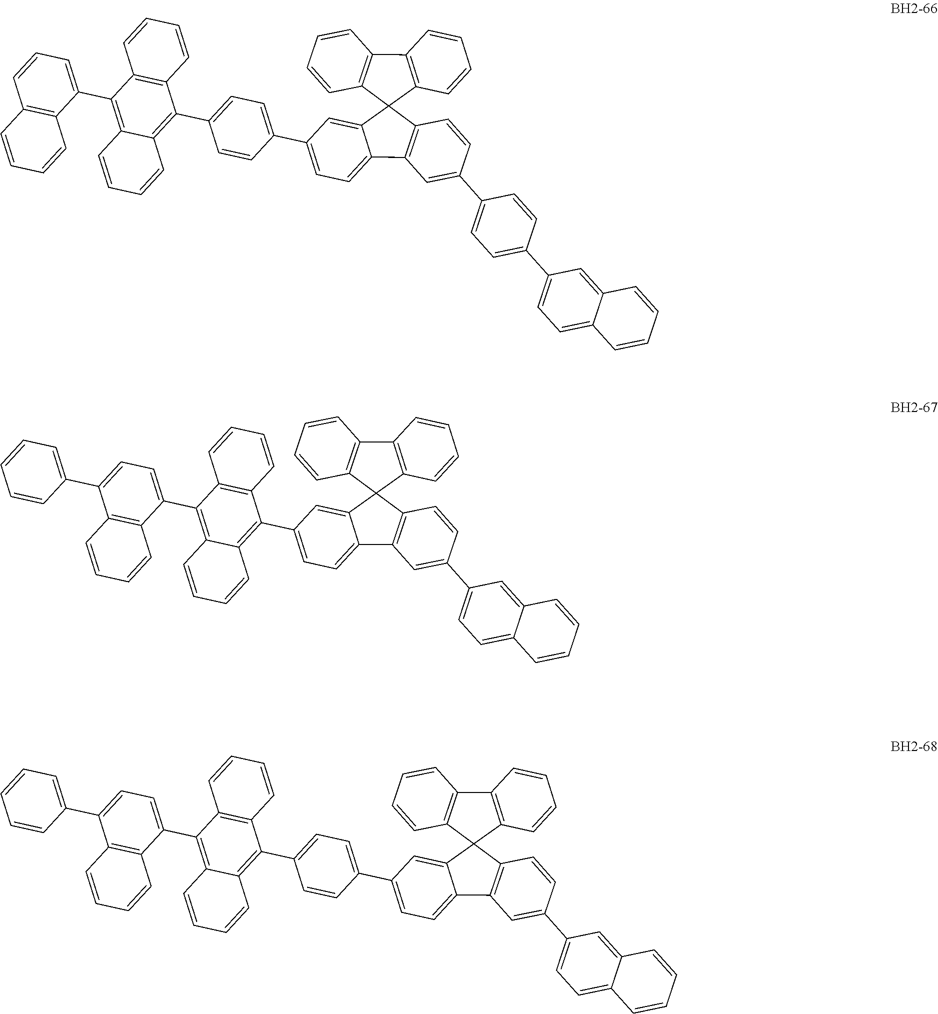

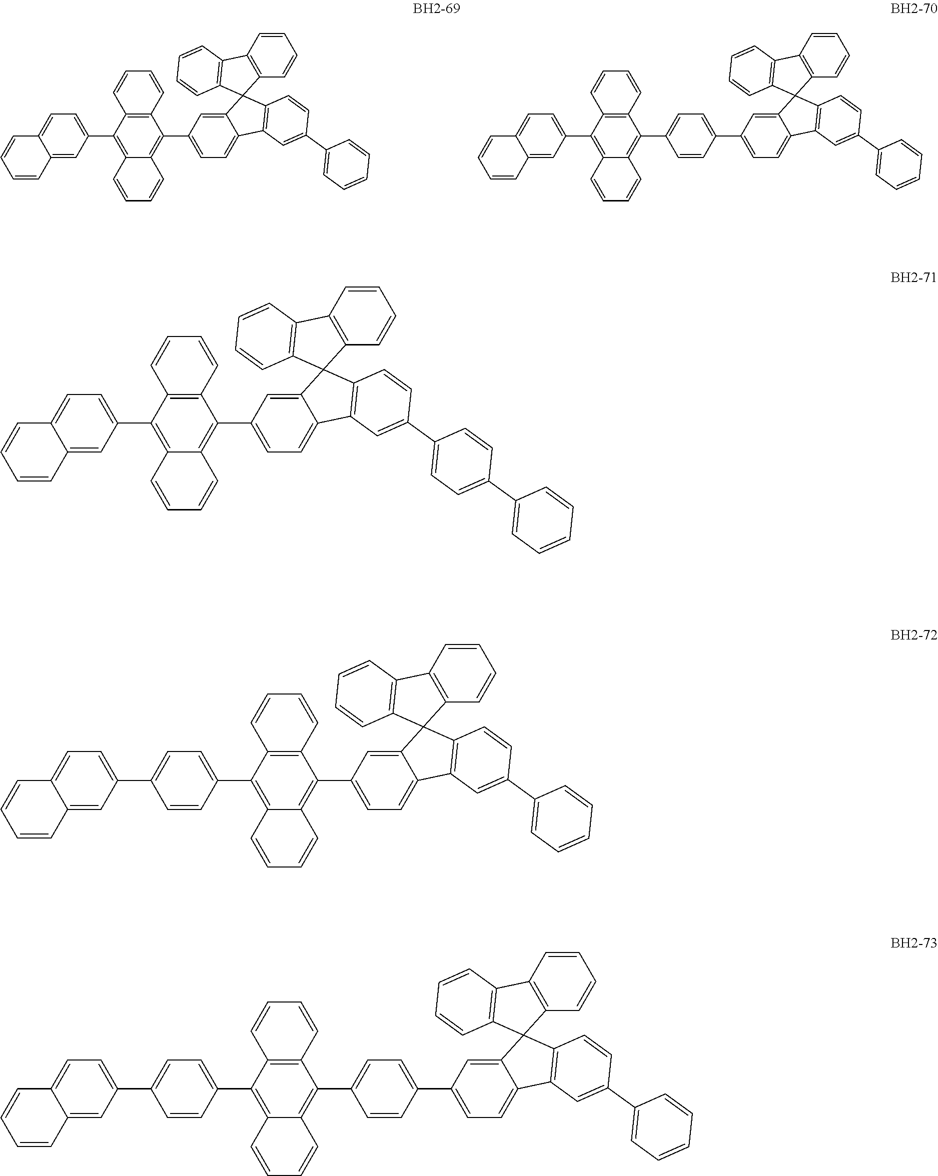

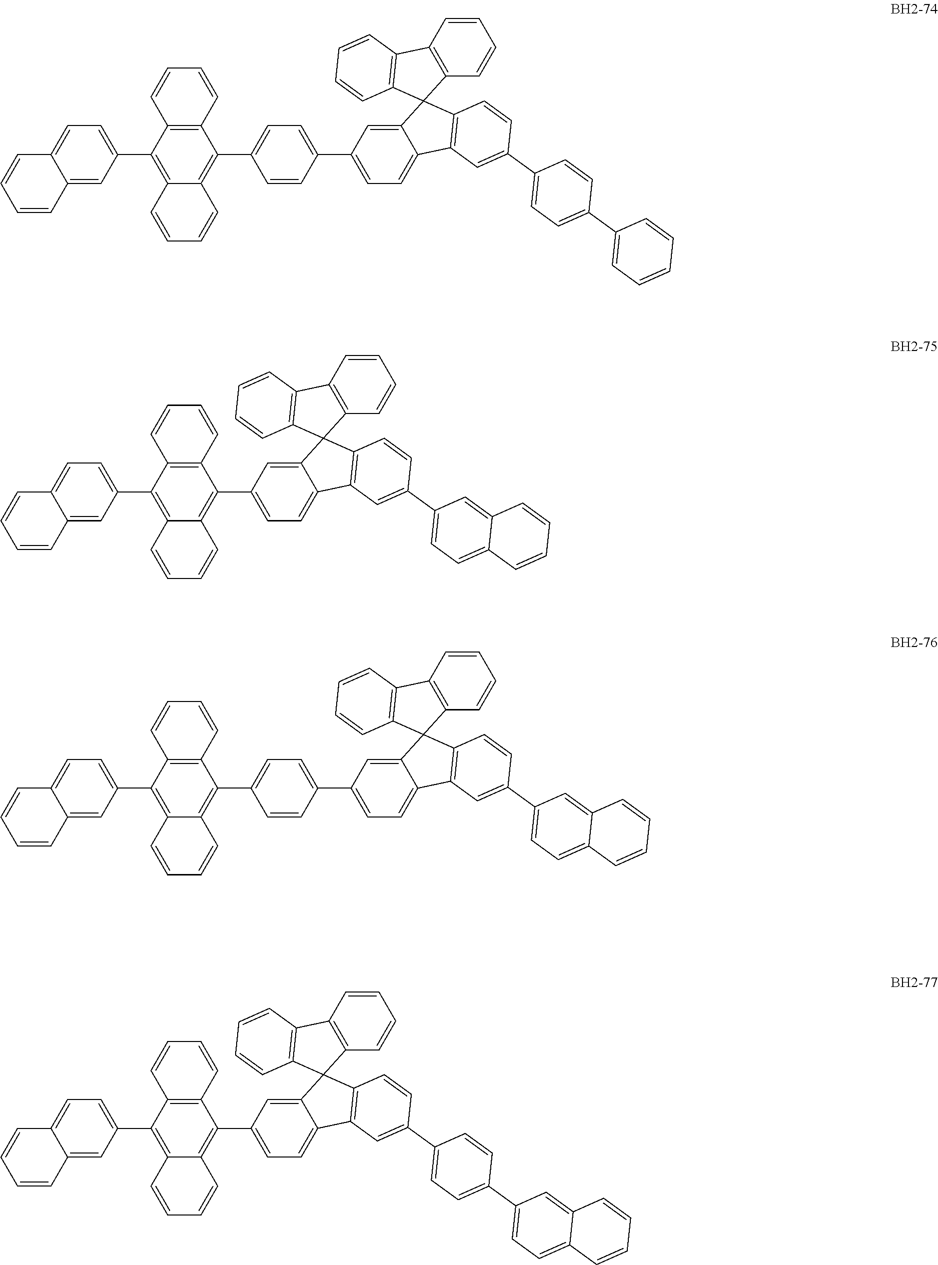

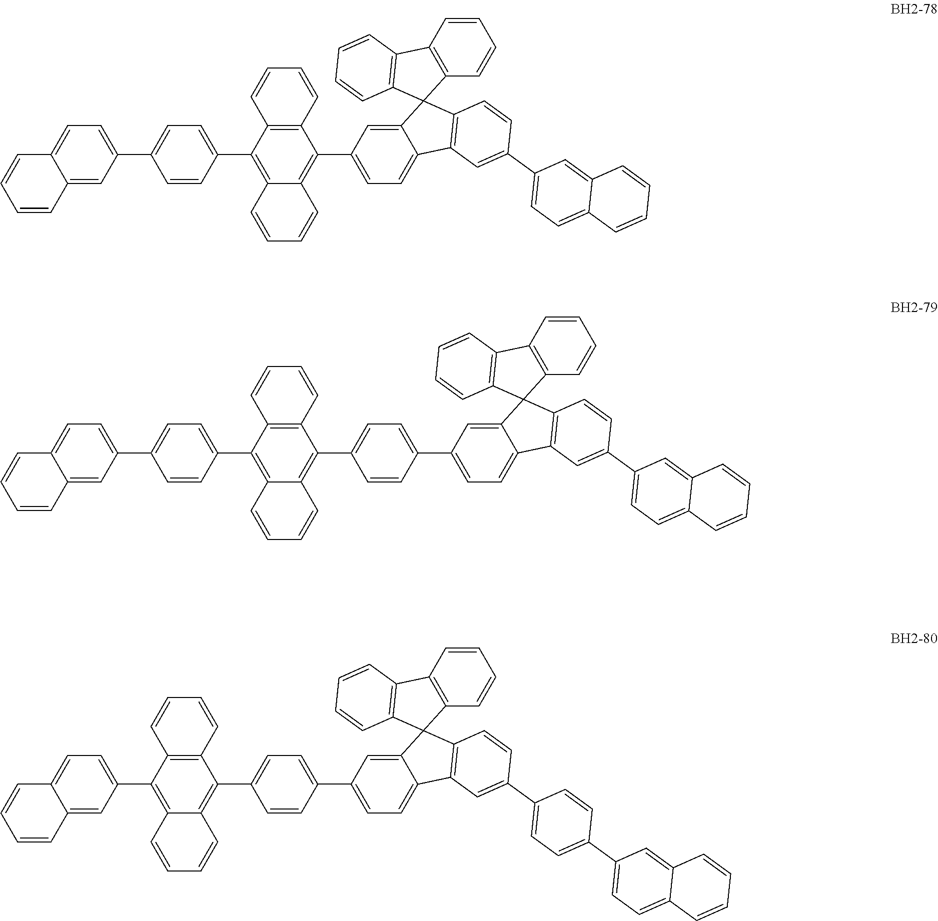

In an aspect, a highest occupied molecular orbital (HOMO) energy level of the second host, represented by Formula 2, may be about −5.2 eV or greater, and a lowest unoccupied molecular orbital (LUMO) energy level may be about −1.7 eV or less. In addition, a highest occupied molecular orbital (HOMO) energy level of each of the compounds in Compound Group 2 may be about −5.2 eV or greater, and a lowest unoccupied molecular orbital (LUMO) energy level may be about −1.7 eV or less.

In the light-emitting element ED according to an aspect, the first host and the second host, included in the light-emitting layer EML-L and EML-T may each be included in a particular proportion, and the proportion of the first host may be higher than the proportion of the second host. The light-emitting element ED according to an aspect may include the first host H1 and the second host H2 in the light-emitting layer EML-L and EML-T in a ratio of about 9:1 (H1:H2) to about 8:2 (H1:H2), thereby exhibiting excellent light-emitting efficiency and long lifespan characteristics. For example, the light-emitting layers EML-L and EML-T may each include the first host H1 and the second host H2 in a ratio of about 9:1 (H1:H2) or about 8:2 (H1:H2).

When the ratio of the first host and the second host included in the light-emitting layer EML-L and EML-T falls out of the above-described range, lifespan characteristics may be reduced, or light-emitting efficiency may be reduced. Accordingly, when the first host and the second host are included in the light-emitting layer EML-L and EML-T, by using the first host and the second host mixed in the above-described ratio, the light-emitting element ED according to an aspect may have improvement both in the light-emitting efficiency and lifespan.

In addition, in the light-emitting element ED according to an aspect, the light-emitting layer EML-L or EML-T not including the first host and the second host may include a known host material. Each of the light-emitting layer EML-L and EML-T may include, as a host material, an anthracene derivative, a pyrene derivative, a fluoranthene derivative, a chrysene derivative, a dihydrobenzanthracene derivative, or a triphenylene derivative. For example, the light-emitting layer EML-L or EML-T may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, aspects of the present disclosure are not limited thereto, for example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

The light-emitting layer EML-L or EML-T may include, as a known dopant material, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), etc.

The light-emitting layer EML-L or EML-T may further include a known phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. Specifically, iridium(III) bis(4,6-difluorophenylpyridinato-N,C2) (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, aspects of the present disclosure are not limited thereto.

In an aspect, the light-emitting layer EML-L and EML-T may include a hole transport host and an electron transport host. For example, the light-emitting layer EML-L or EML-T not including the above-described first host and second host may include a hole transport host represented by Formula HT-1 below and an electron transport host represented by Formula ET-1 below.

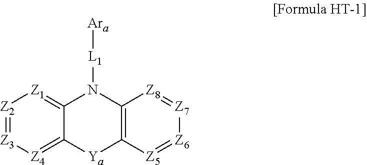

In Formula HT-1, Z₁ to Z₈ may be each independently N or CRₐ₁. For example, all of Z₁ to Z₇ may be CRₐ₁. Alternatively, any one among Z₁ to Z₈ may be N, and the rest may be CRₐ₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but aspects of the present disclosure are not limited thereto.

In Formula HT-1, Yₐ may be a direct linkage, CRₐ₂Rₐ₃, or SiRₐ₄Rₛ₅. That is, it may mean that the two benzene rings linked to the nitrogen atom in Formula HT-1 are linked via a direct linkage,

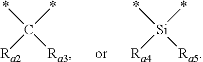

In Formula HT-1, when Yₐ is a direct linkage, the second compound represented by Formula HT-1 may include a carbazole moiety.

In Formula HT-1, Arₐ may be a substituted or unsubstituted aryl group having 6 to 30 ring-forming carbon atoms, or a substituted or unsubstituted heteroaryl group having 2 to 30 ring-forming carbon atoms. For example, Arₐ may be a substituted or unsubstituted carbazole group, a substituted or unsubstituted dibenzofuran group, a substituted or unsubstituted dibenzothiophene group, a substituted or unsubstituted biphenyl group, etc., but aspects of the present disclosure are not limited thereto.

In Formula HT-1, Rₐ₁ to Rₐ₅ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. Alternatively, each of Rₐ₁ to Rₐ₅ may be bonded to an adjacent group to form a ring. For example, Rₐ₁ to Rₐ₅ may be each independently a hydrogen atom or a deuterium atom. Rₐ₁ to Rₐ₅ may be each independently an unsubstituted methyl group or an unsubstituted phenyl group.

In an aspect, the hole transport host represented by Formula HT-1 may be represented by any one of compounds represented in Compound Group 3 below. The light-emitting layer EML-L and EML-T may include at least one of the compounds represented by Compound Group 3 below as the hole transport host.

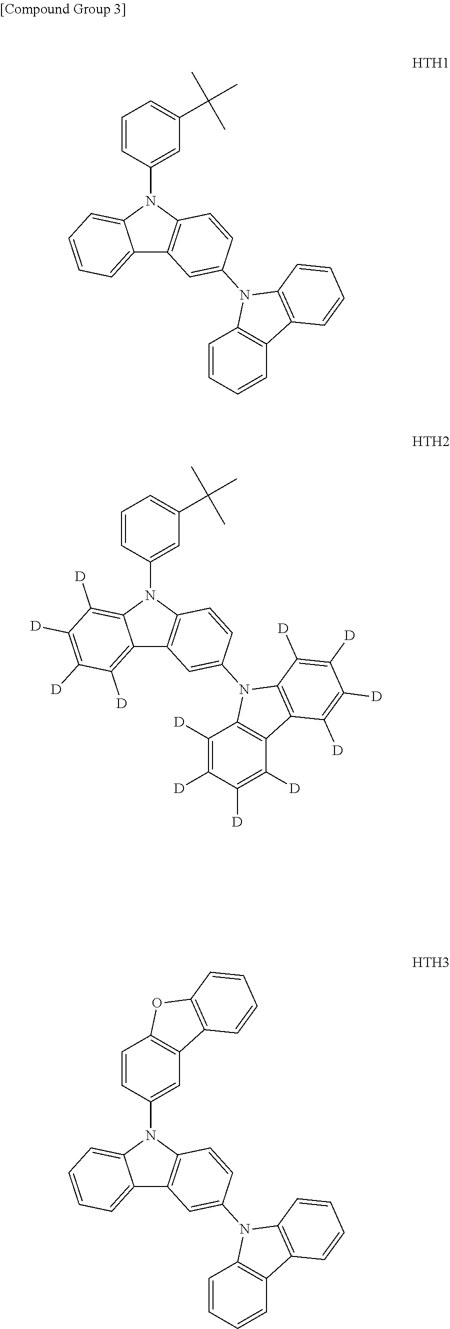 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

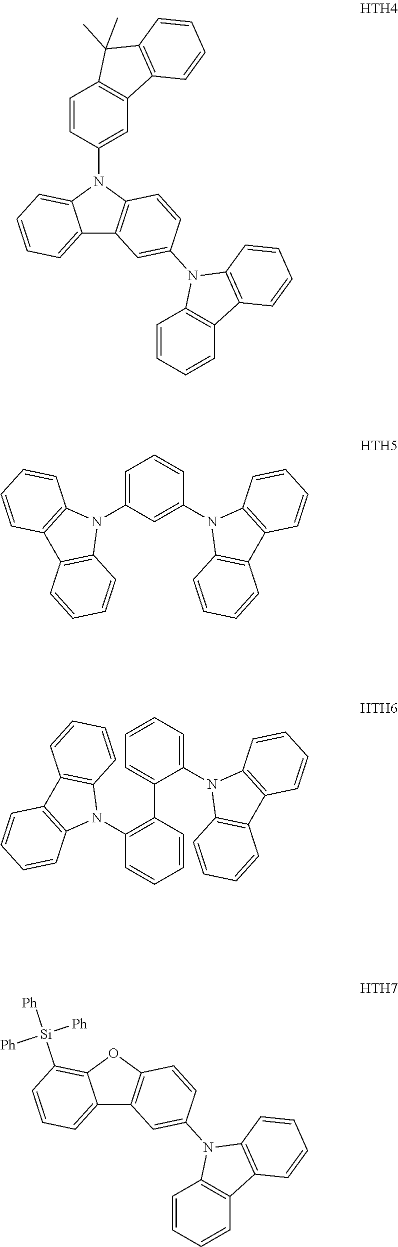 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

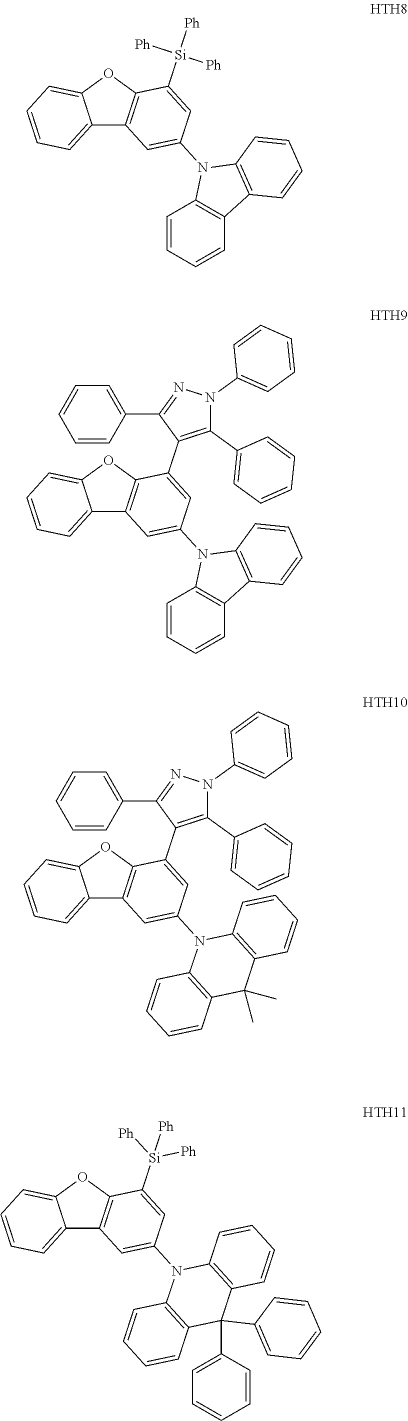 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

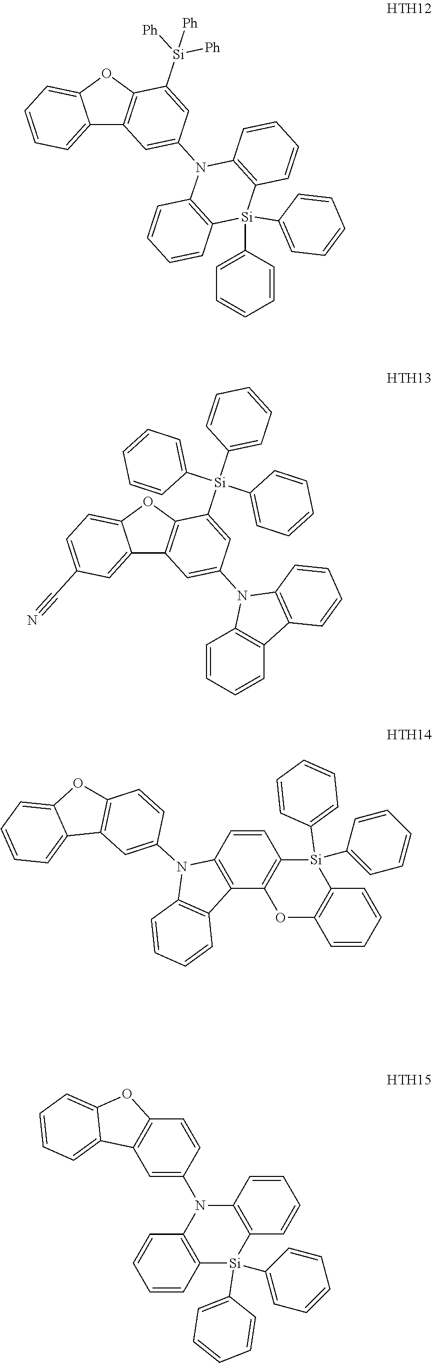 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1]

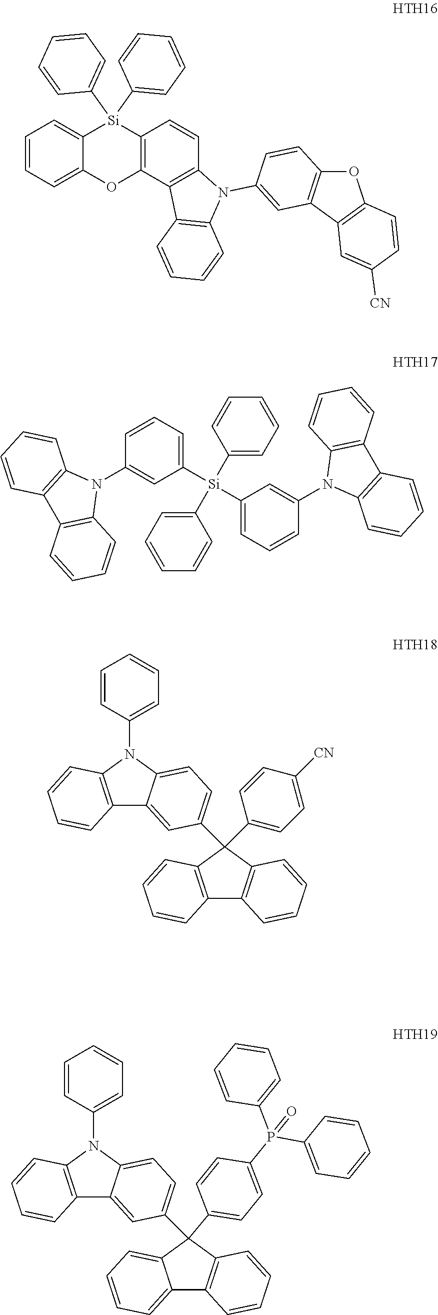 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1]

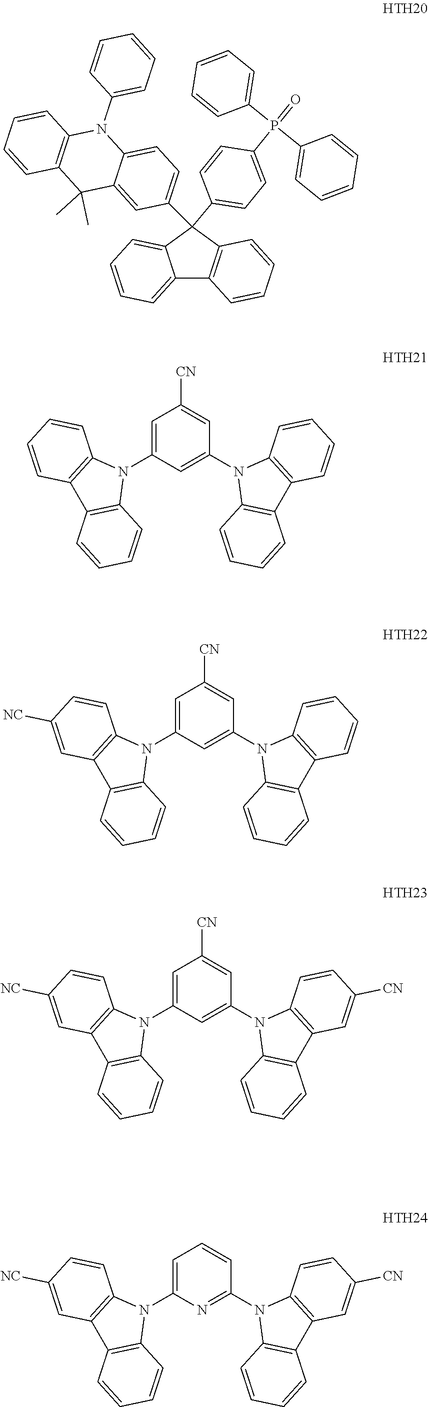 [SMILES: CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

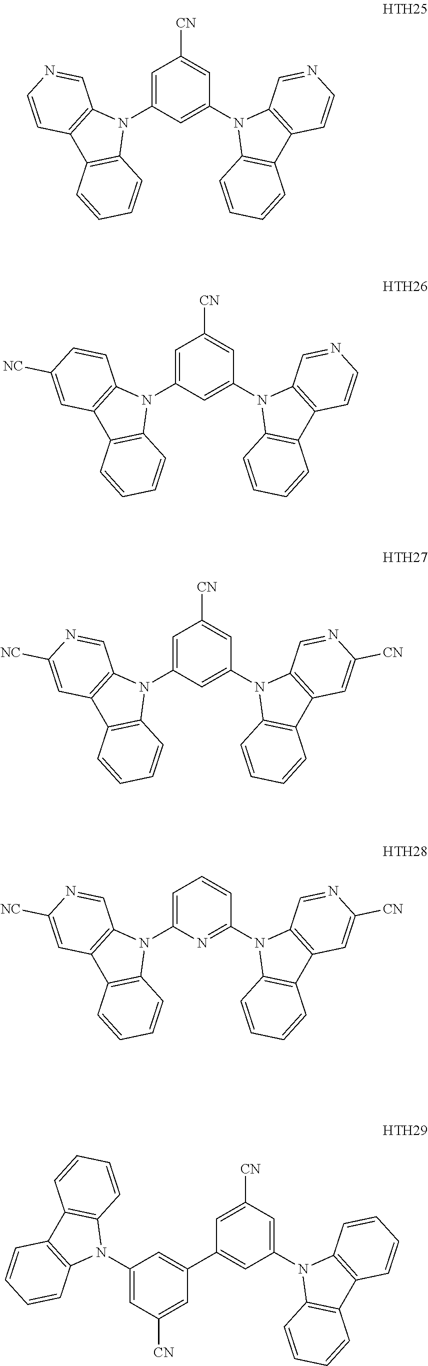 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1]

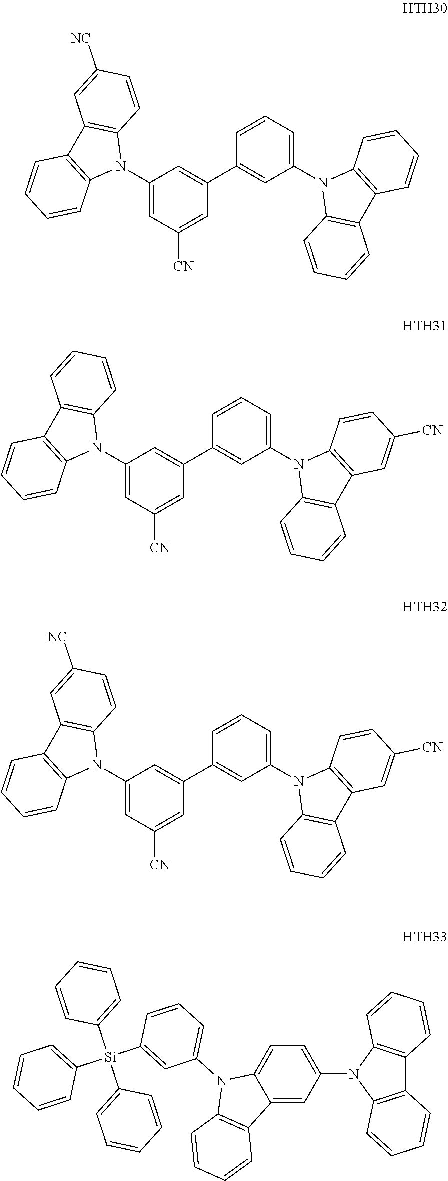 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

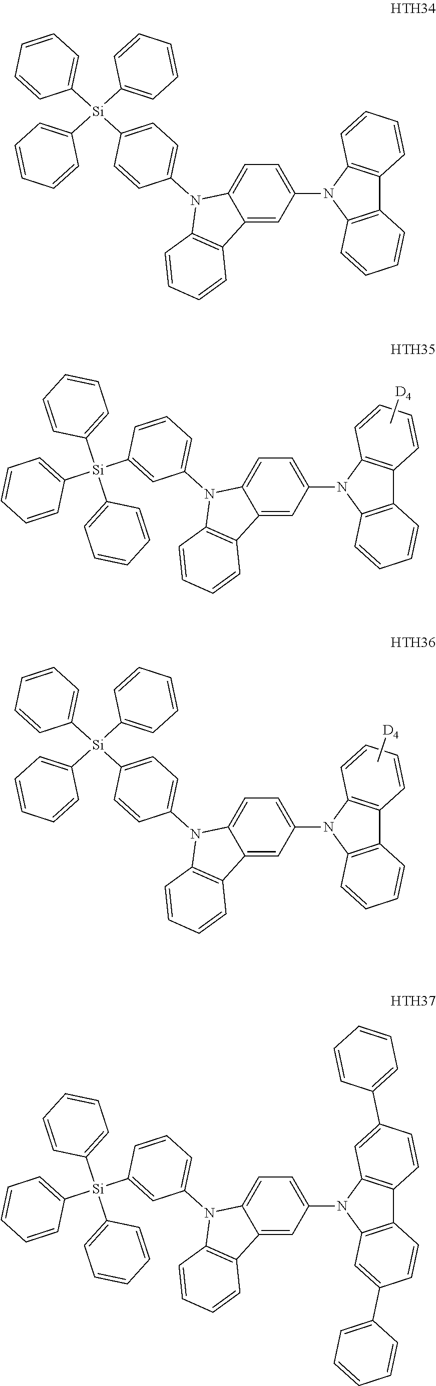

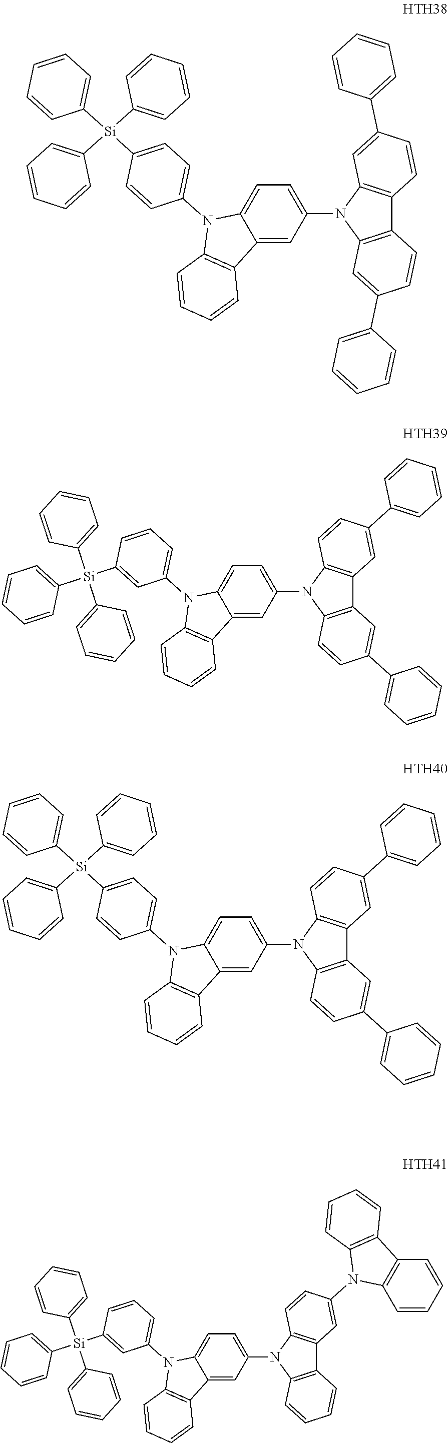

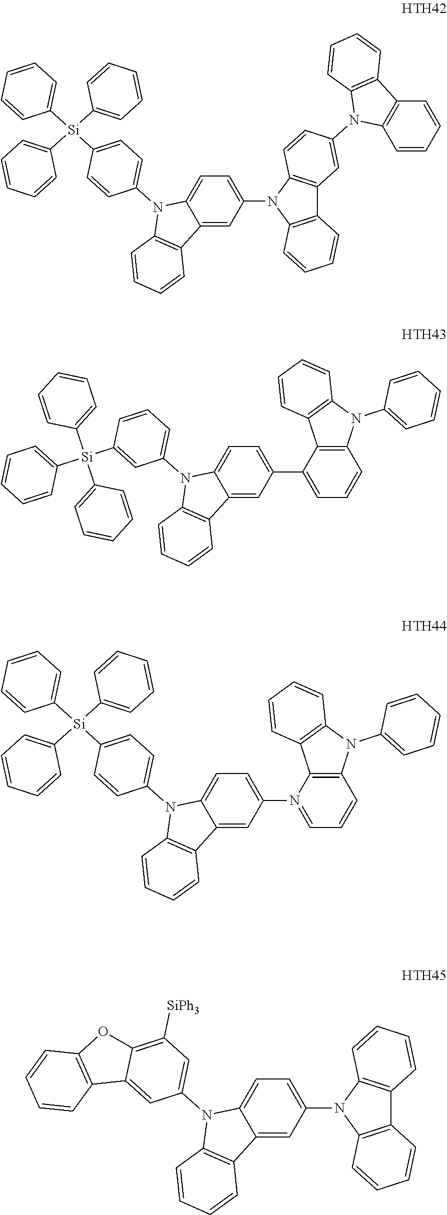

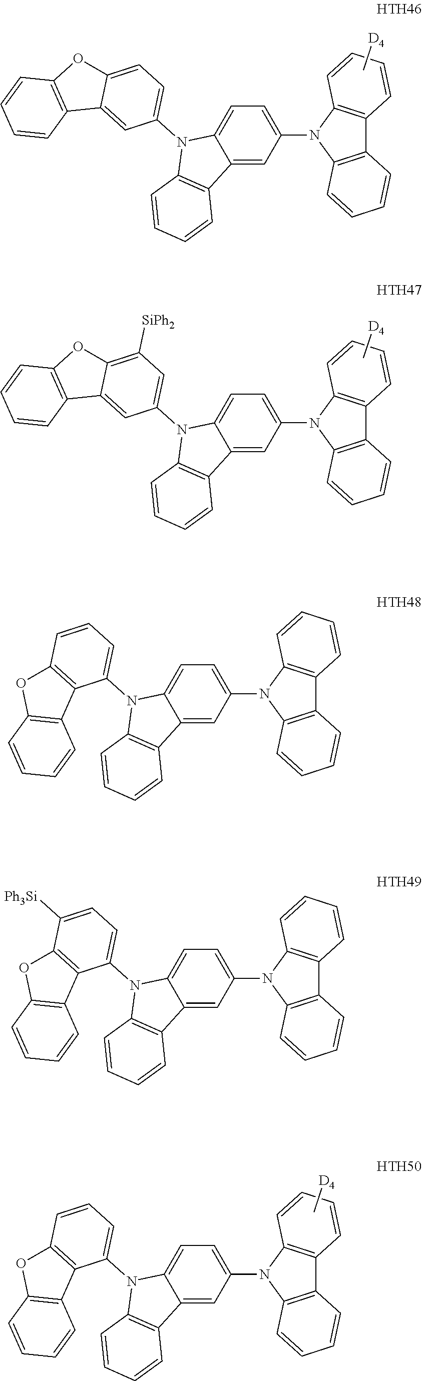

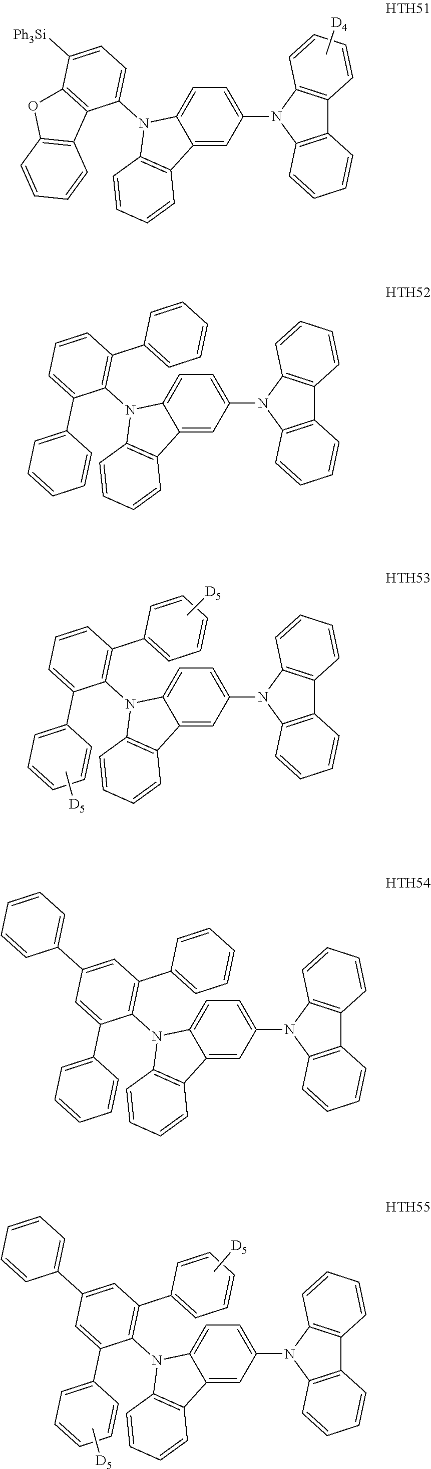

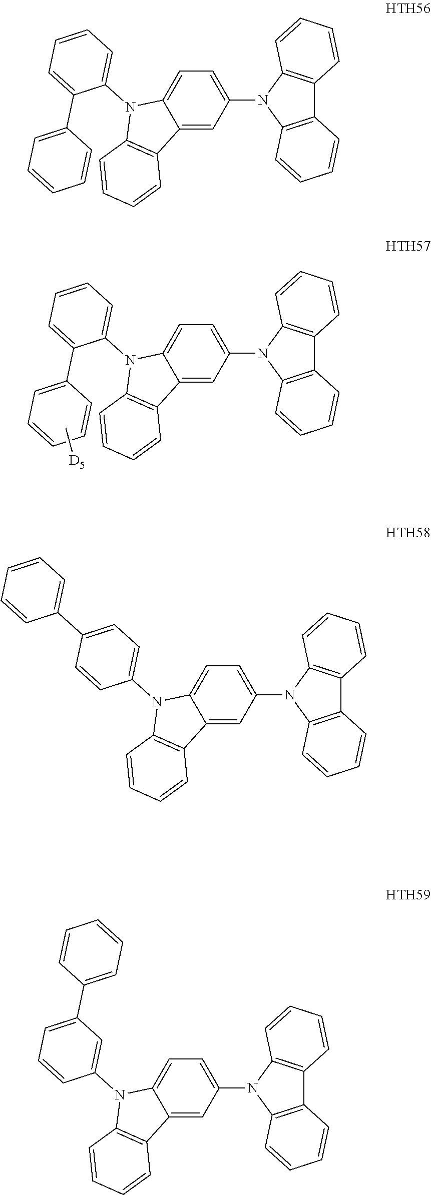

In the compounds presented in Compound Group 3, “D may mean a deuterium atom, and “Ph” may mean a substituted or unsubstituted phenyl group. For example, in the compounds presented in Compound Group 3, “Ph” may mean an unsubstituted phenyl group.

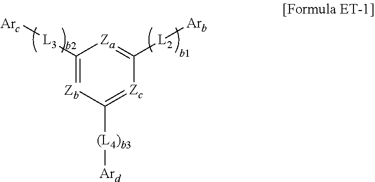

In Formula ET-1, at least one among Zₐ to Z_{c} is N, and the rest are CRₐ₆. For example, any one among Zₐ to Z_{c} may be N, and the rest may be each independently CRₐ₆. In this case, the third compound represented by Formula ET-1 may include a pyridine moiety. Alternatively, two among Zₐ to Z_{c} may be N, and the rest may be CRₐ₆. In this case, the third compound represented by Formula ET-1 may include a pyrimidine moiety. Alternatively, Zₐ to Z_{c} may all be N. In this case, the third compound represented by Formula ET-1 may include a triazine moiety.

In Formula ET-1, Rₐ₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may be each independently an integer of 0 to 10.

In Formula ET-1, Ar_{b} to Ar_{d} may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar_{b} to Ar_{d} may be each independently a substituted or unsubstituted phenyl group, or a substituted or unsubstituted carbazole group.

In Formula ET-1, L₂ to L₄ may be each independently a direct linkage, a substituted or unsubstituted arylene group having 6 to 30 ring-forming carbon atoms, or a substituted or unsubstituted heteroarylene group having 2 to 30 ring-forming carbon atoms. Meanwhile, when b1 to b3 are integers of 2 or greater, L₂ to L₄ may be each independently a substituted or unsubstituted arylene group having 6 to 30 ring-forming carbon atoms, or a substituted or unsubstituted heteroarylene group having 2 to 30 ring-forming carbon atoms.

In an aspect, the electron transport host may be represented by any one of compounds in Compound Group 4 below. In the light-emitting element ED according to an aspect, the light-emitting layer EML-L and EML-T may include any one of the compounds in Compound Group 4 below.

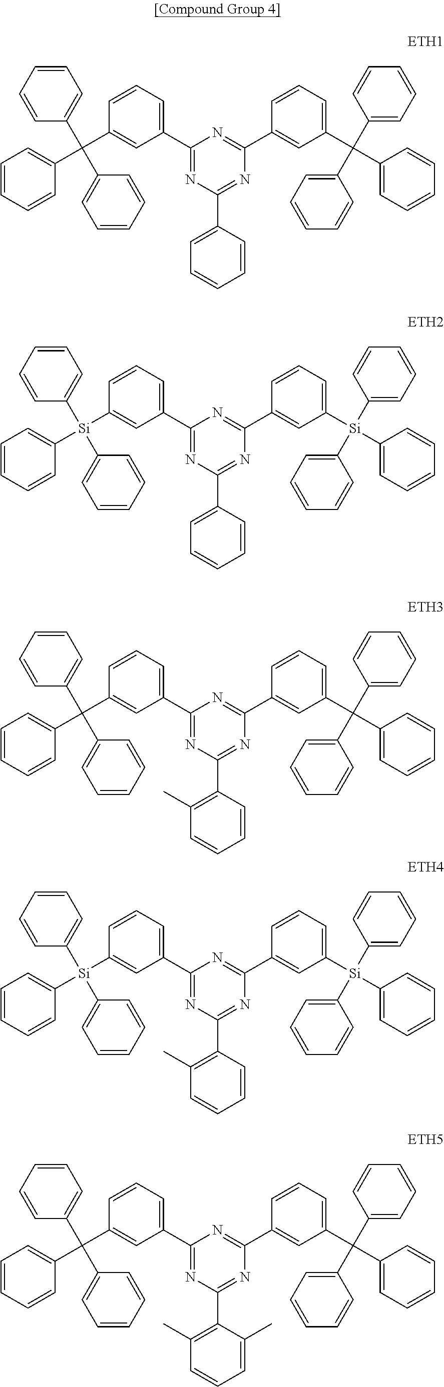

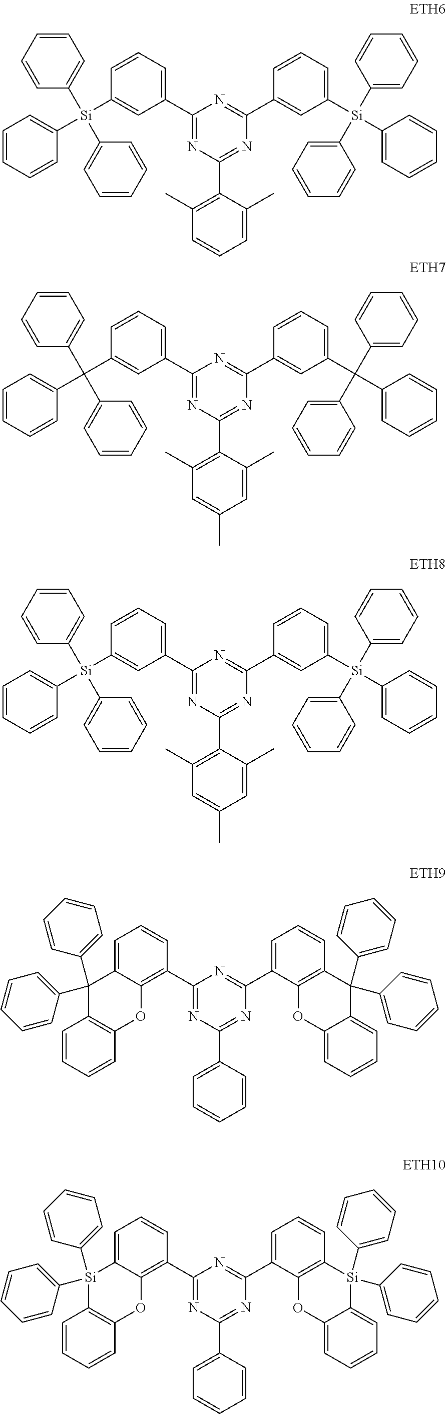

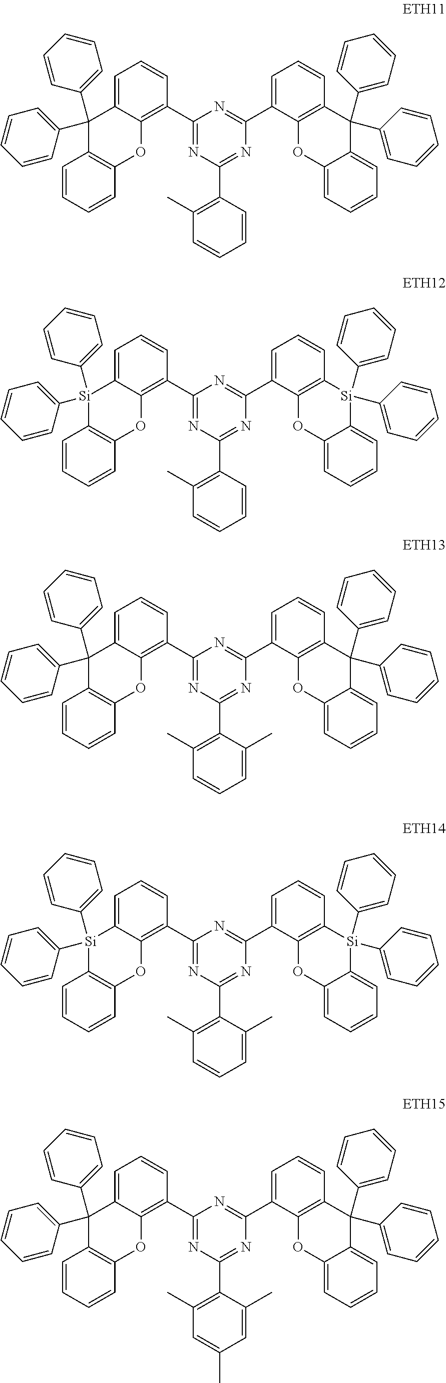

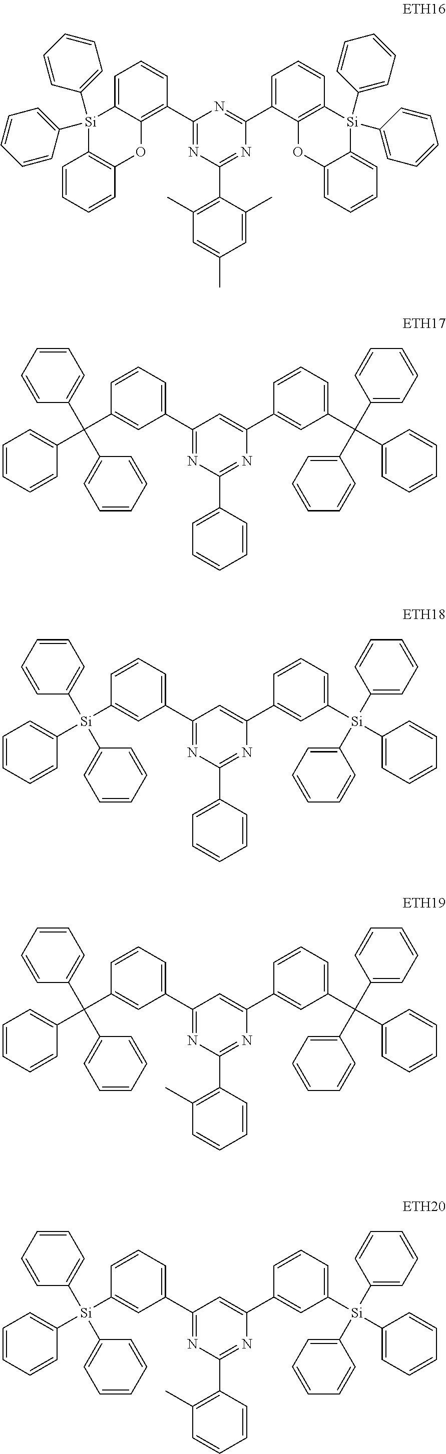

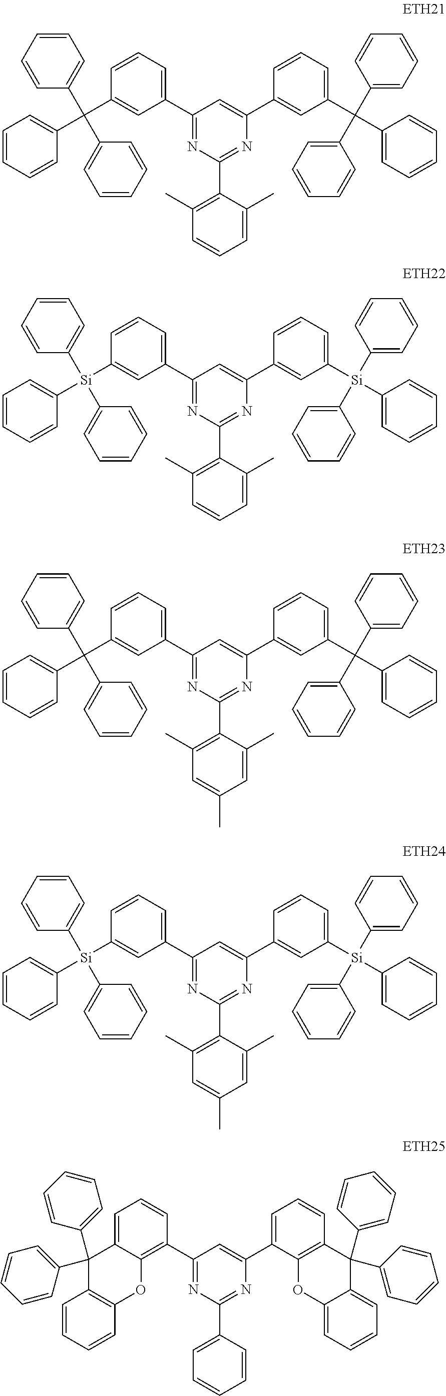

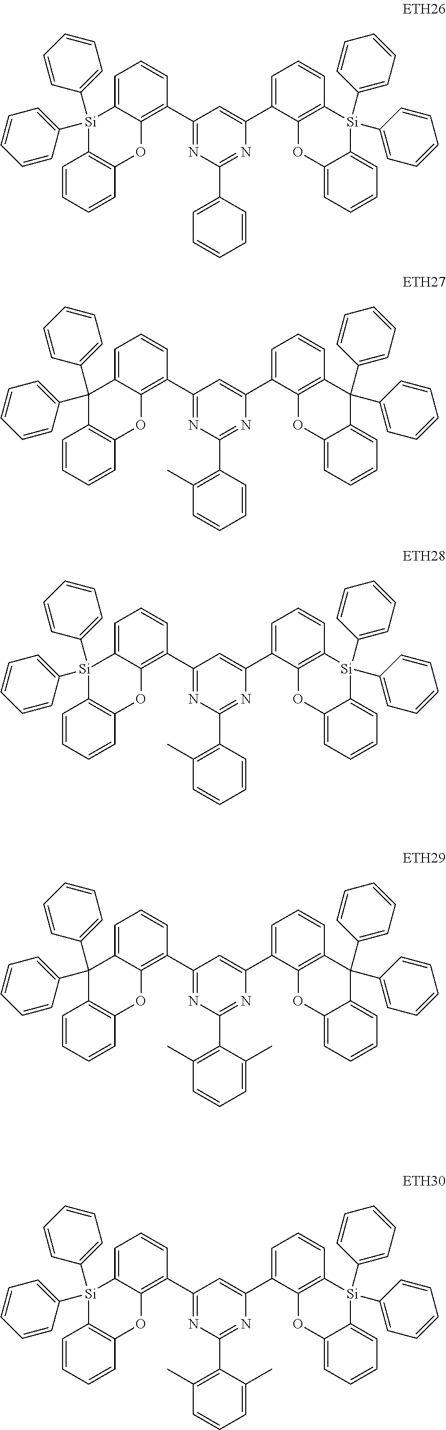

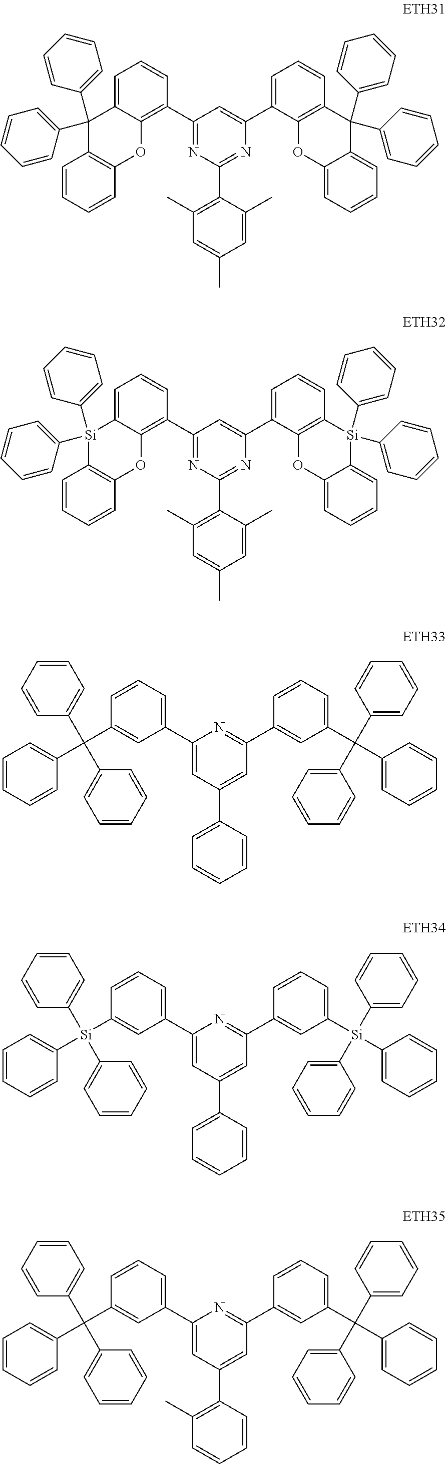

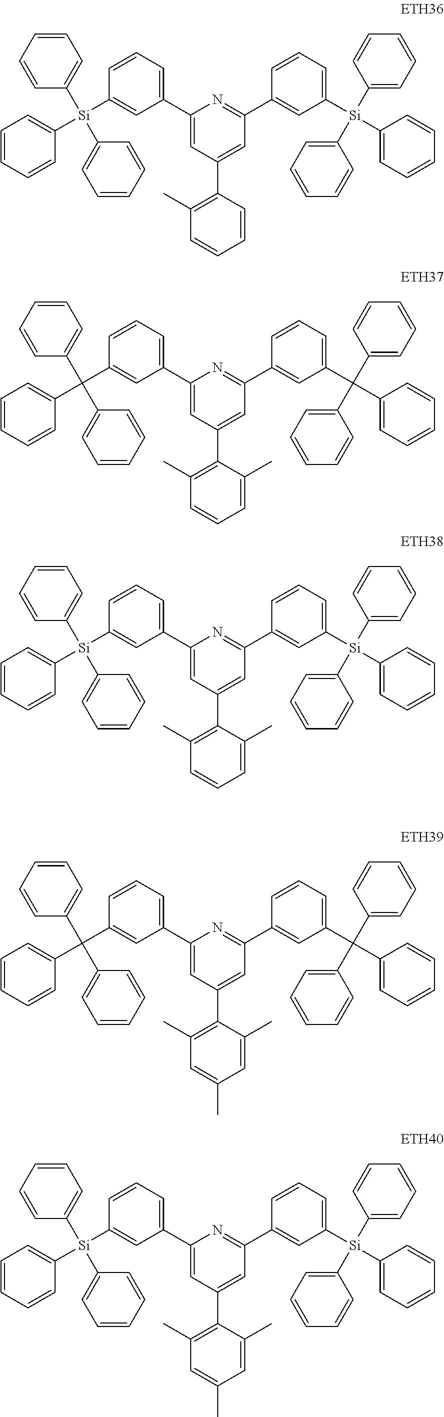

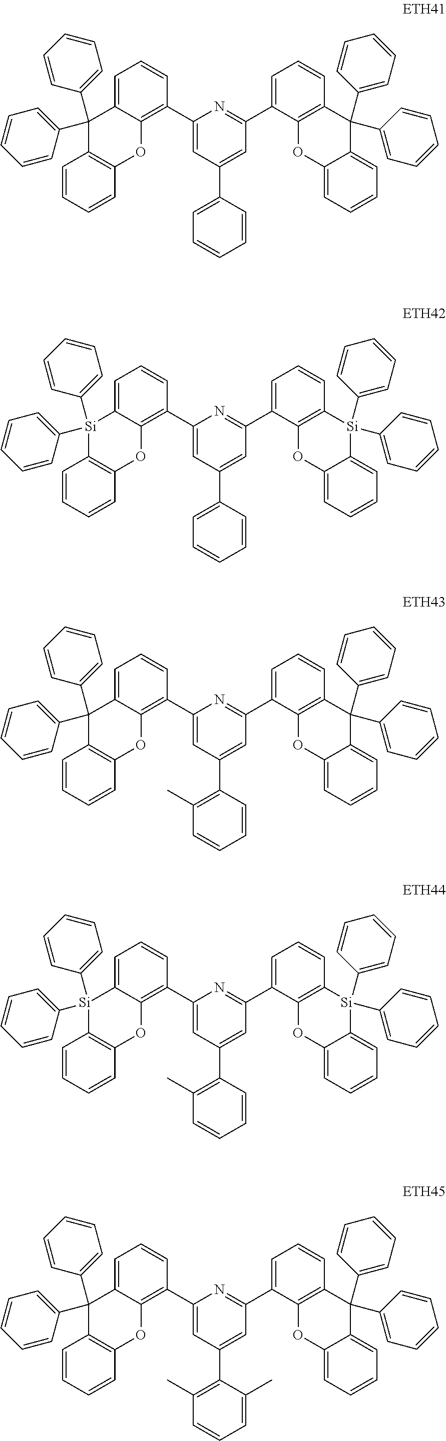

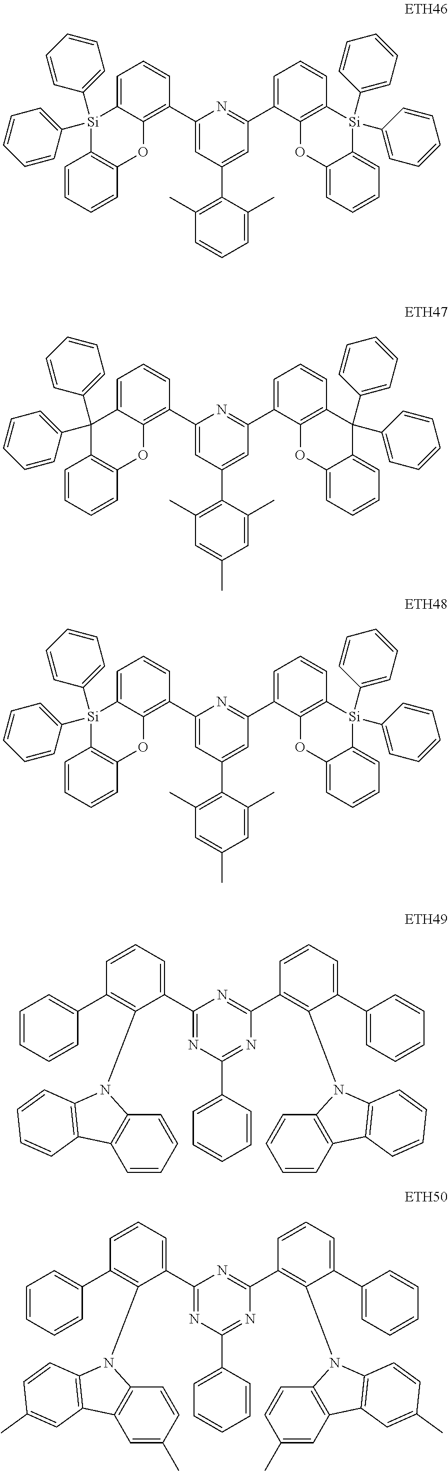

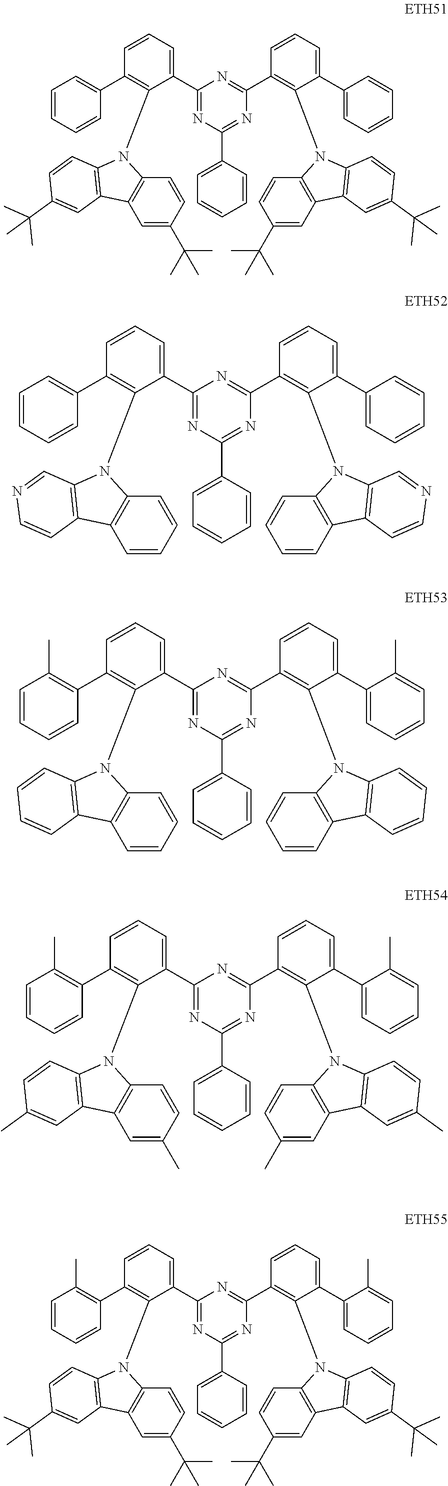

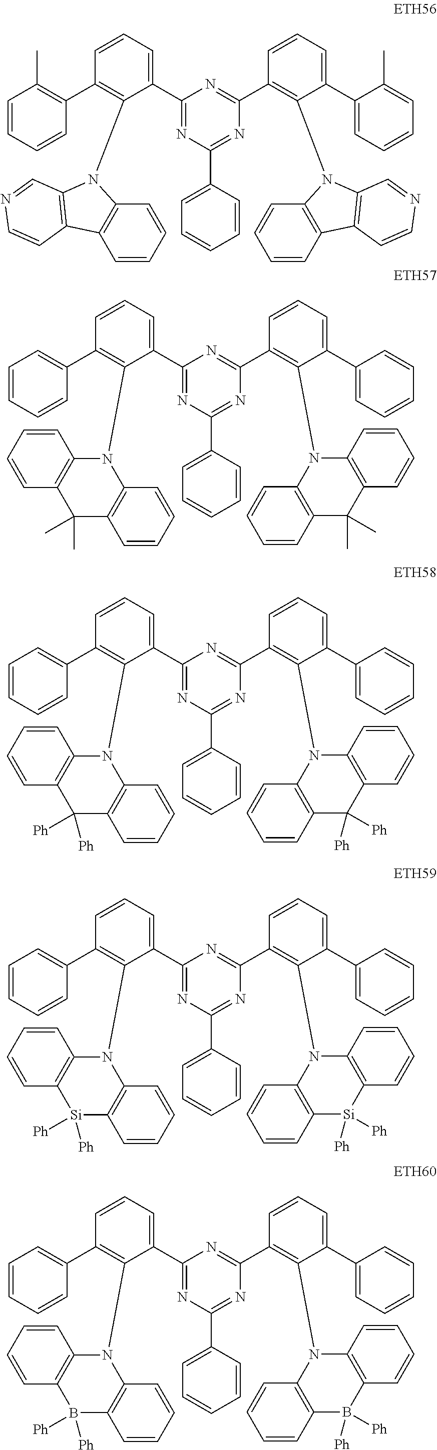

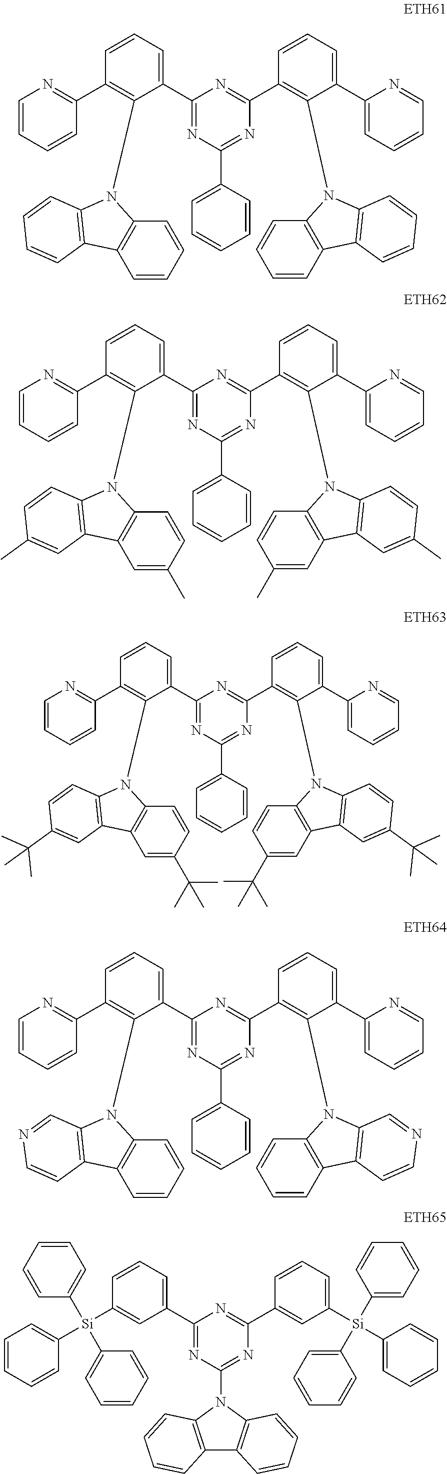

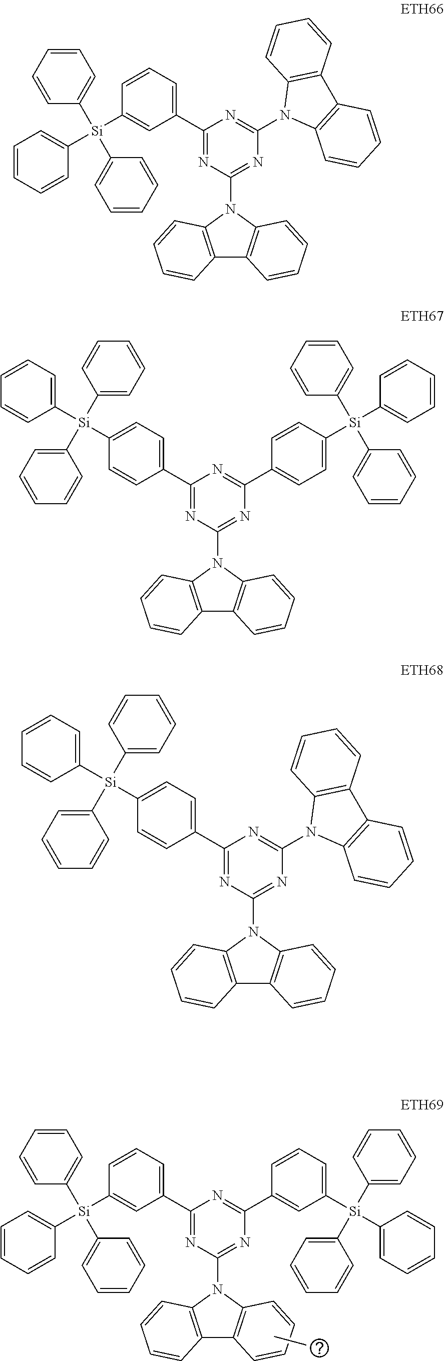

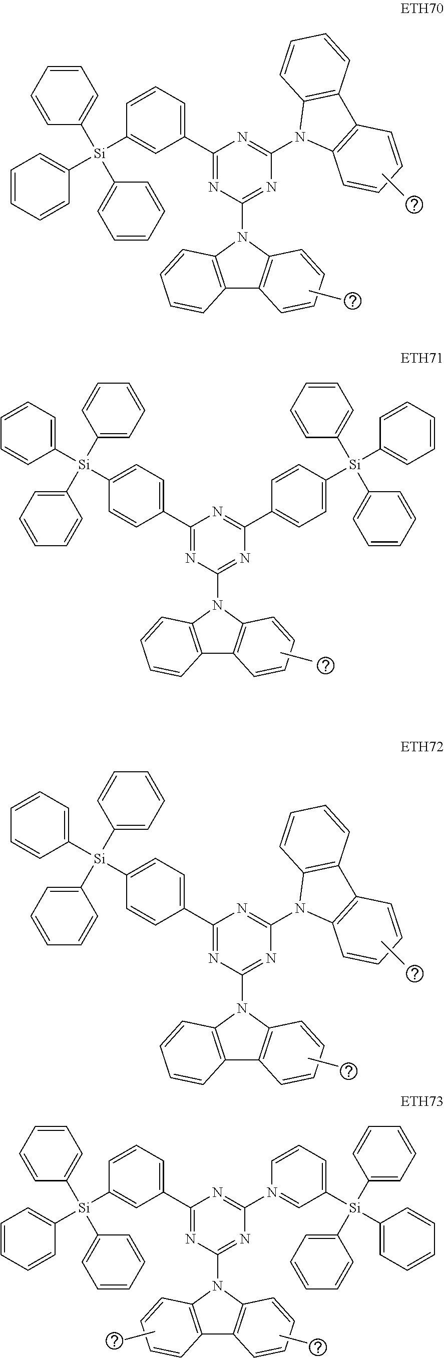

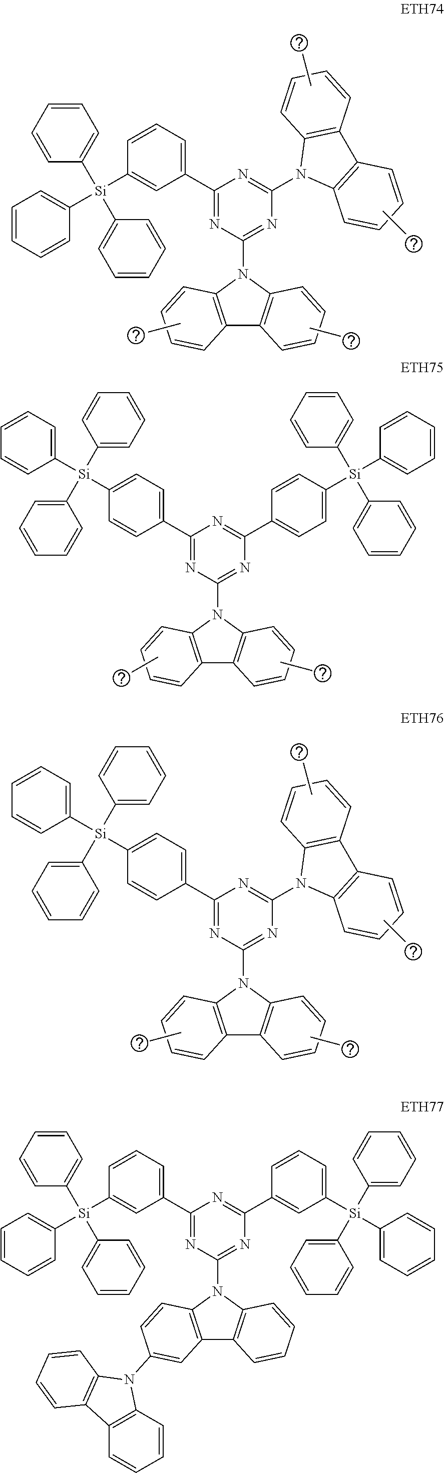

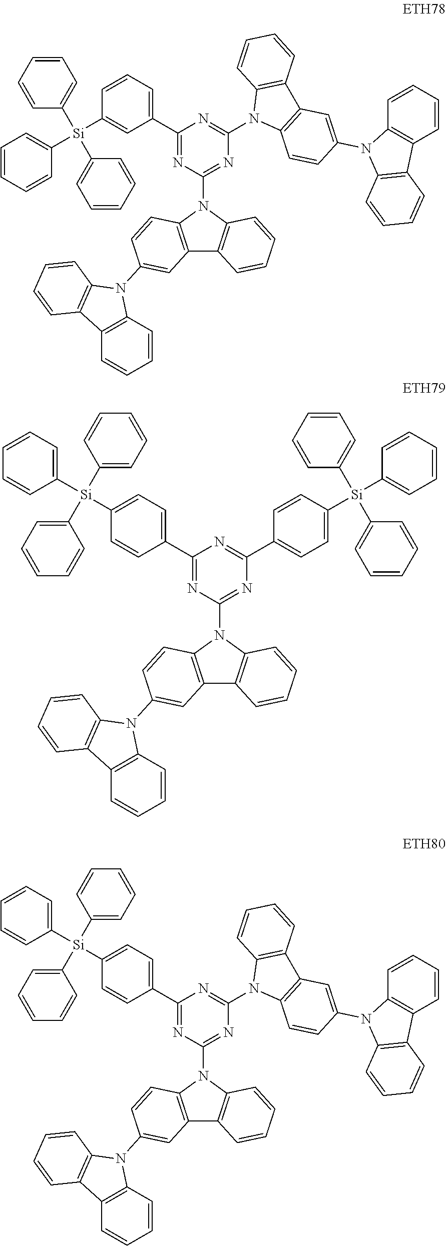

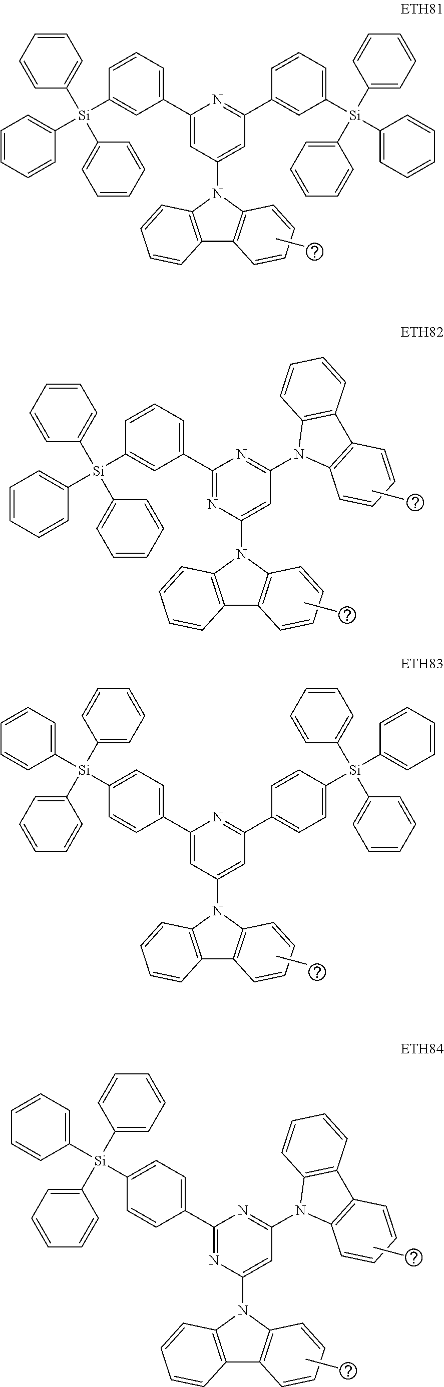

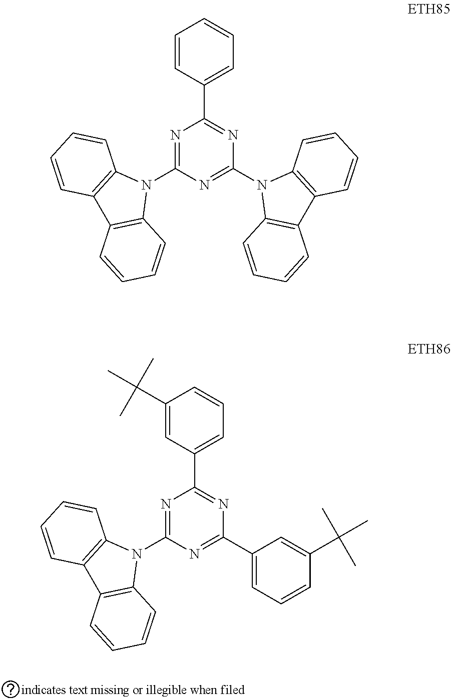 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In the compounds presented in Compound Group 4, “D” refers to a deuterium atom and “Ph” refers to an unsubstituted phenyl group.

In an aspect, the light-emitting layer EML-L and EML-T may include an organic metal complex containing platinum (Pt) as a central metal atom, and containing ligands bonded to the central metal atom. In the light-emitting element ED according to an aspect, the light-emitting layer EML-L and EML-T may include a compound represented by Formula D-1 below as a phosphorescence sensitizer.

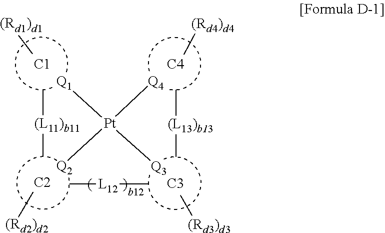

In Formula D-1, Q₁ to Q₄ may be each independently C or N.

In Formula D-1, C1 to C₄ may be each independently a substituted or unsubstituted hydrocarbon ring having 5 to 30 ring-forming carbon atoms, or a substituted or unsubstituted heterocycle having 2 to 30 ring-forming carbon atoms.

In Formula D-1, L₁₁ to L₁₃ may be each independently a direct linkage,

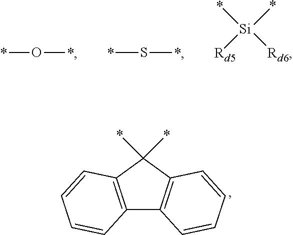

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃,

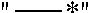

means a part linked to C1 to C4.

In Formula D-1, b11 to b13 may be each independently 0 or 1. If b 11 is 0, C1 and C2 may not be linked to each other. If b12 is 0, C2 and C3 may not be linked to each other. Ifb13 is 0, C3 and C4 may not be linked to each other.

In Formula D-1, R_{d1} to R_{d6} may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. Alternatively, each of R₆₁ to R₆₆ may be bonded to an adjacent group to form a ring. R₆₁ to R₆₆ may be each independently a substituted or unsubstituted methyl group, or a substituted or unsubstituted t-butyl group.

In Formula D-1, d1 to d4 are each independently an integer of 0 to 4. In Formula D-1, if each of d1 to d4 is 0, the fourth compound may not be substituted with each of R_{d1} to R_{d4}. The case where each of d1 to d4 is 4 and R_{d1}'s to R_{d4}′ are each hydrogen atoms may be the same as the case where each of d1 to d4 is 0. When each of d1 to d4 is an integer of 2 or more, a plurality of R_{d1}'s to R_{d4}'s may each be the same or at least one among the plurality of R_{d1}'s to R_{d4}'S may be different from the others.

In Formula D-1, C1 to C4 may be each independently a substituted or unsubstituted hydrocarbon ring or a substituted or unsubstituted heterocycle represented by any one among C-1 to C-4 below:

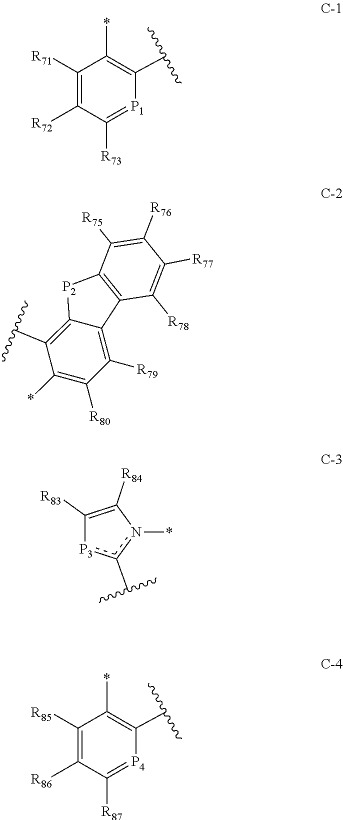

In C-1 to C-4, P₁ may be

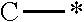 [SMILES: *C]

or CR₇₄, P₂ may be

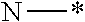 [SMILES: *N]

or NR₈₁, P₃ may be

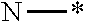 [SMILES: *N]

or NR₈₂, and P₄ may be

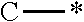 [SMILES: *C]

or CR₈₈. R₇₁ to R₈₈ may be each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In addition, in C-1 to C-4,

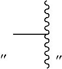

corresponds to a part linked to Pt that is a central metal atom, and

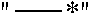

corresponds to a part linked to a neighboring cyclic group (C1 to C4) or a linker (L₁₁ to L₁₃).

In an aspect, the phosphorescence sensitizer represented by Formula D-1 may represented at least one among the compounds represented by Compound Group 5 below. The emission layer EML may include at least one among the compounds represented by Compound Group 5 as a sensitizer material.

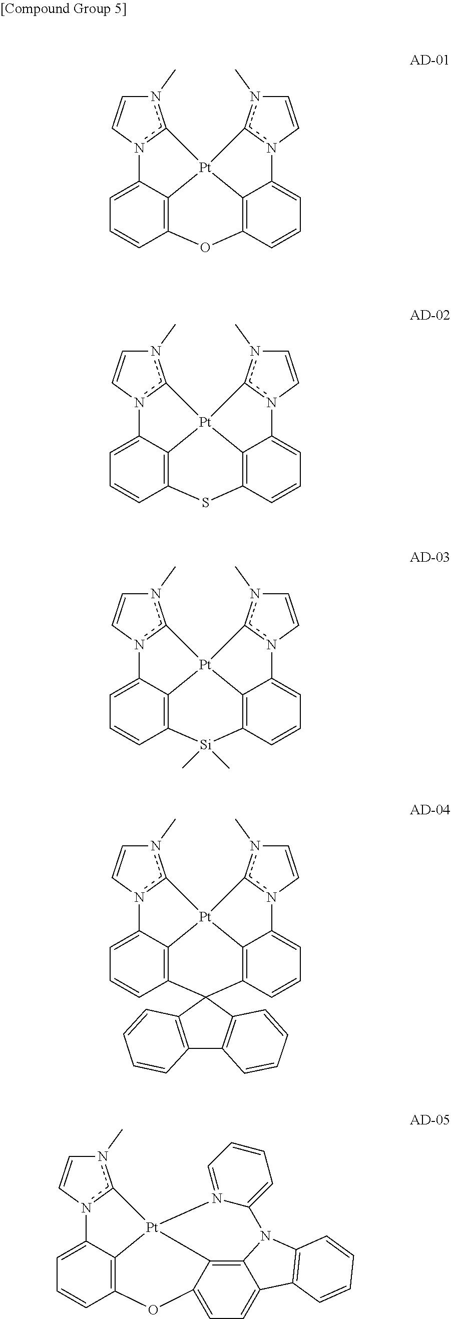

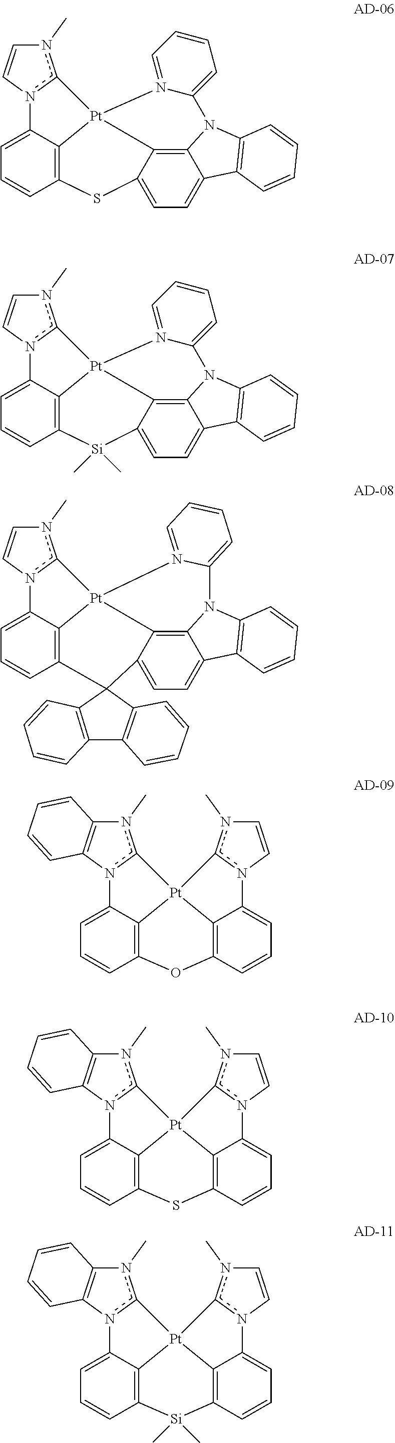

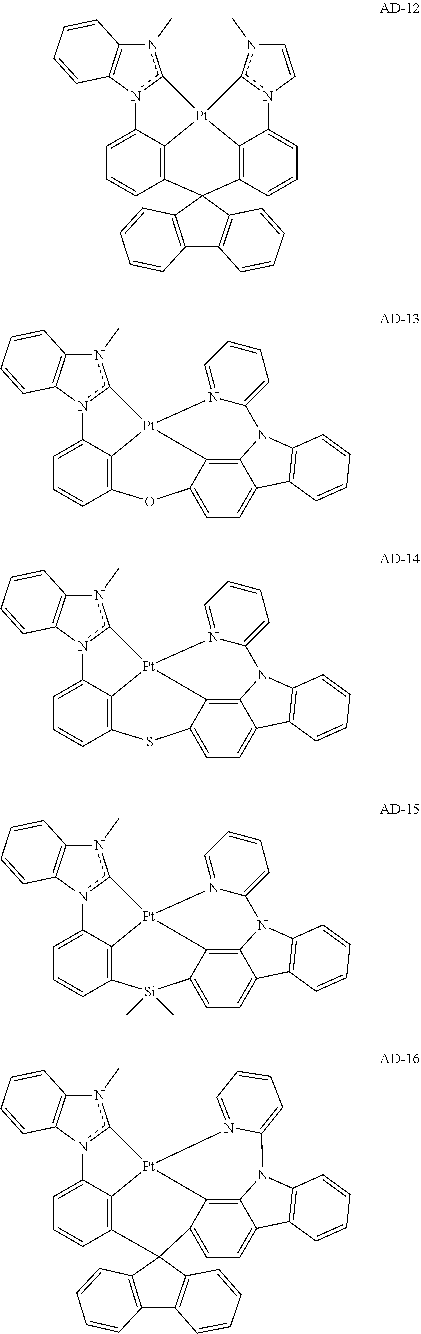

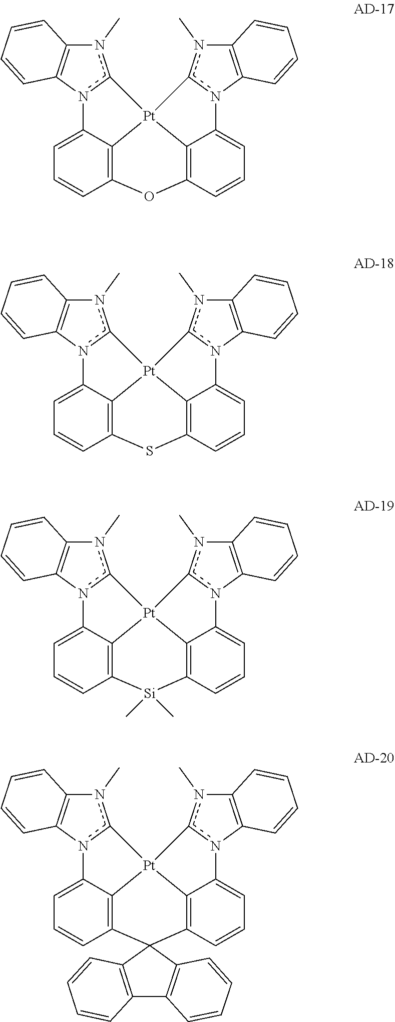

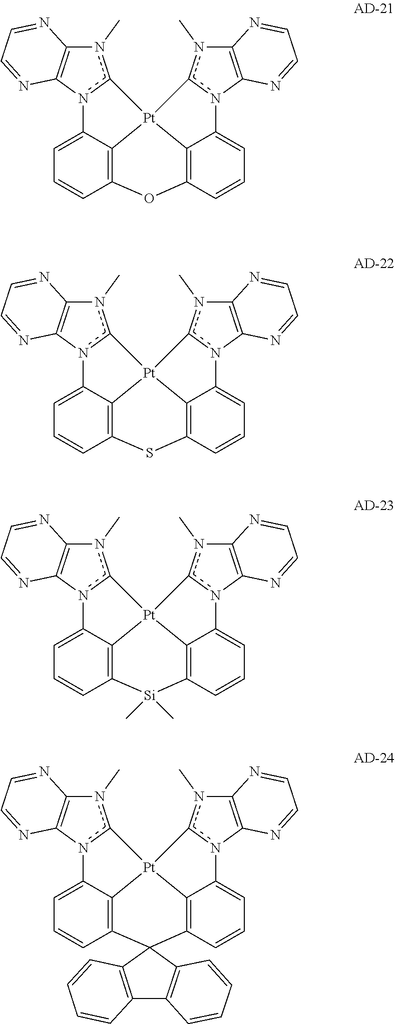

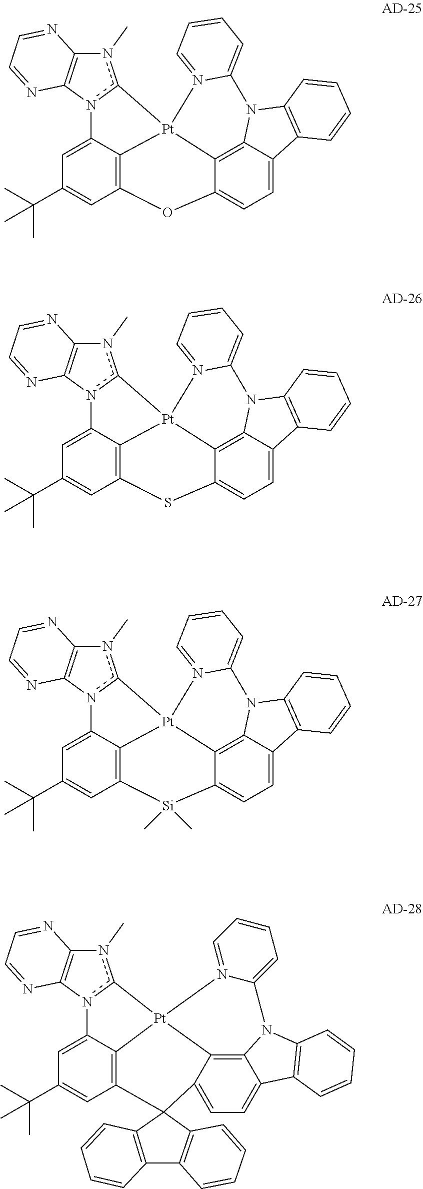

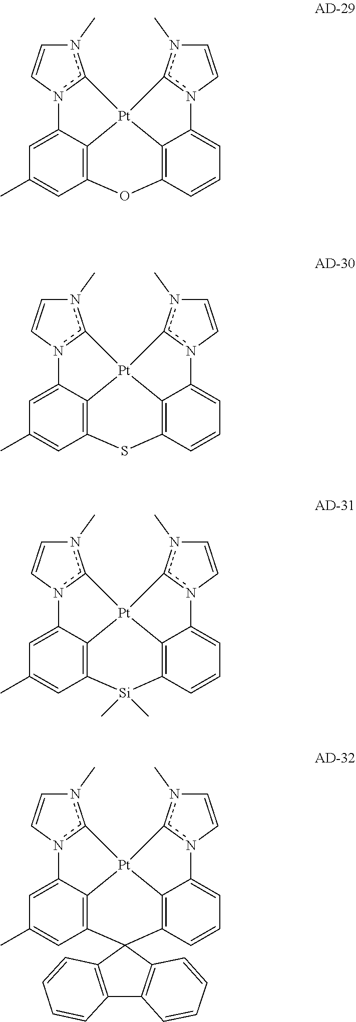

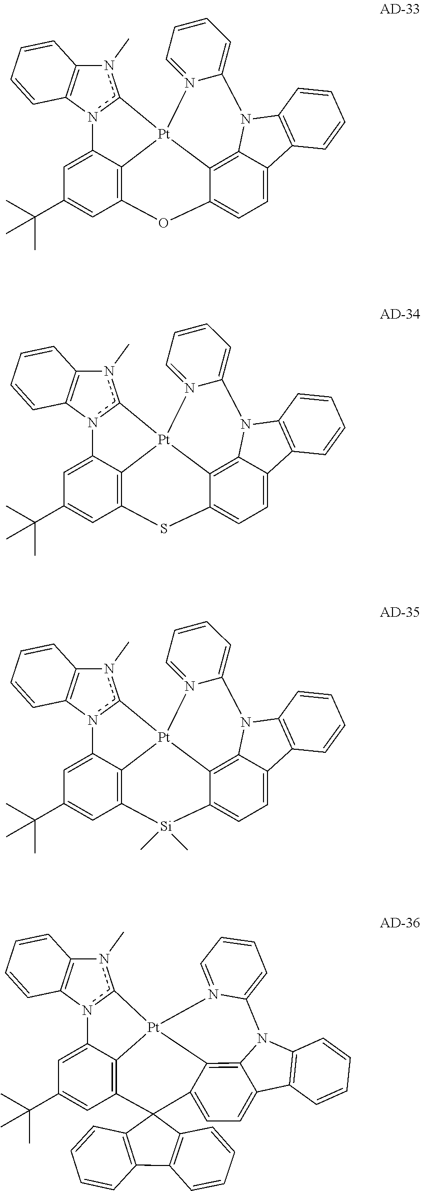

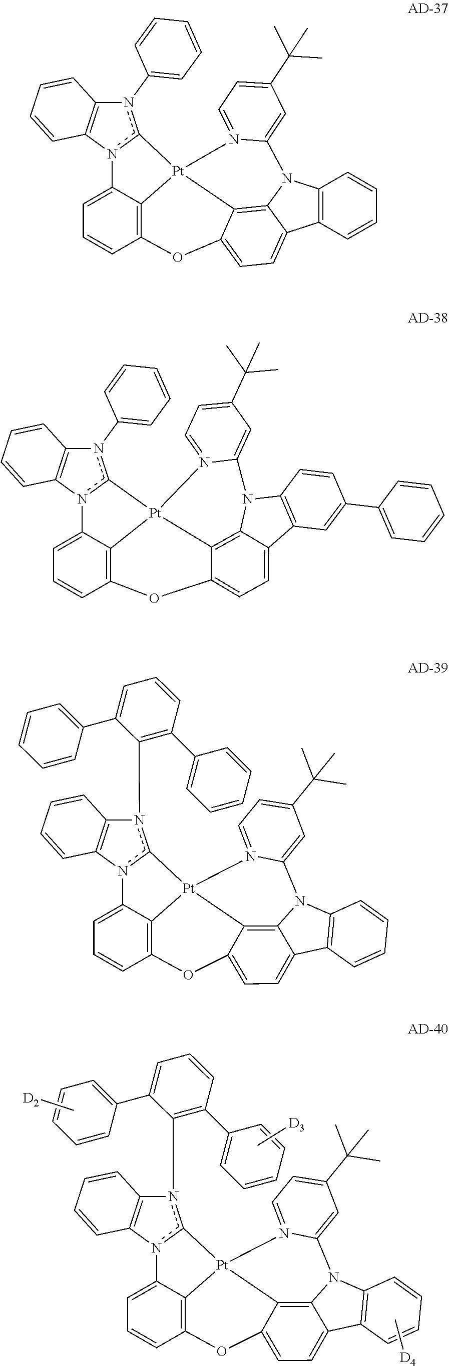

In an aspect, the light-emitting layers EML-L and EML-T may include a quantum dot material.

A light-emitting element ED-1 according to the aspect illustrated in FIG. 8 is different only in the number of the light-emitting structures being stacked, compared to the light-emitting element ED described with reference to FIGS. 6 and 7. The content of each of components of the light-emitting element ED, described with reference to FIGS. 4 and 7, may also be equally applied to the light-emitting element ED-1 according to the aspect in FIG. 8.

Referring to FIG. 8, the light-emitting element ED-1 according to an aspect may include n light-emitting structures EU1, EU2, . . . , and EUn disposed between a first electrode AE and a second electrode CE, and n-1 charge generation layers CGL1, CGL2, and CGLn-1. The each of n light-emitting structures EU1, EU2, . . . , and EUn may include a lower functional layer LFL-1, LFL-2, . . . , and LFL-n, and a upper functional layer UFL-1, UFL-2, . . . , and UFL-n. The first light-emitting structure EU1 among the n light-emitting structures EU1, EU2, . . . , and EUn may correspond to the lower light-emitting structure EU-L described with reference to FIGS. 6 and 7, and the n-th light-emitting structure EUn may correspond to the upper light-emitting structure EU-T described with reference to FIGS. 6 and 7.

In the light-emitting element ED-1 according to an aspect, at least the n-th light-emitting layer EML-n may include a first host, a second host, and a dopant. For example, in the light-emitting element ED-1, according to an aspect, including the n light-emitting structures, at least the light-emitting layer EML-n of the n-th light-emitting structure Eun, disposed adjacent to the second electrode CE, may include a first host, a second host, and a dopant, and the first host and the second host may be included in the ratio of about 9:1 to about 8:2. Through this, the light-emitting element ED-1 according to an aspect may have excellent light-emitting efficiency and long lifespan characteristics, and a display device according to an aspect including the light-emitting element may have excellent display quality.

The light-emitting element ED-1 according to an aspect may include a first host, a second host, and a dopant in each of the light-emitting layers EML-1, EML-2, . . . , and EML-n included in the n light-emitting structures EU1, EU2, . . . , and EUn. In this case, the ratio of the first host and the second host may be about 9:1 to about 8:2. The light-emitting element ED-1 according to an aspect may include the first host and the second host mixed in the above-described ratio in each of the light-emitting layers EML-1, EML-2, . . . , and EML-n of the n light-emitting structures EU1, EU2, . . . , and EUn, and also include the dopant, thereby exhibiting high light-emitting efficiency and long lifespan characteristics.

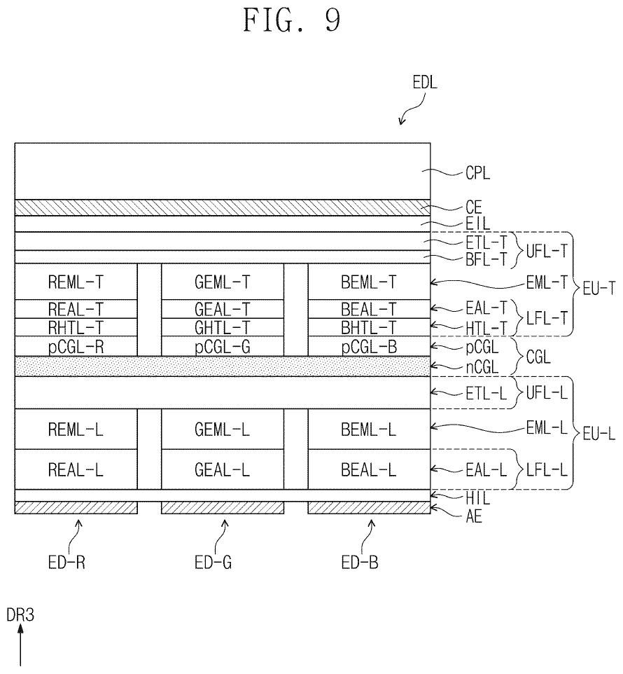

FIG. 9 is a cross-sectional view of a display layer EDL according to an aspect. FIG. 9 exemplarily illustrates the case where each of light-emitting elements ED-R, ED-G, and ED-B of the display layer EDL has the light-emitting element structure illustrated in FIG. 7. However, aspects of the present disclosure are not limited thereto, and any light-emitting element in a tandem element structure may be used, without limitation, for the display layer EDL according to an aspect.

The display layer EDL according to an aspect may include a first electrode AE, a hole injection layer HIL, a lower light-emitting structure EU-L, a charge generation layer CGL, an upper light-emitting structure EU-T, an electron injection layer EIL, a second electrode CE, and a capping layer CPL. In the lower light-emitting structure EU-L, a first lower functional layer LFL-L, a first light-emitting layer EML-L, and a first upper functional layer UFL-L may be included. In addition, in the upper light-emitting structure EU-T, a second lower functional layer LFL-L, a second light-emitting layer EML-T, and a second upper functional layer UFL-T may be included. The charge generation layer CGL may include an n-type charge generation layer nCGL and a p-type charge generation layer pCGL. The n-type charge generation layer nCGL, among the charge generation layers CGL, may be disposed as a common layer in the entire first to third light-emitting elements ED-R, ED-G, and ED-B, and the p-type charge generation layer pCGL may be disposed separately for each of the first to third light-emitting elements ED-R, ED-G, and ED-B.

The first electrode AE may be disposed separately for each of the first to third light-emitting elements ED-R, ED-G, and ED-B. In an aspect, the hole injection layer HIL, the first upper functional layer UFL-L, the second upper functional layer UFL-T, the electron injection layer EIL, the second electrode CE, and the capping layer CPL may each be disposed as a common layer in the entire first to third light-emitting elements ED-R, ED-G, and ED-B. That is, the hole injection layer HIL, the first upper functional layer UFL-L, the second upper functional layer UFL-T, the electron injection layer EIL, the second electrode CE, the n-type charge generation layer nCGL, and the capping layer CPL may overlap in the red light-emitting region PXA-R (see FIG. 5), the green light-emitting region PXA-G (see FIG. 5), and the blue light-emitting region PXA-B (see FIG. 5). However, aspects of the present disclosure are not limited thereto.

In an aspect, the first light-emitting element ED-R may include a first sub-red light-emitting layer REML-L as the first light-emitting layer EML-L, and include a second sub-red light-emitting layer REML-T as the second light-emitting layer EML-T. The first light-emitting element ED-R may include a first auxiliary red light-emitting layer REAL-L as the first lower functional layer LFL-L. In addition, the first light-emitting element ED-R may include a red hole transport layer RHTL-T and a second auxiliary red light-emitting layer REAL-T stacked in sequence on the charge generation layer CGL as the second lower functional layer LFL-T.

The second light-emitting element ED-G may include a first sub-green light-emitting layer GEML-L as the first light-emitting layer EML-L, and include a second sub-green light-emitting layer GEML-T as the second light-emitting layer EML-T. The second light-emitting element ED-G may include a first auxiliary green light-emitting layer GEAL-L as the first lower functional layer LFL-L. In addition, the second light-emitting element ED-G may include a green hole transport layer GHTL-T and a second auxiliary green light-emitting layer GEAL-T stacked in sequence on the charge generation layer CGL as the second lower functional layer LFL-T.

The third light-emitting element ED-B may include a first sub-blue light-emitting layer BEML-L as the first light-emitting layer EML-L, and include a second sub-blue light-emitting layer BEML-T as the second light-emitting layer EML-T. The third light-emitting element ED-B may include a first auxiliary blue light-emitting layer BEAL-L as the first lower functional layer LFL-L. In addition, the third light-emitting element ED-B may include a blue hole transport layer BHTL-T and a second auxiliary blue light-emitting layer BEAL-T, stacked in sequence on the charge generation layer CGL, as the second lower functional layer LFL-T.

The first auxiliary red light-emitting layer REAL-L, the first auxiliary green light-emitting layer GEAL-L, and the first auxiliary blue light-emitting layer BEAL-L may be separately disposed in the first to third light-emitting elements ED-R, ED-G, and ED-B, respectively. The second auxiliary red light-emitting layer REAL-T, the second auxiliary green light-emitting layer GEAL-T, and the second auxiliary blue light-emitting layer BEAL-T may be separately disposed in the first to third light-emitting elements ED-R, ED-G, and ED-B, respectively. When the auxiliary light-emitting layers are included as the first and second lower functional layers LFL-L and LFL-T, the thickness of each of the first and second lower functional layers LFL-L and LFL-T may vary according to the wavelength of light emitted from the first to third light-emitting elements ED-R, ED-G, and ED-B, and is not limited to any one aspect of the present disclosure.

In the display layer EDL according to an aspect, the second light-emitting element ED-G may include a hole transport host, an electron transport host, and a dopant in at least one of the first sub-green light-emitting layer GEML-L or the second sub-green light-emitting layer GEML-T. The dopant, included in the first sub-green light-emitting layer GEML-L and the second sub-green light-emitting layer GEML-T, may be a green light-emitting dopant. The second light-emitting element ED-G may include a hole transport host, an electron transport host, and a dopant in the first sub-green light-emitting layer GEML-L or the second sub-green light-emitting layer GEML-T. Aspects of the present disclosure are not limited thereto, and the second light-emitting element ED-G may include a hole transport host, an electron transport host, and a dopant in each of the first sub-green light-emitting layer GEML-L and the second sub-green light-emitting layer GEML-T. The hole transport host, included in the first sub-green light-emitting layer GEML-L and the second sub-green light-emitting layer GEML-T, may be a compound represented by Formula HT-1 previously described. The electron transport host, included in the first sub-green light-emitting layer GEML-L and the second sub-green light-emitting layer GEML-T, may be a compound represented by Formula ET-1 previously described. Aspects of the present disclosure are not limited thereto, and known hole transport host and electron transport host may also be included.

In the display layer EDL according to an aspect, the third light-emitting element ED-B may include a first host, a second host, and a dopant at least in the second sub-blue light-emitting layer BEML-T. The dopant included in the third light-emitting element ED-B may be a blue light-emitting dopant. In the third light-emitting element ED-B according to an aspect, the first host, the second host, and the dopant may be included only in the second sub-blue light-emitting layer BEML-T. In addition, in the third light-emitting element ED-B according to an aspect, the first host, the second host, and the dopant may be included in each of the first and second sub-blue light-emitting layers BEML-L and BEML-T. The ratio of the first host and the second host, included in the first and second sub-blue light-emitting layers BEML-L and BEML-T, may be about 9:1 to about 8:2.

Since the third light-emitting element ED-B including the dopant as a light-emitting material, together with the first and second hosts mixed in the above-described ratio, has high efficiency and long lifespan characteristics, a display device according to an aspect including this light-emitting element may have improved reliability characteristics due to the excellent display quality and long lifespan.

Hereinafter, referring to examples and comparative examples, a light-emitting element according to an aspect of the present disclosure is described in detail. In addition, the following examples are intended to assist understanding of the present disclosure, and the scope of the present disclosure is not limited thereto.

### Example 1

### 1. Manufacturing Light-Emitting Element

For a light-emitting element according to Example 1, a glass substrate, in which an electrode of ITO/Ag/ITO (about 120 Å/about 500 Å/about 120 Å) was formed as a first electrode, was cut into a size of about 50 mm×about 50 mm×about 0.5 mm, and washed with ultrasonic waves using isopropyl alcohol and pure water for about 15 minutes each, then exposed to plasma to wash, and the glass substrate was installed in a vacuum deposition device. H-1-1:F4-TCNQ (about 3 wt %) was deposited in about 10 nm onto an upper part of the anode to form a hole injection layer, and H-1-1 was deposited in a thickness of about 30 nm onto an upper part of the hole injection layer to form a hole transport layer. H-1-21 was deposited in a thickness of about 10 nm onto the hole transport layer to form an electron-blocking layer, and onto the electron-blocking layer, a first host BH1-2 and a second host BH2-1 in an amount of about 99 wt % in a weight ratio of about 9:1 and a dopant BD1 in an amount of about 1 wt % were co-deposited in a thickness of about 20 nm to form a first light-emitting layer. Next, ET37 was deposited in a thickness of about 10 nm onto an upper part of the first light-emitting layer to form a hole-blocking layer, and a first light-emitting unit was formed therefrom.

2,9-diphenyl-1,10-phenanthroline was deposited in a thickness of about 30 nm onto an upper part of the hole-blocking layer to form an electron transport layer. Continuously, 2,9-diphenyl-1,10-phenanthroline:Li (about 5 wt %) was deposited in a thickness of about 10 nm to form an n-type charge generation layer nCGL in common, and then H1-1:F4-TCNQ (about 10 wt %) was deposited in a thickness of about 10 nm to form a p-type charge generation layer pCGL in common.

Again, for a second light-emitting unit, a hole injection layer, a hole transport layer, an electron-blocking layer, a second light-emitting layer, and a hole-blocking layer were stacked on an upper part of the pCGL in the same manner as that of the first light-emitting unit. Next, on an upper part of the hole-blocking layer, ET39 was deposited in a thickness of about 30 nm to form an electron transport layer, then Yb was deposited in a thickness of about 10 Å and then Ag and Mg were co-deposited in a thickness of about 100 Å in a weight ratio of about 9:1 to form a second electrode, and on the second electrode, P4 was deposited in a thickness of about 700 Å to form a capping layer, and the light-emitting element was manufactured therefrom.

### Example 2

### 1. Manufacturing Light-Emitting Element

For a light-emitting element according to Example 2, a glass substrate, in which an electrode of ITO/Ag/ITO (about 120 Å/about 500 Å/about 120 Å) was formed as a first electrode, was cut into a size of about 50 mm×about 50 mm×about 0.5 mm, and washed with ultrasonic waves using isopropyl alcohol and pure water for about 15 minutes each, then exposed to plasma to wash, and the glass substrate was installed in a vacuum deposition device. H-1-1:F4-TCNQ (about 3 wt %) was deposited in about 10 nm onto an upper part of the anode to form a hole injection layer, and H-1-1 was deposited in a thickness of about 30 nm onto an upper part of the hole injection layer to form a hole transport layer. H-1-21 was deposited in a thickness of about 10 nm onto the hole transport layer to form an electron-blocking layer, and onto the electron-blocking layer, a first host BH1-2 and a second host BH2-1 in an amount of about 99 wt % in a weight ratio of about 8:2 and a dopant BD1 in an amount of about 1 wt % were co-deposited in a thickness of about 20 nm to form a first light-emitting layer. Next, ET37 was deposited in a thickness of about 10 nm onto an upper part of the first light-emitting layer to form a hole-blocking layer, and a first light-emitting unit was formed therefrom.

2,9-diphenyl-1,10-phenanthroline was deposited in a thickness of about 30 nm onto an upper part of the hole-blocking layer to form an electron transport layer. Continuously, 2,9-diphenyl-1,10-phenanthroline:Li (about 5 wt %) was deposited in a thickness of about 10 nm to form an n-type charge generation layer nCGL in common, and then H1-1:F4-TCNQ (about 10 wt %) was deposited in a thickness of about 10 nm to form a p-type charge generation layer pCGL in common.

Again, for a second light-emitting unit, a hole injection layer, a hole transport layer, an electron-blocking layer, a second light-emitting layer, and a hole-blocking layer were stacked on an upper part of the pCGL in the same manner as that of the first light-emitting unit. Next, on an upper part of the hole-blocking layer, ET39 was deposited in a thickness of about 30 nm to form an electron transport layer, then Yb was deposited in a thickness of about 10 Å and then Ag and Mg were co-deposited in a thickness of about 100 Å in a weight ratio of about 9:1 to form a second electrode, and on the second electrode, P4 was stacked in a thickness of about 700 Å to form a capping layer, and the light-emitting element was manufactured therefrom.

### Example 3

### 1. Manufacturing Light-Emitting Element

For a light-emitting element according to Example 3, a glass substrate, in which an electrode of ITO/Ag/ITO (about 120 Å/about 500 Å/about 120 Å) was formed as a first electrode, was cut into a size of about 50 mm×about 50 mm×about 0.5 mm, and washed with ultrasonic waves using isopropyl alcohol and pure water for about 15 minutes each, then exposed to plasma to wash, and the glass substrate was installed in a vacuum deposition device. H-1-1:F4-TCNQ (about 3 wt %) was deposited in about 10 nm onto an upper part of the anode to form a hole injection layer, and H-1-1 was deposited in a thickness of about 30 nm onto an upper part of the hole injection layer to form a hole transport layer. H-1-21 was deposited in a thickness of about 10 nm onto the hole transport layer to form an electron-blocking layer, and onto the electron-blocking layer, a first host BH1-2 in an amount of about 99 wt % and a dopant BD1 in an amount of about 1 wt % were co-deposited in a thickness of about 20 nm to form a first light-emitting layer. Next, ET37 was deposited in a thickness of about 10 nm onto an upper part of the first light-emitting layer to form a hole-blocking layer, and a first light-emitting unit was formed therefrom.

2,9-diphenyl-1,10-phenanthroline was deposited in a thickness of about 30 nm onto an upper part of the hole-blocking layer to form an electron transport layer. Continuously, 2,9-diphenyl-1,10-phenanthroline:Li (about 5 wt %) was deposited in a thickness of about 10 nm to form an n-type charge generation layer nCGL in common, and then H1-1:F4-TCNQ (about 10 wt %) was deposited in a thickness of about 10 nm to form a p-type charge generation layer pCGL in common.

Again, for a second light-emitting unit, a hole injection layer, a hole transport layer, an electron-blocking layer were stacked on an upper part of the pCGL in the same manner as that of the first light-emitting unit. Onto the electron-blocking layer, BH1-2 and BH2-1 in a weight ratio of about 9:1 and a dopant in an amount of about 1 wt % were co-deposited in a thickness of about 20 nm to form a second light-emitting layer. Next, ET37 was deposited in a thickness of about 10 nm onto an upper part of the second light-emitting layer to form a hole-blocking layer, and the second light-emitting unit was formed therefrom. Next, on an upper part of the hole-blocking layer, ET39 was deposited in a thickness of about 30 nm to form an electron transport layer, then Yb was deposited in a thickness of about 10 Å and then Ag and Mg were co-deposited in a thickness of about 100 Å in a weight ratio of about 9:1 to form a second electrode, and on the second electrode, P4 was deposited in a thickness of about 700 Å to form a capping layer, and the light-emitting element was manufactured therefrom.

### Example 4

### 1. Manufacturing Light-Emitting Element

For a light-emitting element according to Example 4, a glass substrate, in which an electrode of ITO/Ag/ITO (about 120 Å/about 500 Å/about 120 Å) was formed as a first electrode, was cut into a size of about 50 mm×about 50 mm×about 0.5 mm, and washed with ultrasonic waves using isopropyl alcohol and pure water for about 15 minutes each, then exposed to plasma to wash, and the glass substrate was installed in a vacuum deposition device. H-1-1:F4-TCNQ (about 3 wt %) was deposited in about 10 nm onto an upper part of the anode to form a hole injection layer, and H-1-1 was deposited in a thickness of about 30 nm onto an upper part of the hole injection layer to form a hole transport layer. H-1-21 was deposited in a thickness of about 10 nm onto the hole transport layer to form an electron-blocking layer, and onto the electron-blocking layer, a first host BH1-2 and a second host BH2-5 in an amount of about 99 wt % in a weight ratio of about 9:1 and a dopant BD1 in an amount of about 1 wt % were co-deposited in a thickness of about 20 nm to form a first light-emitting layer. Next, ET37 was deposited in a thickness of about 10 nm onto an upper part of the first light-emitting layer to form a hole-blocking layer, and a first light-emitting unit was formed therefrom.

2,9-diphenyl-1,10-phenanthroline was deposited in a thickness of about 30 nm onto an upper part of the hole-blocking layer to form an electron transport layer. Continuously, 2,9-diphenyl-1,10-phenanthroline:Li (about 5 wt %) was deposited in a thickness of about 10 nm to form an n-type charge generation layer nCGL in common, and then H1-1:F4-TCNQ (about 10 wt %) was deposited in a thickness of about 10 nm to form a p-type charge generation layer pCGL in common.

Again, for a second light-emitting unit, a hole injection layer, a hole transport layer, an electron-blocking layer, a second light-emitting layer, and a hole-blocking layer were stacked on an upper part of the pCGL in the same manner as that of the first light-emitting unit. Next, on an upper part of the hole-blocking layer, ET39 was deposited in a thickness of about 30 nm to form an electron transport layer, then Yb was deposited in a thickness of about 10 Å and then Ag and Mg were co-deposited in a thickness of about 100 Å in a weight ratio of about 9:1 to form a second electrode, and on the second electrode, P4 was stacked in a thickness of about 700 Å to form a capping layer CPL, and the light-emitting element was manufactured therefrom.

### Example 5

### 1. Manufacturing Light-Emitting Element

For a light-emitting element according to Example 5, a glass substrate, in which an electrode of ITO/Ag/ITO (about 120 Å/about 500 Å/about 120 Å) was formed as a first electrode, was cut into a size of about 50 mm×about 50 mm×about 0.5 mm, and washed with ultrasonic waves using isopropyl alcohol and pure water for about 15 minutes each, then exposed to plasma to wash, and the glass substrate was installed in a vacuum deposition device. H-1-1:F4-TCNQ (about 3 wt %) was deposited in about 10 nm onto an upper part of the anode to form a hole injection layer, and H-1-1 was deposited in a thickness of about 30 nm onto an upper part of the hole injection layer to form a hole transport layer. H-1-21 was deposited in a thickness of about 10 nm onto the hole transport layer to form an electron-blocking layer, and onto the electron-blocking layer, a first host BH1-2 and a second host BH2-5 in an amount of about 99 wt % in a weight ratio of about 8:2 and a dopant BD1 in an amount of about 1 wt % were co-deposited in a thickness of about 20 nm to form a first light-emitting layer. Next, ET37 was deposited in a thickness of about 10 nm onto an upper part of the first light-emitting layer to form a hole-blocking layer, and a first light-emitting unit was formed therefrom.

2,9-diphenyl-1,10-phenanthroline was deposited in a thickness of about 30 nm onto an upper part of the hole-blocking layer to form an electron transport layer. Continuously, 2,9-diphenyl-1,10-phenanthroline:Li (about 5 wt %) was deposited in a thickness of about 10 nm to form an n-type charge generation layer nCGL in common, and then H1-1:F4-TCNQ (about 10 wt %) was deposited in a thickness of about 10 nm to form a p-type charge generation layer pCGL in common.

Again, for a second light-emitting unit, a hole injection layer, a hole transport layer, an electron-blocking layer, a second light-emitting layer, and a hole-blocking layer were stacked on an upper part of the pCGL in the same manner as that of the first light-emitting unit. Next, on an upper part of the hole-blocking layer, ET39 was deposited in a thickness of about 30 nm to form an electron transport layer, then Yb was deposited in a thickness of about 10 Å and then Ag and Mg were co-deposited in a thickness of about 100 Å in a weight ratio of about 9:1 to form a second electrode, and on the second electrode, P4 was stacked in a thickness of about 700 Å to form a capping layer CPL, and the light-emitting element was manufactured therefrom.

### Example 6

### 1. Manufacturing Light-Emitting Element

For a light-emitting element according to Example 6, a glass substrate, in which an electrode of ITO/Ag/ITO (about 120 Å/about 500 Å/about 120 Å) was formed as a first electrode, was cut into a size of about 50 mm×about 50 mm×about 0.5 mm, and washed with ultrasonic waves using isopropyl alcohol and pure water for about 15 minutes each, then exposed to plasma to wash, and the glass substrate was installed in a vacuum deposition device. H-1-1:F4-TCNQ (about 3 wt %) was deposited in about 10 nm onto an upper part of the anode to form a hole injection layer, and H-1-1 was deposited in a thickness of about 30 nm onto an upper part of the hole injection layer to form a hole transport layer. H-1-21 was deposited in a thickness of about 10 nm onto the hole transport layer to form an electron-blocking layer, and onto the electron-blocking layer, a first host BH1-3 and a second host BH2-5 in an amount of about 99 wt % in a weight ratio of about 9:1 and a dopant BD1 in an amount of about 1 wt % were co-deposited in a thickness of about 20 nm to form a first light-emitting layer. Next, ET37 was deposited in a thickness of about 10 nm onto an upper part of the first light-emitting layer to form a hole-blocking layer, and a first light-emitting unit was formed therefrom.

2,9-diphenyl-1,10-phenanthroline was deposited in a thickness of about 30 nm onto an upper part of the hole-blocking layer to form an electron transport layer. Continuously, 2,9-diphenyl-1,10-phenanthroline:Li (about 5 wt %) was deposited in a thickness of about 10 nm to form an n-type charge generation layer nCGL in common, and then H1-1:F4-TCNQ (about 10 wt %) was deposited in a thickness of about 10 nm to form a p-type charge generation layer pCGL in common.

Again, for a second light-emitting unit, a hole injection layer, a hole transport layer, an electron-blocking layer, a second light-emitting layer, and a hole-blocking layer were stacked on an upper part of the pCGL in the same manner as that of the first light-emitting unit. Next, on an upper part of the hole-blocking layer, ET39 was deposited in a thickness of about 30 nm to form an electron transport layer, then Yb was deposited in a thickness of about 10 Å and then Ag and Mg were co-deposited in a thickness of about 100 Å in a weight ratio of about 9:1 to form a second electrode, and on the second electrode, P4 was stacked in a thickness of about 700 Å to form a capping layer, and the light-emitting element was manufactured therefrom.

### Example 7

### 1. Manufacturing Light-Emitting Element

For a light-emitting element according to Example 7, a glass substrate, in which an electrode of ITO/Ag/ITO (about 120 Å/about 500 Å/about 120 Å) was formed as a first electrode, was cut into a size of about 50 mm×about 50 mm×about 0.5 mm, and washed with ultrasonic waves using isopropyl alcohol and pure water for about 15 minutes each, then exposed to plasma to wash, and the glass substrate was installed in a vacuum deposition device. H-1-1:F4-TCNQ (about 3 wt %) was deposited in about 10 nm onto an upper part of the anode to form a hole injection layer, and H-1-1 was deposited in a thickness of about 30 nm onto an upper part of the hole injection layer to form a hole transport layer. H-1-21 was deposited in a thickness of about 10 nm onto the hole transport layer to form an electron-blocking layer, and onto the electron-blocking layer, a first host BH1-3 and a second host BH2-5 in an amount of about 99 wt % in a weight ratio of about 8:2 and a dopant BD1 in an amount of about 1 wt % were co-deposited in a thickness of about 20 nm to form a first light-emitting layer. Next, ET37 was deposited in a thickness of about 10 nm onto an upper part of the first light-emitting layer to form a hole-blocking layer, and a first light-emitting unit was formed therefrom.

2,9-diphenyl-1,10-phenanthroline was deposited in a thickness of about 30 nm onto an upper part of the hole-blocking layer to form an electron transport layer. Continuously, 2,9-diphenyl-1,10-phenanthroline:Li (about 5 wt %) was deposited in a thickness of about 10 nm to form an n-type charge generation layer nCGL in common, and then H1-1:F4-TCNQ (about 10 wt %) was deposited in a thickness of about 10 nm to form a p-type charge generation layer pCGL in common.

Again, for a second light-emitting unit, a hole injection layer, a hole transport layer, an electron-blocking layer, a second light-emitting layer, and a hole-blocking layer were stacked on an upper part of the pCGL in the same manner as that of the first light-emitting unit. Next, on an upper part of the hole-blocking layer, ET39 was deposited in a thickness of about 30 nm to form an electron transport layer, then Yb was deposited in a thickness of about 10 Å and then Ag and Mg were co-deposited in a thickness of about 100 Å in a weight ratio of about 9:1 to form a second electrode, and on the second electrode, P4 was stacked in a thickness of about 700 Å to form a capping layer, and the light-emitting element was manufactured therefrom.

### Example 8

### 1. Manufacturing Light-Emitting Element

For a light-emitting element according to Example 8, a glass substrate, in which an electrode of ITO/Ag/ITO (about 120 Å/about 500 Å/about 120 Å) was formed as a first electrode, was cut into a size of about 50 mm×about 50 mm×about 0.5 mm, and washed with ultrasonic waves using isopropyl alcohol and pure water for about 15 minutes each, then exposed to plasma to wash, and the glass substrate was installed in a vacuum deposition device. H-1-1:F4-TCNQ (about 3 wt %) was deposited in about 10 nm onto an upper part of the anode to form a hole injection layer, and H-1-1 was deposited in a thickness of about 30 nm onto an upper part of the hole injection layer to form a hole transport layer. H-1-21 was deposited in a thickness of about 10 nm onto the hole transport layer to form an electron-blocking layer, and onto the electron-blocking layer, a first host BH1-5 and a second host BH2-25 in an amount of about 99 wt % in a weight ratio of about 9:1 and a dopant BD1 in an amount of about 1 wt % were co-deposited in a thickness of about 20 nm to form a first light-emitting layer. Next, ET37 was deposited in a thickness of about 10 nm onto an upper part of the first light-emitting layer to form a hole-blocking layer, and a first light-emitting unit was formed therefrom.

2,9-diphenyl-1,10-phenanthroline was deposited in a thickness of about 30 nm onto an upper part of the hole-blocking layer to form an electron transport layer. Continuously, 2,9-diphenyl-1,10-phenanthroline:Li (about 5 wt %) was deposited in a thickness of about 10 nm to form an n-type charge generation layer nCGL in common, and then H1-1:F4-TCNQ (about 10 wt %) was deposited in a thickness of about 10 nm to form a p-type charge generation layer pCGL in common.

Again, for a second light-emitting unit, a hole injection layer, a hole transport layer, an electron-blocking layer, a second light-emitting layer, and a hole-blocking layer were stacked on an upper part of the pCGL in the same manner as that of the first light-emitting unit. Next, on an upper part of the hole-blocking layer, ET39 was deposited in a thickness of about 30 nm to form an electron transport layer, then Yb was deposited in a thickness of about 10 Å and then Ag and Mg were co-deposited in a thickness of about 100 Å in a weight ratio of about 9:1 to form a second electrode, and on the second electrode, P4 was deposited in a thickness of about 700 Å to form a capping layer, and the light-emitting element was manufactured therefrom.

### Example 9

### 1. Manufacturing Light-Emitting Element

For a light-emitting element according to Example 9, a glass substrate, in which an electrode of ITO/Ag/ITO (about 120 Å/about 500 Å/about 120 Å) was formed as a first electrode, was cut into a size of about 50 mm×about 50 mm×about 0.5 mm, and washed with ultrasonic waves using isopropyl alcohol and pure water for about 15 minutes each, then exposed to plasma to wash, and the glass substrate was installed in a vacuum deposition device. H-1-1:F4-TCNQ (about 3 wt %) was deposited in about 10 nm onto an upper part of the anode to form a hole injection layer, and H-1-1 was deposited in a thickness of about 30 nm onto an upper part of the hole injection layer to form a hole transport layer. H-1-21 was deposited in a thickness of about 10 nm onto the hole transport layer to form an electron-blocking layer, and onto the electron-blocking layer, a first host BH1-5 and a second host BH2-25 in an amount of about 99 wt % in a weight ratio of about 8:2 and a dopant BD1 in an amount of about 1 wt % were co-deposited in a thickness of about 20 nm to form a first light-emitting layer. Next, ET37 was deposited in a thickness of about 10 nm onto an upper part of the first light-emitting layer to form a hole-blocking layer, and a first light-emitting unit was formed therefrom.

2,9-diphenyl-1,10-phenanthroline was deposited in a thickness of about 30 nm onto an upper part of the hole-blocking layer to form an electron transport layer. Continuously, 2,9-diphenyl-1,10-phenanthroline:Li (about 5 wt %) was deposited in a thickness of about 10 nm to form an n-type charge generation layer nCGL in common, and then H1-1:F4-TCNQ (about 10 wt %) was deposited in a thickness of about 10 nm to form a p-type charge generation layer pCGL in common.

Again, for a second light-emitting unit, a hole injection layer, a hole transport layer, an electron-blocking layer, a second light-emitting layer, and a hole-blocking layer were stacked on an upper part of the pCGL in the same manner as that of the first light-emitting unit. Next, on an upper part of the hole-blocking layer, ET39 was deposited in a thickness of about 30 nm to form an electron transport layer, then Yb was deposited in a thickness of about 10 Å and then Ag and Mg were co-deposited in a thickness of about 100 Å in a weight ratio of about 9:1 to form a second electrode, and on the second electrode, P4 was deposited in a thickness of about 700 Å to form a capping layer, and the light-emitting element was manufactured therefrom.

### Comparative Example 1

### 1. Manufacturing Light-Emitting Element

For a light-emitting element according to Comparative Example 1, a glass substrate, in which an electrode of ITO/Ag/ITO (about 120 Å/about 500 Å/about 120 Å) was formed as a first electrode, was cut into a size of about 50 mm×about 50 mm×about 0.5 mm, and washed with ultrasonic waves using isopropyl alcohol and pure water for about 15 minutes each, then exposed to plasma to wash, and the glass substrate was installed in a vacuum deposition device. H-1-1:F4-TCNQ (about 3 wt %) was deposited in about 10 nm onto an upper part of the anode to form a hole injection layer, and H-1-1 was deposited in a thickness of about 30 nm onto an upper part of the hole injection layer to form a hole transport layer. H-1-21 was deposited in a thickness of about 10 nm onto the hole transport layer to form an electron-blocking layer, and onto the electron-blocking layer, BH1-2 and a dopant BD1 in an amount of about 1 wt % were co-deposited in a thickness of about 20 nm to form a first light-emitting layer. Next, ET37 was deposited in a thickness of about 10 nm onto an upper part of the first light-emitting layer to form a hole-blocking layer, and a first light-emitting unit was formed therefrom.

2,9-diphenyl-1,10-phenanthroline was deposited in a thickness of about 30 nm onto an upper part of the hole-blocking layer to form an electron transport layer. Continuously, 2,9-diphenyl-1,10-phenanthroline:Li (about 5 wt %) was deposited in a thickness of about 10 nm to form an n-type charge generation layer nCGL in common, and then H1-1:F4-TCNQ (about 10 wt %) was deposited in a thickness of about 10 nm to form a p-type charge generation layer pCGL in common.

Again, for a second light-emitting unit, a hole injection layer, a hole transport layer, an electron-blocking layer, a second light-emitting layer, and a hole-blocking layer were stacked on an upper part of the pCGL in the same manner as that of the first light-emitting unit. Next, on an upper part of the hole-blocking layer, ET39 was deposited in a thickness of about 30 nm to form an electron transport layer, then Yb was deposited in a thickness of about 10 Å and then Ag and Mg were co-deposited in a thickness of about 100 Ain a weight ratio of about 9:1 to form a second electrode, and on the second electrode, P4 was deposited in a thickness of about 700 Å to form a capping layer, and the light-emitting element was manufactured therefrom.

### Comparative Example 2

### 1. Manufacturing Light-Emitting Element

For a light-emitting element according to Comparative Example 2, a glass substrate, in which an electrode of ITO/Ag/ITO (about 120 Å/about 500 Å/about 120 Å) was formed as a first electrode, was cut into a size of about 50 mm×about 50 mm×about 0.5 mm, and washed with ultrasonic waves using isopropyl alcohol and pure water for about 15 minutes each, then exposed to plasma to wash, and the glass substrate was installed in a vacuum deposition device. H-1-1:F4-TCNQ (about 3 wt %) was deposited in about 10 nm onto an upper part of the anode to form a hole injection layer, and H-1-1 was deposited in a thickness of about 30 nm onto an upper part of the hole injection layer to form a hole transport layer. H-1-21 was deposited in a thickness of about 10 nm onto the hole transport layer to form an electron-blocking layer, and onto the electron-blocking layer, BH1-2 and BH2-1 in a weight ratio of about 7:3, and a dopant BD1 in an amount of about 1 wt % were co-deposited in a thickness of about 20 nm to form a first light-emitting layer. Next, ET37 was deposited in a thickness of about 10 nm onto an upper part of the first light-emitting layer to form a hole-blocking layer, and a first light-emitting unit was formed therefrom.

2,9-diphenyl-1,10-phenanthroline was deposited in a thickness of about 30 nm onto an upper part of the hole-blocking layer to form an electron transport layer. Continuously, 2,9-diphenyl-1,10-phenanthroline:Li (about 5 wt %) was deposited in a thickness of about 10 nm to form an n-type charge generation layer nCGL in common, and then H1-1:F4-TCNQ (about 10 wt %) was deposited in a thickness of about 10 nm to form a p-type charge generation layer pCGL in common.

Again, for a second light-emitting unit, a hole injection layer, a hole transport layer, an electron-blocking layer, a second light-emitting layer, and a hole-blocking layer were stacked on an upper part of the pCGL in the same manner as that of the first light-emitting unit. Next, on an upper part of the hole-blocking layer, ET39 was deposited in a thickness of about 30 nm to form an electron transport layer, then Yb was deposited in a thickness of about 10 Å and then Ag and Mg were co-deposited in a thickness of about 100 Å in a weight ratio of about 9:1 to form a second electrode, and on the second electrode, P4 was stacked in a thickness of about 700 Å to form a capping layer, and the light-emitting element was manufactured therefrom.

### Comparative Example 3

### 1. Manufacturing Light-Emitting Element

For a light-emitting element according to Comparative Example 3, a glass substrate, in which an electrode of ITO/Ag/ITO (about 120 Å/about 500 Å/about 120 Å) was formed as a first electrode, was cut into a size of about 50 mm×about 50 mm×about 0.5 mm, and washed with ultrasonic waves using isopropyl alcohol and pure water for about 15 minutes each, then exposed to plasma to wash, and the glass substrate was installed in a vacuum deposition device. H-1-1:F4-TCNQ (about 3 wt %) was deposited in about 10 nm onto an upper part of the anode to form a hole injection layer, and H-1-1 was deposited in a thickness of about 30 nm onto an upper part of the hole injection layer to form a hole transport layer. H-1-21 was deposited in a thickness of about 10 nm onto the hole transport layer to form an electron-blocking layer, and onto the electron-blocking layer, BH1-2 and BH2-1 in a weight ratio of about 9:1, and a dopant BD1 in an amount of about 1 wt % were co-deposited in a thickness of about 20 nm to form a first light-emitting layer. Next, ET37 was deposited in a thickness of about 10 nm onto an upper part of the first light-emitting layer to form a hole-blocking layer, and a first light-emitting unit was formed therefrom.

2,9-diphenyl-1,10-phenanthroline was deposited in a thickness of about 30 nm onto an upper part of the hole-blocking layer to form an electron transport layer. Continuously, 2,9-diphenyl-1,10-phenanthroline:Li (about 5 wt %) was deposited in a thickness of about 10 nm to form an n-type charge generation layer nCGL in common, and then H1-1:F4-TCNQ (about 10 wt %) was deposited in a thickness of about 10 nm to form a p-type charge generation layer pCGL in common.

Again, for a second light-emitting unit, a hole injection layer, a hole transport layer, an electron-blocking layer were stacked on an upper part of the pCGL in the same manner as that of the first light-emitting unit. Onto the electron-blocking layer, BH1-2 and a dopant BD1 in an amount of about 1 wt % were co-deposited in a thickness of about 20 nm to form a second light-emitting layer. Next, ET37 was deposited in a thickness of about 10 nm onto an upper part of the second light-emitting layer to form a hole-blocking layer, and the second light-emitting unit was formed therefrom. Next, on an upper part of the hole-blocking layer, ET39 was deposited in a thickness of about 30 nm to form an electron transport layer, then Yb was deposited in a thickness of about 10 Å and then Ag and Mg were co-deposited in a thickness of about 100 Å in a weight ratio of about 9:1 to form a second electrode, and on the second electrode, P4 was deposited in a thickness of about 700 Å to form a capping layer, and the light-emitting element was manufactured therefrom.

### <Compounds Used in Manufacturing of Light-Emitting Element>

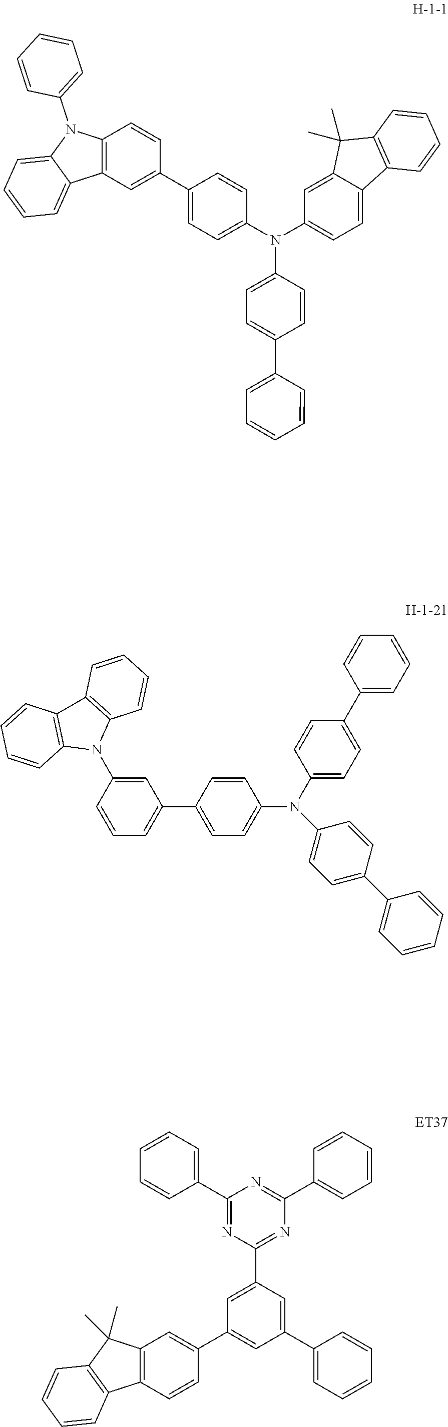 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4ccccc4)cc3)c3ccc(-c4cccc(-n5c6ccccc6c6ccccc65)c4)cc3)cc2)cc1 ; CC1(C)c2ccccc2-c2ccc(-c3cc(-c4ccccc4)cc(-c4nc(-c5ccccc5)nc(-c5ccccc5)n4)c3)cc21]

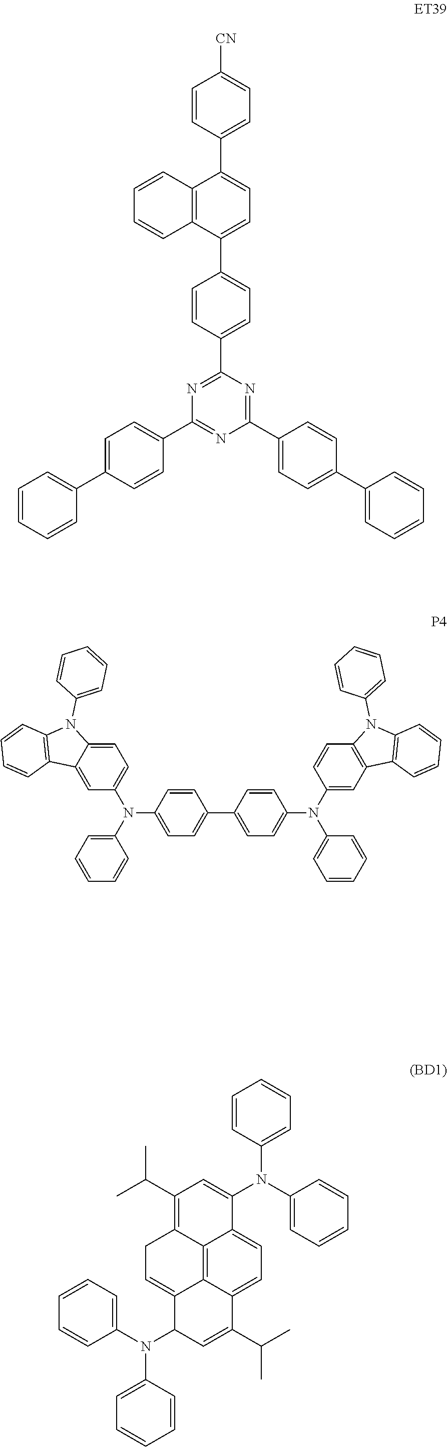 [SMILES: N#Cc1ccc(-c2ccc(-c3ccc(-c4nc(-c5ccc(-c6ccccc6)cc5)nc(-c5ccc(-c6ccccc6)cc5)n4)cc3)c3ccccc23)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC(C)C1=CC(N(c2ccccc2)c2ccccc2)C2=CCc3c(C(C)C)cc(N(c4ccccc4)c4ccccc4)c4ccc1c2c34]

The combinations of light-emitting materials used in the light-emitting elements according to the examples and comparative examples were as follows.

TABLE 1

| | | | | First | |
|---|---|---|---|---|---|
| | | First | Second | host:Second | |
| Classification | | host | host | host | Dopant |
| Example 1 | First light-emitting layer | BH1-2 | BH2-1 | 9:1 | BD1 |
| | Second light-emitting layer | BH1-2 | BH2-1 | 9:1 | BD1 |
| Example 2 | First light-emitting layer | BH1-2 | BH2-1 | 8:2 | BD1 |
| | Second light-emitting layer | BH1-2 | BH2-1 | 8:2 | BD1 |
| Example 3 | First light-emitting layer | BH1-2 | — | — | BD1 |
| | Second light-emitting layer | BH1-2 | BH2-1 | 9:1 | BD1 |
| Example 4 | First light-emitting layer | BH1-2 | BH2-5 | 9:1 | BD1 |
| | Second light-emitting layer | BH1-2 | BH2-5 | 9:1 | BD1 |
| Example 5 | First light-emitting layer | BH1-2 | BH2-5 | 8:2 | BD1 |
| | Second light-emitting layer | BH1-2 | BH2-5 | 8:2 | BD1 |
| Example 6 | First light-emitting layer | BH1-3 | BH2-5 | 9:1 | BD1 |
| | Second light-emitting layer | BH1-3 | BH2-5 | 9:1 | BD1 |
| Example 7 | First light-emitting layer | BH1-3 | BH2-5 | 8:2 | BD1 |
| | Second light-emitting layer | BH1-3 | BH2-5 | 8:2 | BD1 |
| Example 8 | First light-emitting layer | BH1-5 | BH2-25 | 9:1 | BD1 |
| | Second light-emitting layer | BH1-5 | BH2-25 | 9:1 | BD1 |
| Example 9 | First light-emitting layer | BH1-5 | BH2-25 | 8:2 | BD1 |
| | Second light-emitting layer | BH1-5 | BH2-25 | 8:2 | BD1 |
| Comparative | First light-emitting layer | BH1-2 | — | — | BD1 |
| Example 1 | Second light-emitting layer | BH1-2 | — | — | BD1 |
| Comparative | First light-emitting layer | BH1-2 | BH2-1 | 7:3 | BD1 |
| Example 2 | Second light-emitting layer | BH1-2 | BH2-1 | 7:3 | BD1 |
| Comparative | First light-emitting layer | BH1-2 | BH2-1 | 9:1 | BD1 |
| Example 3 | Second light-emitting layer | BH1-2 | — | — | BD1 |

### 2. Evaluation on Light-Emitting Element

Table 2 below shows light-emitting efficiency and lifespan characteristics of the light-emitting elements manufactured according to the examples and comparative examples. The efficiency and lifespan characteristics were expressed as relative values when the efficiency and lifespan of Comparative Example 1 were each set to 100%.

Each of the efficiency and lifespan values listed in Table 2 below was measured using Keithley SMU 236 and a luminance meter (PR650 Spectroscan Source Measurement Unit of PhotoResearch), and the result was expressed as a relative value. The lifespan, listed in Table 2, was a “T97 lifespan”, which was measured as the time taken for the luminance decreasing up to about 97% when the initial luminance was set to 100% in a condition of about 10 mA/cm² current density.

TABLE 2

| Classification | Efficiency (%) | Lifespan (T97, %) |
|---|---|---|
| Example 1 | 102 | 118 |
| Example 2 | 103 | 129 |
| Example 3 | 104 | 108 |
| Example 4 | 101 | 116 |
| Example 5 | 103 | 124 |
| Example 6 | 102 | 129 |
| Example 7 | 104 | 132 |
| Example 8 | 101 | 112 |
| Example 9 | 103 | 119 |
| Comparative Example 1 | 100 | 100 |
| Comparative Example 2 | 102 | 71 |
| Comparative Example 3 | 101 | 100 |

Referring to Table 2, it can be seen that the light-emitting elements according to the examples had excellent light-emitting efficiency and lifespan characteristics, compared to the light-emitting elements according to the comparative examples. Particularly, in the light-emitting elements according to the examples, a first host and a second host were included in a ratio of about 9:1 to about 8:2 in the light-emitting layer of at least upper light-emitting structure among a plurality of light-emitting structures, thereby exhibiting excellent efficiency without substantial increase of driving voltage, and exhibiting long lifespan characteristics.

On the contrary, the light-emitting element according to Comparative Example 1 included only one host and one dopant in the light-emitting layer, thereby exhibiting reduced efficiency and lifespan, compared to the examples. In the light-emitting element according to Comparative Example 2, a first host and a second host were included in the light-emitting layer of at least upper light-emitting structure among a plurality of light-emitting structures, but the first host and the second host were included in the ratio of about 7:3, exhibiting the result of significantly reduced lifespan.

In the light-emitting element according to Comparative Example 3, a first host and a second host were included in the ratio of about 9:1 only in the light-emitting layer of the first light-emitting structure among a plurality of light-emitting structures, exhibiting the result of the efficiency and lifespan of the light-emitting element not substantially improved.

A light-emitting element according to an aspect may include a plurality of light-emitting structures, and may exhibit improved light-emitting efficiency and excellent lifespan characteristics by a combination of light-emitting layer materials at least in a light-emitting structure disposed on an upper part among the plurality of light-emitting structures.

A display device according to an aspect may exhibit excellent display quality and improved lifespan characteristics through the combination of light-emitting layer materials in the plurality of light-emitting structures.

In the above, description has been made with reference to aspects of the present disclosure, but those skilled or of ordinary skill in the art may understand that various modifications and changes may be made to the aspects of the present disclosure insofar as such modifications and changes do not depart from the spirit and technical scope of the present disclosure set forth in the claims to be described later.

Therefore, the technical scope of the present disclosure is not to be limited to the contents stated in the detailed description, but should be determined by the claims.

What is claimed is:

1. A light-emitting element comprising:
a first electrode;
a second electrode facing the first electrode;
a first light-emitting structure between the first electrode and the second electrode, the first light-emitting structure comprising a first lower functional layer, a first light-emitting layer, and a first upper functional layer stacked in that sequence;
a second light-emitting structure on the first light-emitting structure, the second light-emitting structure comprising a second lower functional layer, a second light-emitting layer, and a second upper functional layer stacked in that sequence; and
a charge generation layer between the first light-emitting structure and the second light-emitting structure,
wherein the second light-emitting layer comprises a first host, a second host different from the first host, and a blue light-emitting dopant, and
wherein a ratio of the first host to the second host is about 9:1 to about 8:2.

2. The light-emitting element of claim 1, wherein the first light-emitting layer comprises the first host, the second host, and the blue light-emitting dopant,
wherein the first host included in the first light-emitting layer is the same as the first host included in the second light-emitting layer, and
the second host included in the first light-emitting layer is the same as the second host included in the second light-emitting layer.

3. The light-emitting element of claim 1, wherein the first light-emitting structure and the second light-emitting structure are each configured to emit light having a wavelength in a blue-light wavelength region.

4. The light-emitting element of claim 1, wherein the first host has a HOMO energy level of about −5.1 eV or greater, and a LUMO energy level of about −1.6 eV or less, and
wherein the second host has a HOMO energy level of about −5.2 eV or greater, and a LUMO energy level of about −1.7 eV or less.

5. The light-emitting element of claim 1, wherein the first lower functional layer and the second lower functional layer each comprises an auxiliary light-emitting layer.

6. The light-emitting element of claim 1, wherein the first host is represented by Formula 1: 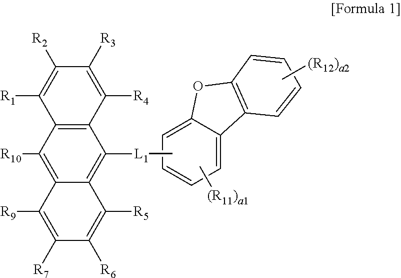
wherein, in Formula 1,
L₁ is a direct linkage, or a substituted or unsubstituted arylene group of 6 to 30 ring-forming carbon atoms,
R₁ to R₇ and R₉ to R₁₁ are each independently a hydrogen atom, a deuterium atom, or a substituted or unsubstituted aryl group of 6 to 30 ring-forming carbon atoms,
R₁₂ is a hydrogen atom, a deuterium atom, a hydroxy group, a substituted or unsubstituted oxy group, a substituted or unsubstituted alkyl group of 1 to 30 carbon atoms, a substituted or unsubstituted alkenyl group of 2 to 30 carbon atoms, or a substituted or unsubstituted aryl group of 6 to 30 ring-forming carbon atoms, or is bonded to an adjacent group to form a ring,
a1 is an integer of 0 to 3, and
a2 is an integer of 0 to 4.

7. The light-emitting element of claim 1, wherein the second host is represented by Formula 2: 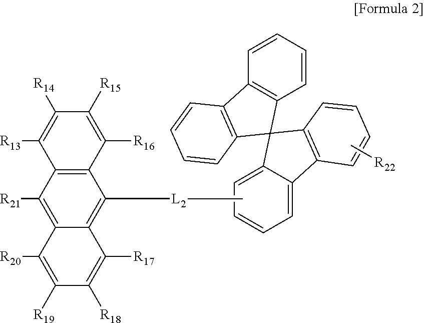
wherein, in Formula 2,
L₂ is a direct linkage, or a substituted or unsubstituted arylene group of 6 to 30 ring-forming carbon atoms,
R₁₃ to R₂₁ are each independently a hydrogen atom, a deuterium atom, or a substituted or unsubstituted aryl group of 6 to 30 ring-forming carbon atoms, and
R₂₂ is a substituted or unsubstituted aryl group of 6 to 30 ring-forming carbon atoms.

8. The light-emitting element of claim 1, wherein the first host is represented by any compound of Compound Group 1:

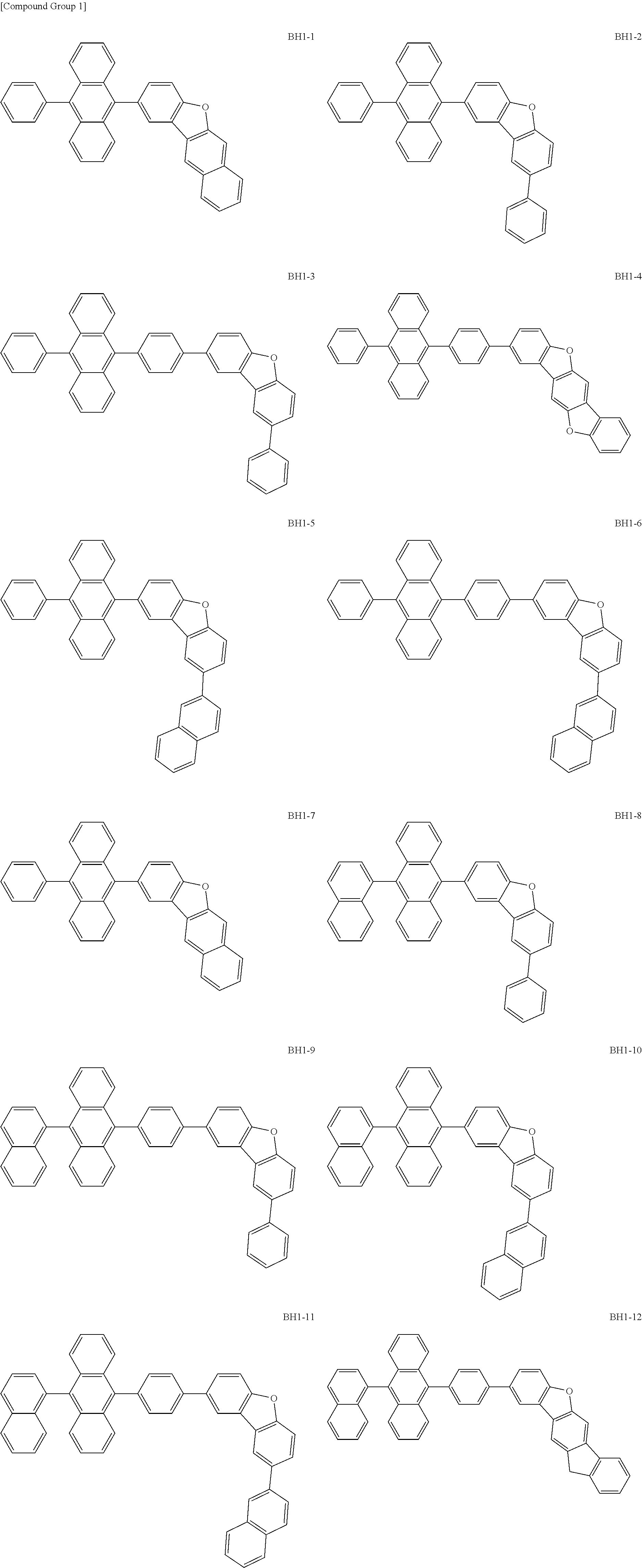

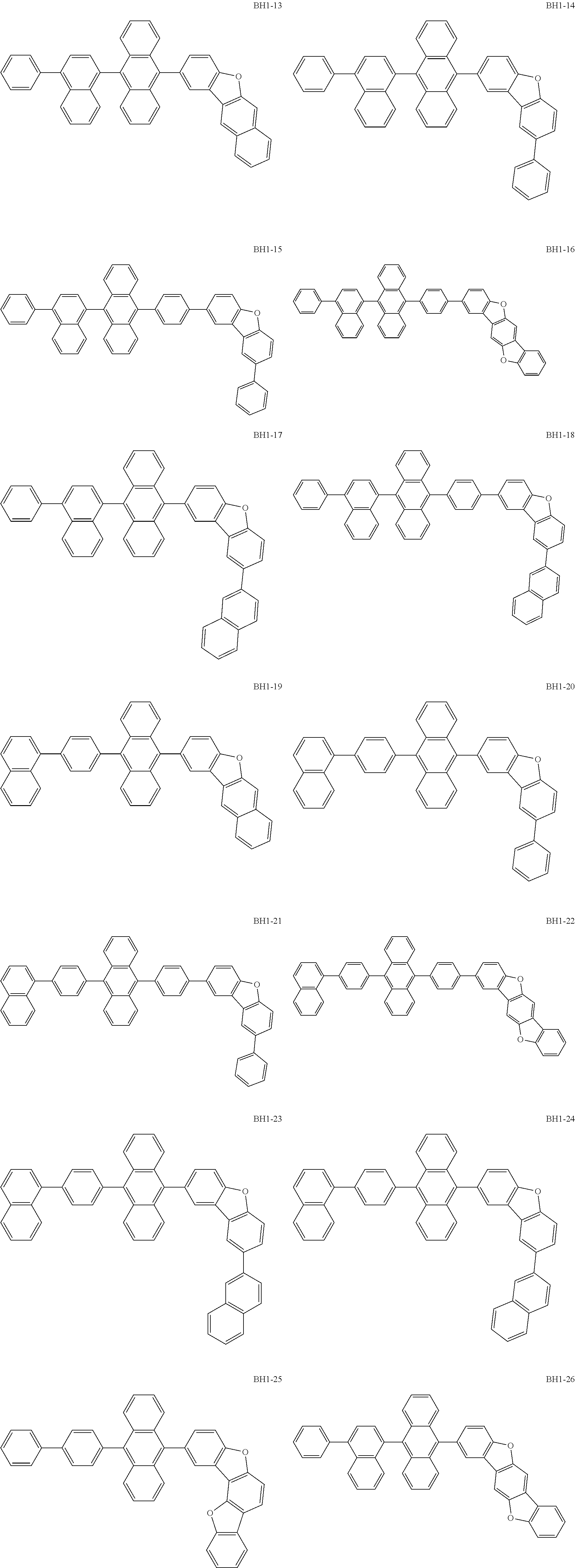

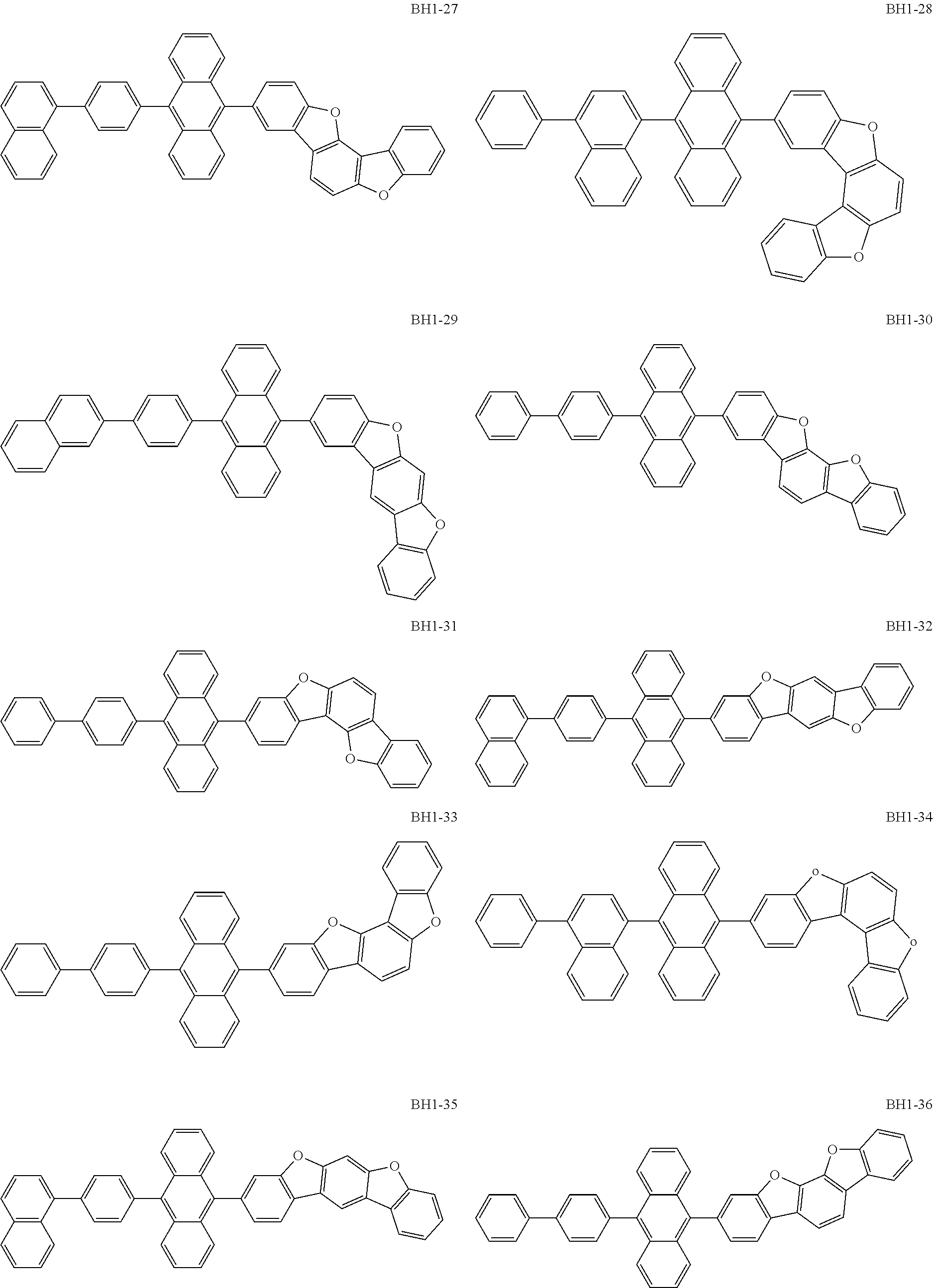

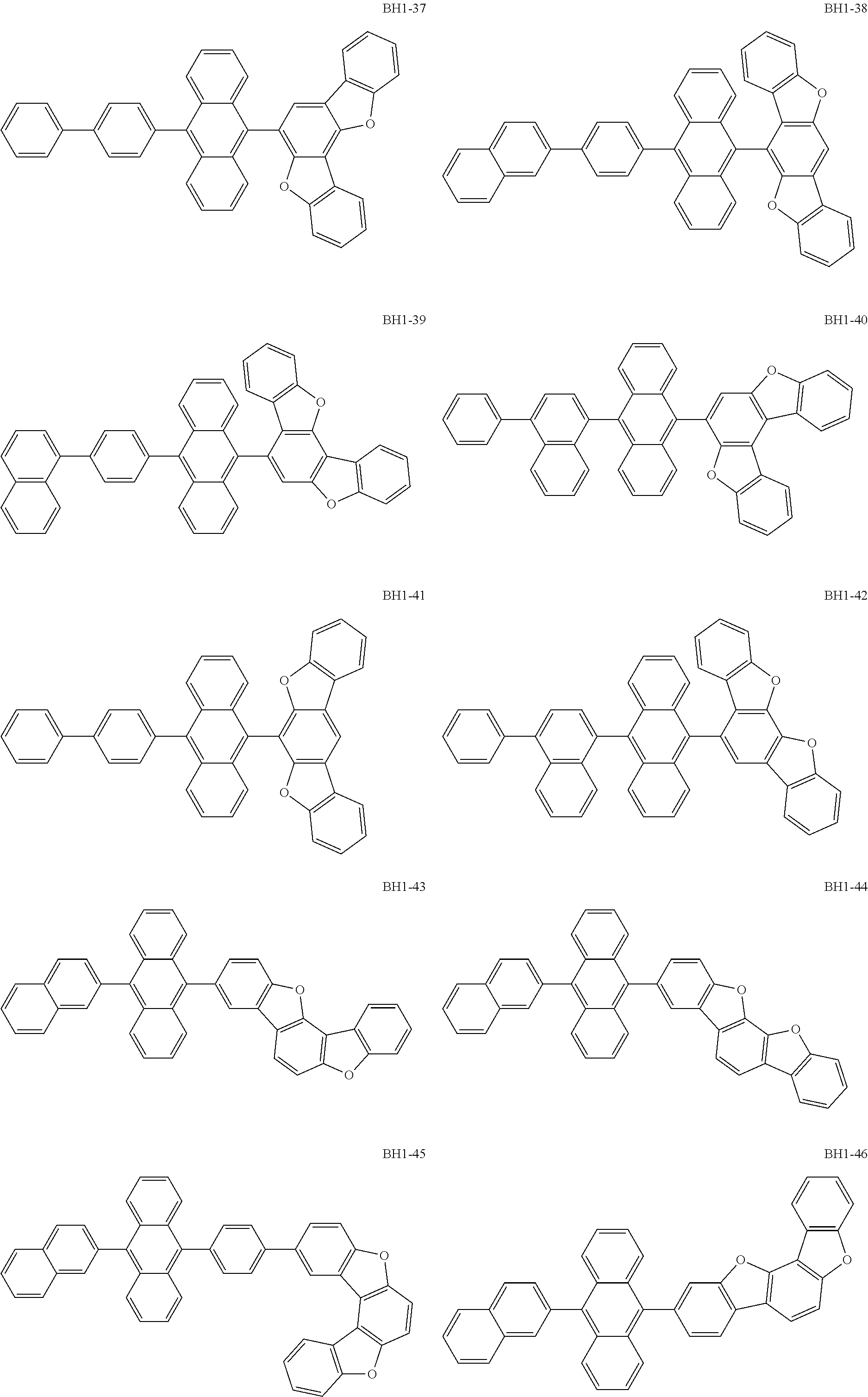

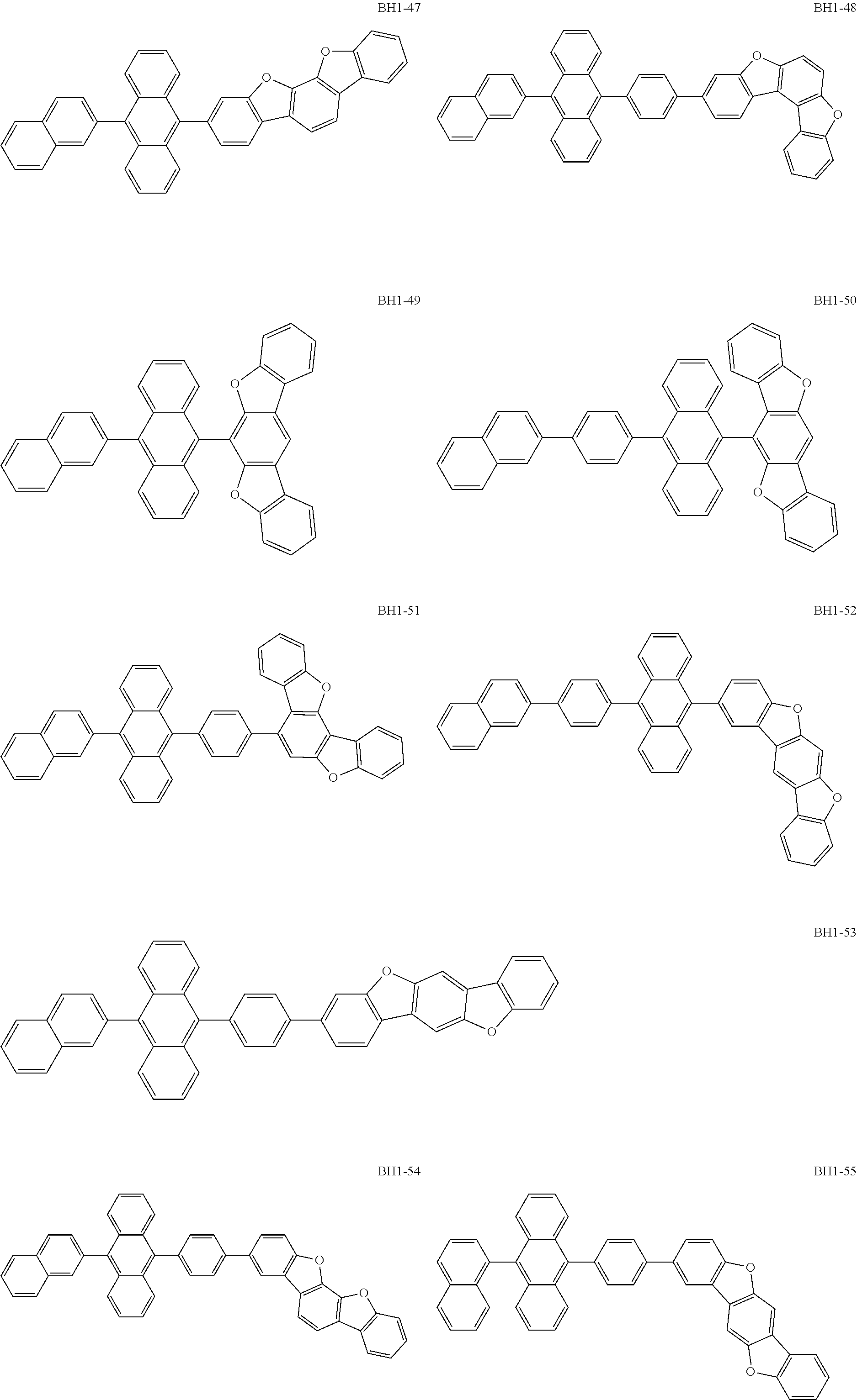

9. The light-emitting element of claim 1, wherein the second host is represented by any compound of Compound Group 2 below.

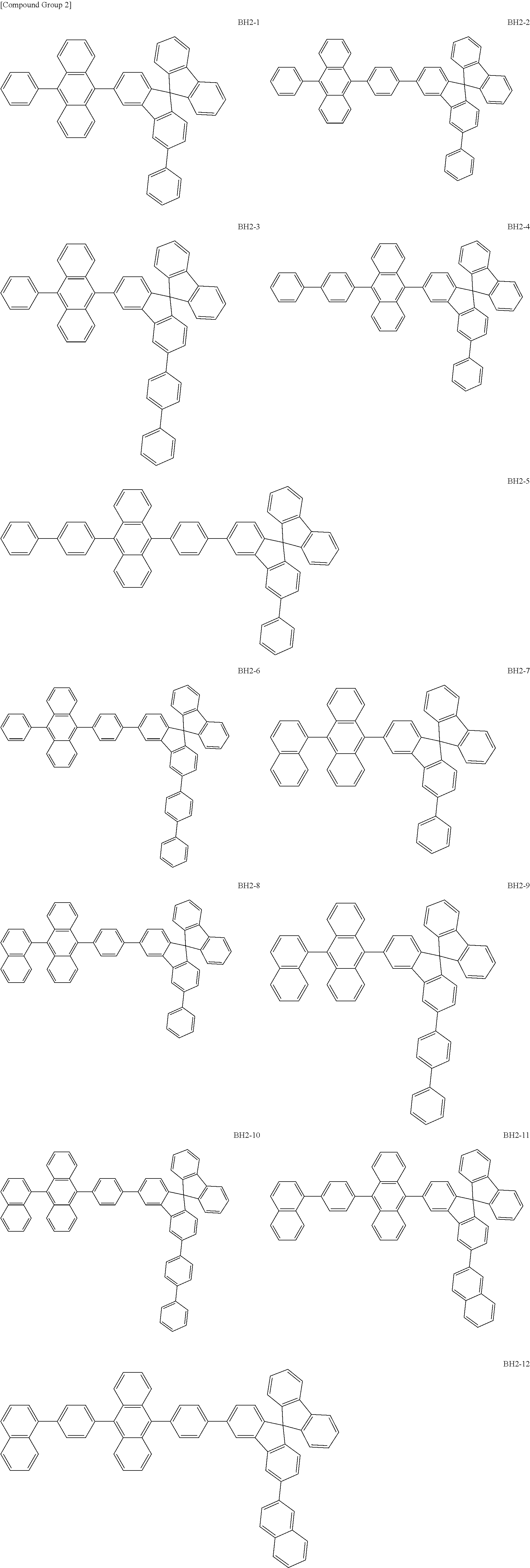

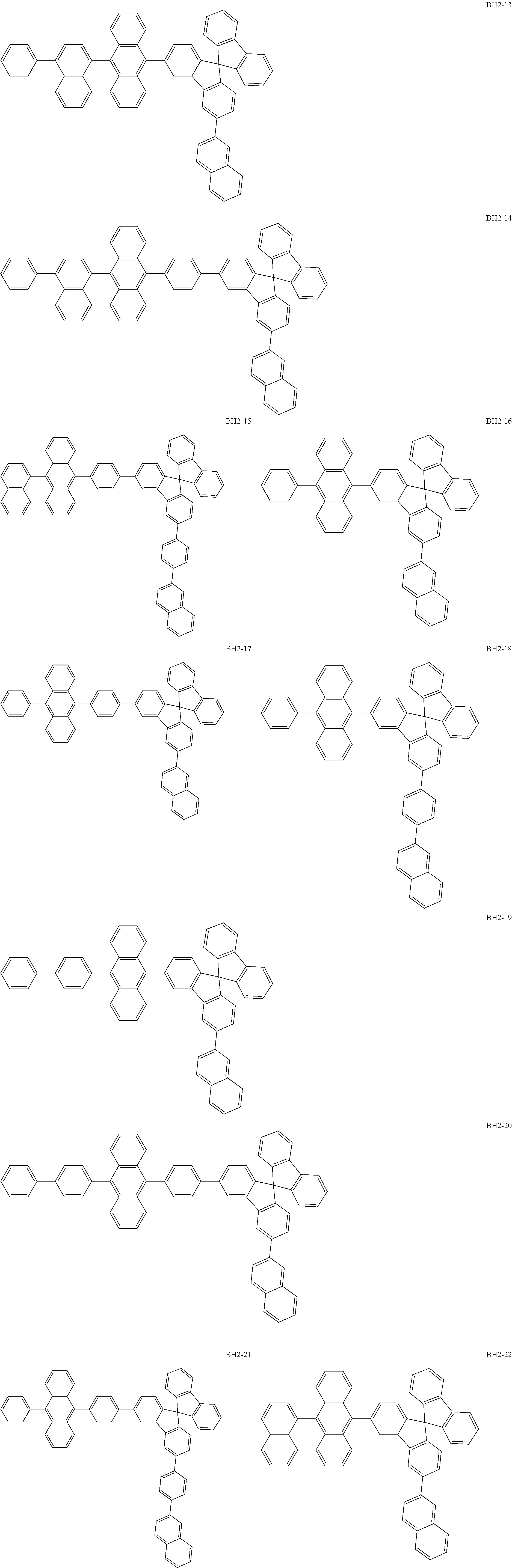

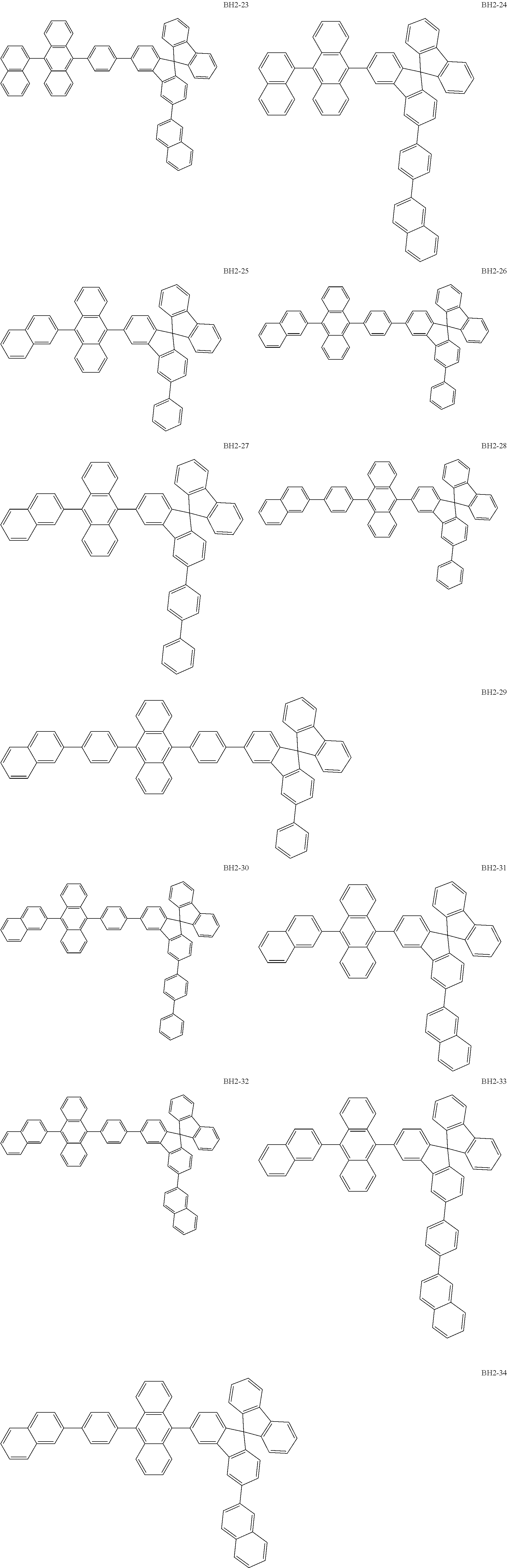

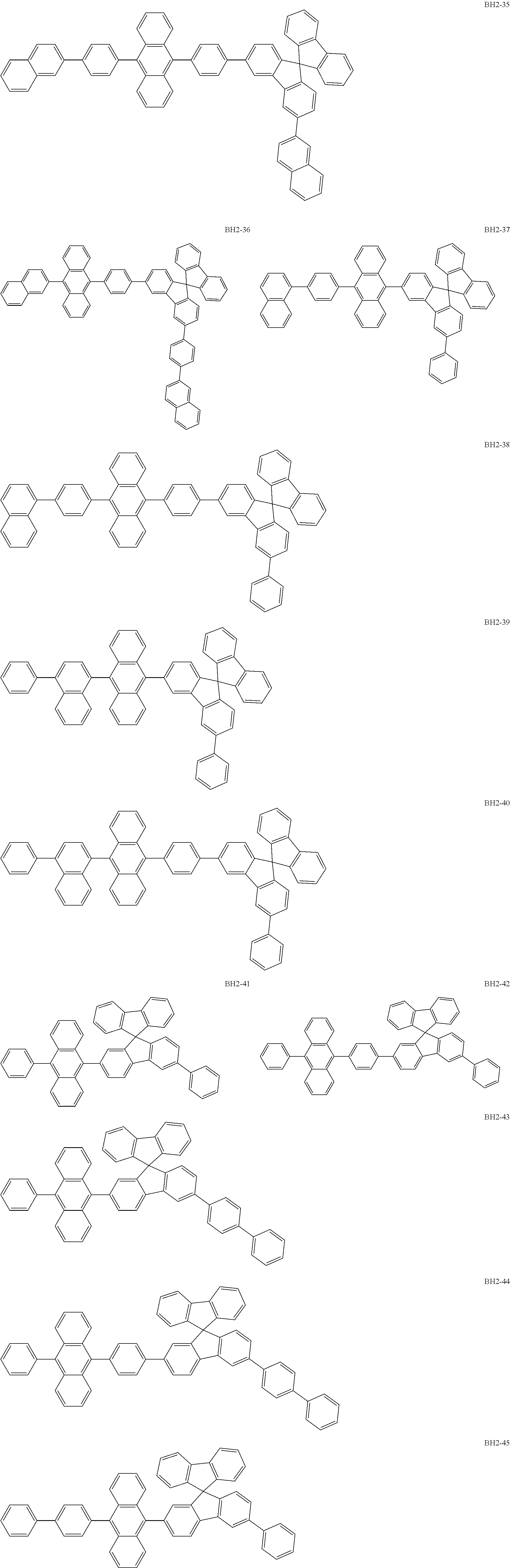

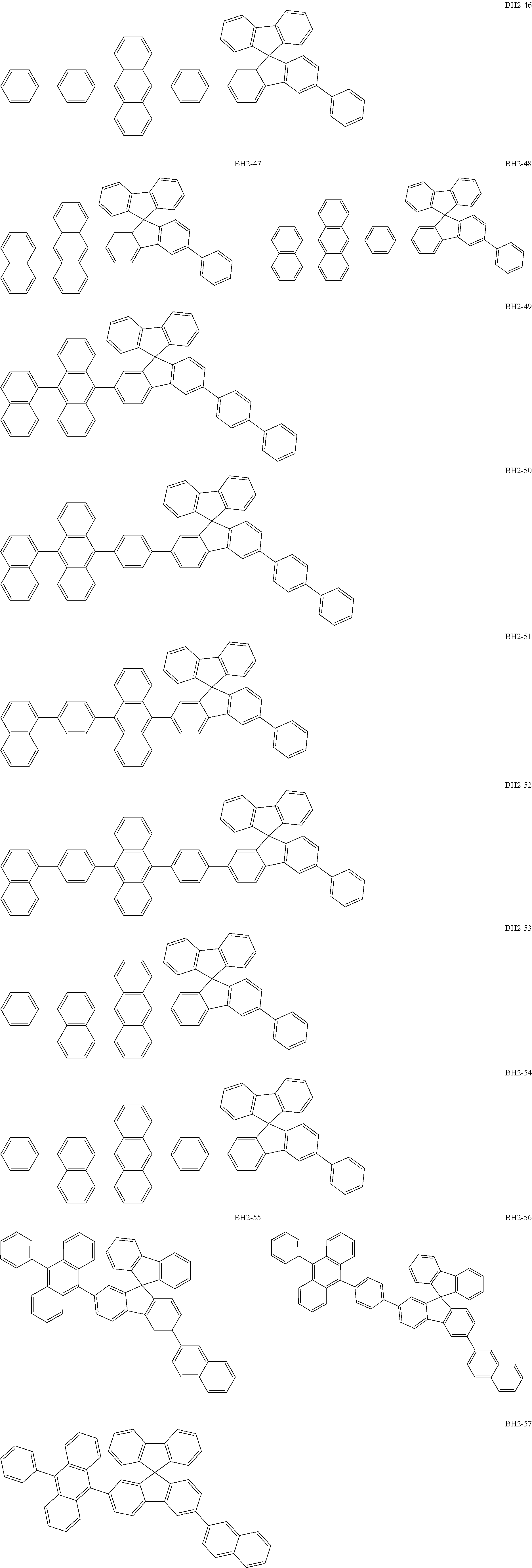

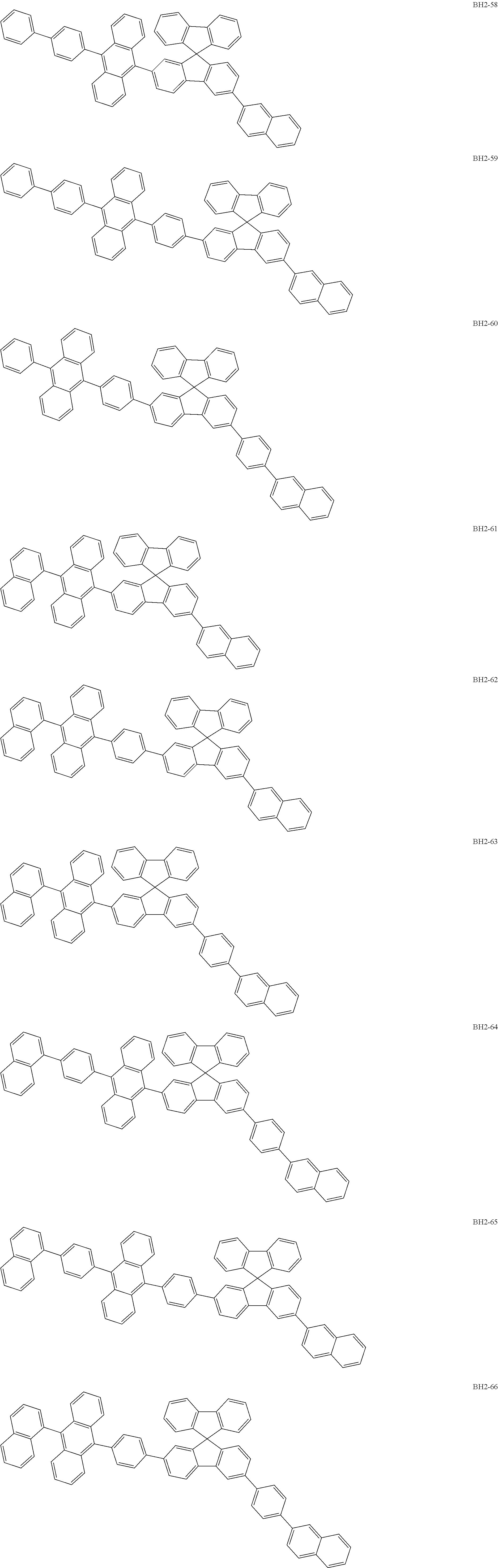

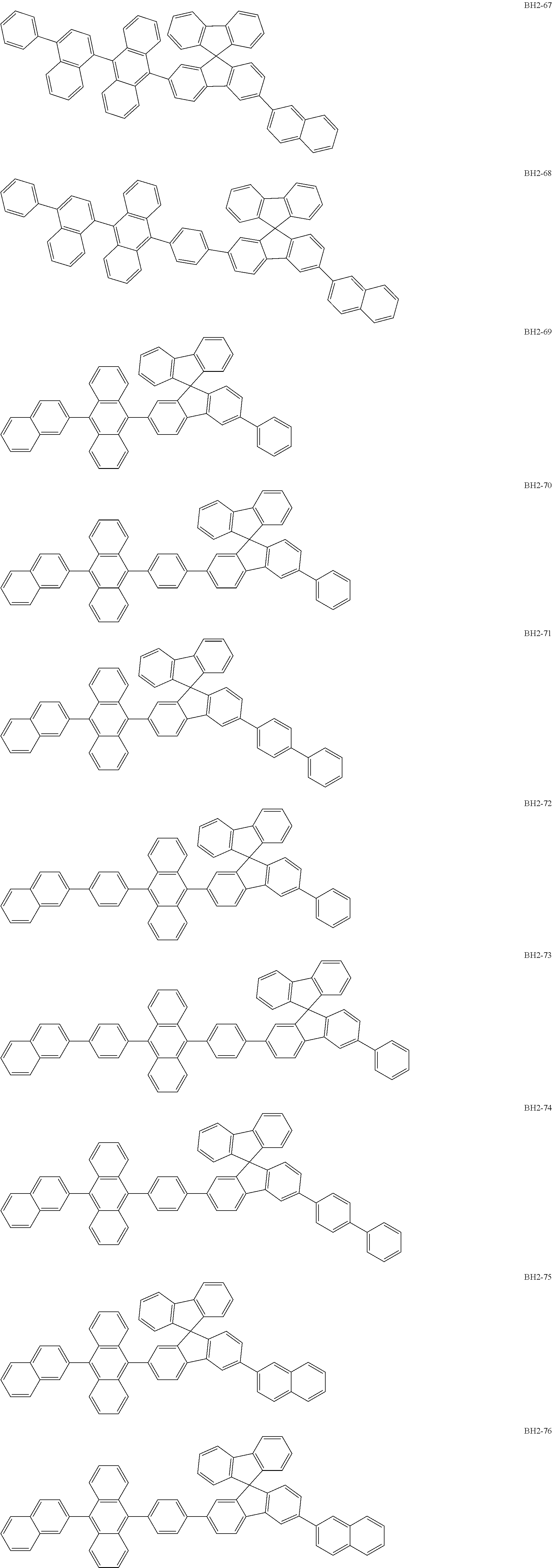

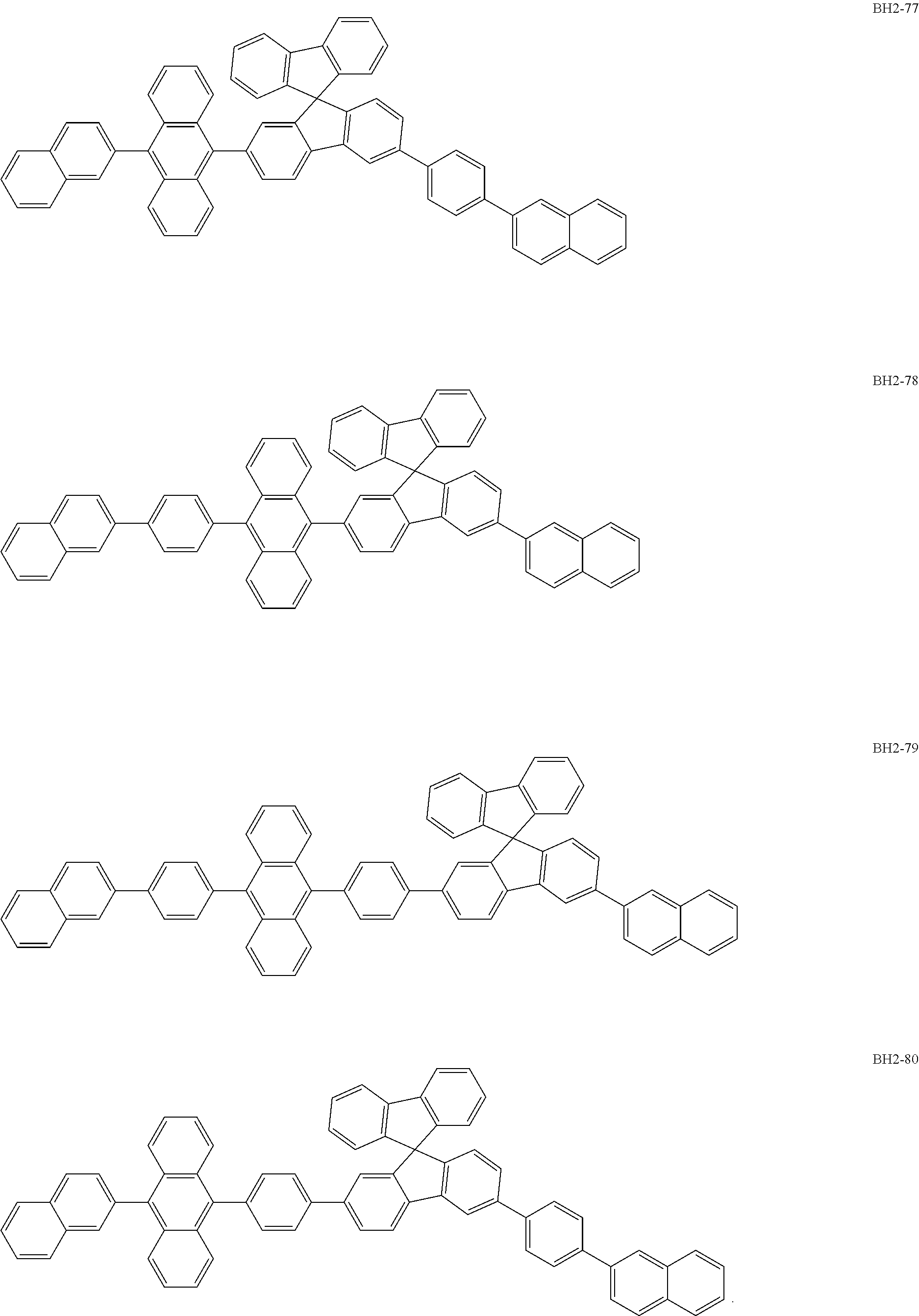

10. The light-emitting element of claim 1, further comprising a capping layer on the second electrode.

11. The light-emitting element of claim 1, wherein at least one of the first lower functional layer or the second lower functional layer further comprises an auxiliary light-emitting layer.

12. The light-emitting element of claim 1, wherein at least one of the first upper functional layer or the second upper functional layer further comprises an electron transport layer.

13. A display device having a red light-emitting region, a green light-emitting region, and a blue light-emitting region separated from each other on a plane, the display device comprising:
a base layer;
a circuit layer on the base layer; and
a display layer on the circuit layer, the display layer comprising a red light-emitting element corresponding to the red light-emitting region of the display device, a green light-emitting element corresponding to the green light-emitting region of the display device, and a blue light-emitting element corresponding to the blue light-emitting region of the display device,
wherein each of the red light-emitting element, the green light-emitting element, and the blue light-emitting element includes:
a first electrode,
a second electrode facing the first electrode,
a first light-emitting structure between the first electrode and the second electrode, the first light-emitting structure comprising a first lower functional layer, a first light-emitting layer, and a first upper functional layer stacked in that sequence,
a second light-emitting structure on the first light-emitting structure, the second light-emitting structure comprising a second lower functional layer, a second light-emitting layer, and a second upper functional layer stacked in that sequence, and
a charge generation layer between the first light-emitting structure and the second light-emitting structure,
wherein the second light-emitting layer of the blue light-emitting element comprises a first host, a second host different from the first host, and a blue light-emitting dopant, and
wherein a ratio of the first host to the second host is about 9:1 to about 8:2.

14. The display device of claim 13, wherein the charge generation layer comprises:
an n-type charge generation layer overlapping the red light-emitting region, the green light-emitting region, and the blue light-emitting region, wherein the n-type charge generation layer is a common layer on the first light-emitting structure; and
a p-type charge generation layer directly on the n-type charge generation layer,
wherein the p-type charge generation layer has a discontinuous pattern such that the p-type charge generation layer overlaps each of the red light-emitting region, the green light-emitting region, and the blue light-emitting region individually.

15. The display device of claim 13, wherein the green light-emitting element comprises a hole transport host and an electron transport host on at least one of the first light-emitting layer or the second light-emitting layer,
wherein the hole transport host is represented by Formula HT-1: 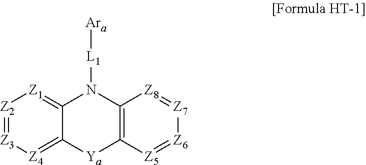
wherein, in Formula HT-1,
Z₁ to Z₈ are each independently N or CRₐ₁,
L₁ is a direct linkage, a substituted or unsubstituted arylene group of 6 to 30 ring-forming carbon atoms, or a substituted or unsubstituted hetero arylene group of 2 to 30 ring-forming carbon atoms,
Yₐ is a direct linkage, CRₐ₂Rₐ₃, or SiRₐ₄Rₐ₅,
Rₐ₁ to Rₐ₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 c ring-forming carbon atoms, and
Arₐ is a substituted or unsubstituted aryl group of 6 to 30 ring-forming carbon atoms, or a substituted or unsubstituted heteroaryl group of2 to 30 ring-forming carbon atoms,
wherein the electron transport host is represented by Formula ET-1: 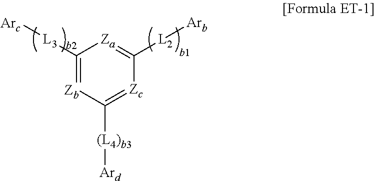
wherein, in Formula ET-1,
at least one of Zₐ to Z_{c} is N, and a remainder are CRₐ₆,
Rₐ₆ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
b1 to b3 are each independently an integer of 0 to 10,
L₂ to L₄ are each independently a direct linkage, a substituted or unsubstituted arylene group of 6 to 30 ring-forming carbon atoms, or a substituted or unsubstituted heteroarylene group of 2 to 30 ring-forming carbon atoms, and
Ar_{b} to Ar_{d} are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

16. The display device of claim 13, wherein the first host is represented by Formula 1: 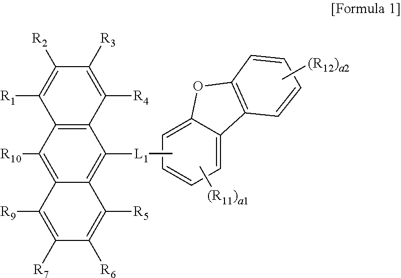
wherein, in Formula 1,
L₁ is a direct linkage, or a substituted or unsubstituted arylene group of 6 to 30 ring-forming carbon atoms,
R₁ to R₇ and R₉ to R₁₁ are each independently a hydrogen atom, a deuterium atom, or a substituted or unsubstituted aryl group of 6 to 30 ring-forming carbon atoms,
R₁₂ is a hydrogen atom, a deuterium atom, a hydroxy group, a substituted or unsubstituted oxy group, a substituted or unsubstituted alkyl group of 1 to 30 carbon atoms, a substituted or unsubstituted alkenyl group of 2 to 30 carbon atoms, or a substituted or unsubstituted aryl group of 6 to 30 ring-forming carbon atoms, or is bonded to an adjacent group to form a ring,
a1 is an integer of 0 to 3, and
a2 is an integer of 0 to 4.

17. The display device of claim 13, wherein the second host is represented by Formula 2: 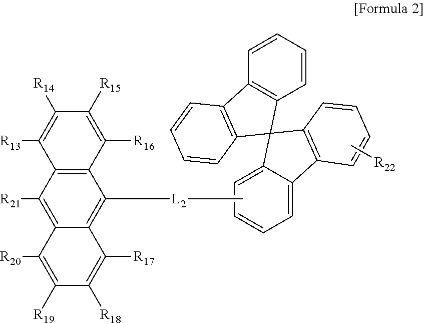
wherein, in Formula 2,
L₂ is a direct linkage, or a substituted or unsubstituted arylene group of 6 to 30 ring-forming carbon atoms,
R₁₃ to R₂₁ are each independently a hydrogen atom, a deuterium atom, or a substituted or unsubstituted aryl group of 6 to 30 ring-forming carbon atoms, and
R₂₂ is a substituted or unsubstituted ring-forming aryl group of 6 to 30 carbon atoms.

18. An electronic apparatus comprising a display panel comprising a plurality of light-emitting elements,
wherein at least one of the plurality of light-emitting elements comprises:
a first electrode;
a second electrode facing the first electrode;
a first light-emitting structure between the first electrode and the second electrode, the first light-emitting structure containing a first lower functional layer, a first light-emitting layer, and a first upper functional layer stacked in that sequence;
a second light-emitting structure on the first light-emitting structure, the second light-emitting structure containing a second lower functional layer, a second light-emitting layer, and a second upper functional layer stacked in that sequence; and
a charge generation layer between the first light-emitting structure and the second light-emitting structure,
wherein the second light-emitting layer comprises a first host, a second host different from the first host, and a blue light-emitting dopant, and
wherein a ratio of the first host to the second host is about 9:1 to about 8:2.

19. The electronic apparatus of claim 18, further comprising a color filter layer on the display panel,
wherein the color filter layer comprises filters corresponding to the plurality of light-emitting elements.

20. The electronic apparatus of claim 18,
wherein the electronic apparatus is a television, a monitor, a billboard, a personal computer, a laptop computer, a personal digital assistant, a device for vehicles, a game console, a smartphone, a tablet computer, a smart watch, or a camera.
